(19) United States
(12) Patent Application Publication
(10) Pub. No.: US 2024/0304254 A1
(43) Pub. Date: Sep. 12, 2024

(54) MEMORY DEVICE FOR SIGNED MULTI-BIT TO MULTI-BIT MULTIPLICATIONS

(71) Applicant: Micron Technology, Inc., Boise, ID (US)

(72) Inventor: Hernan Castro, Shingle Springs, CA (US)

(21) Appl. No.: 18/423,178

(22) Filed: Jan. 25, 2024

Related U.S. Application Data
(60) Provisional application No. 63/489,387, filed on Mar. 9, 2023.

(51) Int. Cl. G11C 16/10; G06F 7/544; G11C 16/04

(52) U.S. Cl. CPC G11C 16/102; G06F 7/5443; G11C 16/0433

(57) ABSTRACT

Systems, methods, and apparatus related to memory devices that perform signed multi-bit to multi-bit multiplication using sets of memory cells. In one approach, a memory cell array has sets of memory cells. Each set is programmable to store a multi-bit signed weight. Voltage drivers apply voltages to each set. The voltages correspond to multi-bit signed inputs. One or more common lines are coupled to each set for summing output currents from the sets during the multiplication. A digitizer provides signed results based on summing the output currents. The signed results are added with adjustment for the bit significance of each signed result to provide a final accumulation result for the multiplication.

### RELATED APPLICATIONS

The present application claims priority to Prov. U.S. Pat. App. Ser. No. 63/489,387 filed Mar. 9, 2023, the entire disclosures of which application are hereby incorporated herein by reference.

### TECHNICAL FIELD

At least some embodiments disclosed herein relate to memory devices in general and more particularly, but not limited to, memory devices that perform signed multi-bit to multi-bit multiplications using sets of memory cells in a memory cell array.

### BACKGROUND

Image and other sensors can generate large amounts of data. It is inefficient to transmit certain types of data from the sensors to general-purpose microprocessors (e.g., central processing units (CPU)) for processing in some applications. For example, it is inefficient to transmit image data from image sensors to microprocessors for image segmentation, object recognition, feature extraction, etc.

Some image processing can include intensive computations involving multiplications of columns or matrices of elements for accumulation. Some specialized circuits have been developed for the acceleration of multiplication and accumulation operations. For example, a multiplier-accumulator (MAC unit) can be implemented using a set of parallel computing logic circuits to achieve a computation performance higher than general-purpose microprocessors.

### BRIEF DESCRIPTION OF THE DRAWINGS

The embodiments are illustrated by way of example and not limitation in the figures of the accompanying drawings in which references indicate similar elements.

FIG. 1 shows an integrated circuit device having an image sensing pixel array, a memory cell array, and circuits to perform inference computations according to one embodiment.

FIG. 2 shows the computation of a column of weight bits multiplied by a column of input bits to provide an accumulation result according to one embodiment.

FIG. 3 shows the computation of a column of multi-bit weights multiplied by a column of input bits to provide an accumulation result according to one embodiment.

FIG. 4 shows the computation of a column of multi-bit weights multiplied by a column of multi-bit inputs using inputs at multiple time instances to provide an accumulation result according to one embodiment.

FIG. 5 shows the computation of a column of multi-bit weights multiplied by a column of multi-bit inputs using pulse width modulation (PWM) of the inputs to provide an accumulation result according to one embodiment.

FIG. 6 shows a method of computation in an integrated circuit device according to one embodiment.

FIG. 7 shows an exemplary current-voltage (IV) curve for a resistive memory cell according to one embodiment.

FIG. 8 shows an exemplary current-voltage (IV) curve for a floating gate or charge trap memory cell according to one embodiment.

FIG. 9 shows a three-dimensional memory cell array having resistive random-access memory (RRAM) cells according to one embodiment.

FIG. 10 shows a three-dimensional memory cell array having floating gate or charge trap memory cells in a NAND configuration according to one embodiment.

FIG. 11 shows a three-dimensional memory cell array having floating gate memory cells in a NOR configuration according to one embodiment.

FIG. 12 shows sets of memory cells storing signed weights used for multiplication according to one embodiment.

FIG. 13 shows an exemplary memory cell of a three-dimensional memory array formed above a semiconductor substrate according to one embodiment.

FIG. 14 shows a method for performing signed multiplication using weights stored in sets of memory cells according to one embodiment.

FIG. 15 shows a set of two memory cells for storing a signed weight used for multiplication according to one embodiment.

FIG. 16 shows voltage waveforms used for the memory cell configuration of FIG. 15 according to one embodiment.

FIG. 17 shows a method for performing signed multiplication using weights stored in sets each containing two memory cells according to one embodiment.

FIG. 18 shows a multiplication architecture having two digitizers and using a set of four memory cells for storing a signed weight according to one embodiment.

FIG. 19 shows a multiplication architecture having analog circuitry to combine output currents from two common lines and using a set of four memory cells for storing a signed weight according to one embodiment.

FIG. 20 shows voltage waveforms used as a signed input for the memory cell configuration of FIG. 18 or FIG. 19 according to one embodiment.

FIG. 21 shows a method for performing signed multiplication using weights stored in sets each containing four memory cells according to one embodiment.

FIG. 22 shows a multiplication architecture for summing outputs from multiplications at two different time instances using a single line according to one embodiment.

FIG. 23 shows a multiplication architecture for summing outputs from multiplications at a same time using two lines according to one embodiment.

FIGS. 24-26 show exemplary reductions of summation counts according to one embodiment.

FIG. 27 shows a method for performing summation of outputs from signed multiplications performed by sets of memory cells according to one embodiment.

FIG. 28 shows an architecture for performing signed multi-bit to multi-bit multiplications using sets of memory cells to provide a signed result according to one embodiment.

FIG. 29 shows an architecture for performing signed multi-bit to multi-bit multiplications using serial multi-bit inputs according to one embodiment.

FIG. 30 shows a method for performing signed multi-bit to multi-bit multiplications in a memory cell array according to one embodiment.

FIG. 31 shows a three-dimensional memory cell array having memory cells arranged in a parallel configuration with individual selectors according to one embodiment.

### DETAILED DESCRIPTION

The following disclosure describes various embodiments for memory devices performing multiplication using logical states of memory cells. The memory device may, for example, store data used by a host device (e.g., a computing device of an autonomous vehicle, or another computing device that accesses data stored in the memory device). In one example, the memory device is a solid-state drive mounted in an electric vehicle.

Artificial intelligence (AI) accelerated applications are growing rapidly. Deep learning technologies have been playing a critical role in this emergence and achieved success in a variety of applications such as image classification, object detection, speech recognition, natural language processing, recommender systems, automatic generation, and robotics etc. Many domain-specific deep learning accelerators (DLA) (e.g., GPU, TPU and embedded NPU), have been introduced to provide the required efficient implementations of deep neural networks (DNN) from cloud to edge. However, the limited memory bandwidth is still a critical challenge due to frequent data movement back and forth between compute units and memory in deep learning, especially for energy constrained systems and applications (e.g., edge AIs).

Conventional Von-Neumann computer architecture has developed with processor chips specialized for serial processing and DRAMs optimized for high density memory. The interface between these two devices is a major bottleneck that introduces latency and bandwidth limitations and adds a considerable overhead in power consumption. With the growing demand of higher accuracy and higher speed for AI applications, larger DNN models are developed and implemented with huge amounts of weights and activations. The resulting bottlenecks of memory bandwidth and power consumption on inter-chip data movement are significant technical problems.

To address these and other technical problems, a memory device integrates memory and processing. In one example, memory and inference computation processing are integrated in the same integrated circuit device. In some embodiments, the memory device is an integrated circuit device having an image sensing pixel array, a memory cell array, and one or more circuits to use the memory cell array to perform inference computation on image data from image sensors. In some embodiments, the memory device includes or is used with other types of sensors (e.g., LIDAR, radar, sound).

Existing methods of matrix vector multiplication use digital logic gates. Digital logic implementations are more complex, consume more silicon area, and dissipate more power as compared to various embodiments described below. These embodiments effectively reduce the multiplication to a memory access function which can be parallelized in an array. The accumulation function is carried out by wires that connect these memory elements, which can also be parallelized in an array. By combining these two features in an array, matrix vector multiplication can be performed more efficiently than methods using digital logic gates.

In one embodiment, an image sensor is configured with an analog capability to support inference computations by using matrix vector multiplication, such as computations of an artificial neural network. The image sensor can be implemented as an integrated circuit device having an image sensor chip and a memory chip. The memory chip can have a 3D memory array configured to support multiplication and accumulation operations. The integrated circuit device includes one or more logic circuits configured to process images from the image sensor chip, and to operate the memory cells in the memory chip to perform multiplications and accumulation operations.

The memory chip can have multiple layers of memory cells. Each memory cell can be programmed to store a bit of a binary representation of an integer weight. Each input line can be applied a voltage according to a bit of an integer. Columns of memory cells can be used to store bits of a weight matrix; and a set of input lines can be used to control voltage drivers to apply read voltages on rows of memory cells according to bits of an input vector.

The threshold voltage or state of a memory cell used for multiplication and accumulation operations can be programmed such that the current going through the memory cell subjected to a predetermined read voltage is either a predetermined amount representing a value of one stored in the memory cell, or negligible to represent a value of zero stored in the memory cell. When the predetermined read voltage is not applied, the current going through the memory cell is negligible regardless of the value stored in the memory cell. As a result of the configuration, the current going through the memory cell corresponds to the result of a 1-bit weight, as stored in the memory cell, multiplied by a 1-bit input, corresponding to the presence or the absence of the predetermined read voltage driven by a voltage driver controlled by the 1-bit input.

Output currents of the memory cells, representing the results of a column of 1-bit weights stored in the memory cells and multiplied by a column of 1-bit inputs respectively, are connected to a common line for summation. The summed current in the common line is a multiple of the predetermined amount; and the multiples can be digitized and determined using an analog to digital converter or other digitizer. Such results of 1-bit to 1-bit multiplications and accumulations can be performed for different significant bits of weights and different significant bits of inputs. The results for different significant bits can be shifted to apply the weights of the respective significant bits for summation to obtain the results of multiplications of multi-bit weights and multi-bit inputs with accumulation, as further discussed below.

Using the capability of performing multiplication and accumulation operations implemented via memory cell arrays, a logic circuit can be configured to perform inference computations, such as the computation of an artificial neural network.

Various embodiments of memory devices performing multiplication using logical states of memory cells are described below. A memory device typically has memory cells configured in an array, with each memory cell programmed, for example, to allow an amount of current to go through when a voltage is applied in a predetermined voltage region to represent a first logic state (e.g., a first value stored in the memory cell), or a negligible amount of current to represent a second logic state (e.g., a second value stored the memory cell).

The memory device performs computations based on applying voltages in a digital fashion, in the form of whether or not to apply an input voltage to generate currents for summation over a line (e.g., a bitline of a memory array). The total current on the line will be the multiple of the amount of current allowed for cells programmed at the first value. In one example, an analog-to-digital converter is used to convert the current to a digital result of a sum of bit-by-bit multiplications. Various implementations of performing bit-by-bit multiplications and extending these to multiplications involving multiple bits are described below.

The memory cells in the array may generally be of various types. Examples include NAND or NOR flash memory cells and phase-change memory (PCM) cells. In one example, the PCM cells are chalcogenide memory cells. In one example, floating gate or charge trap memory devices in NAND and NOR memory configurations are used.

NAND flash memory cells and chalcogenide memory cells have different current characteristics near their threshold voltages. The chalcogenide memory cells have a snap-back behavior, and a cell's voltage-current (V-I) curve is not continuous across the threshold voltage. In contrast, NAND flash memory cells exhibit a continuous behavior, but a cell's current typically increases rapidly near its threshold voltage region.

In various embodiments using chalcogenide memory cells, multiplications and other processing is performed by operating the chalcogenide memory cells in a sub-threshold region. This is to avoid thresholding or snapping of any memory cell, which typically would prevent proper multiplication (e.g., due to large undesired output currents associated with snapping).

In one embodiment, a memory device (e.g., integrated circuit device) includes a memory cell array having memory cells. Each memory cell is programmable to store a respective weight for performing a multiplication. The integrated circuit device also includes voltage drivers configured to apply input voltages to the memory cells for performing the multiplication. The input voltages represent an input to be multiplied by the respective weight for each memory cell, and the voltages are applied so that operation of the memory cells is kept in a sub-threshold mode during the multiplication.

The integrated circuit device has a bitline (or other common line) coupled to the memory cells. The bitline is configured to sum output currents from each of the memory cells that result from applying the input voltages. The integrated circuit device has a digitizer configured to generate a result for the multiplication based on the summed output currents.

In one embodiment, a memory device implements unsigned 1-bit to 1-bit multiplication using chalcogenide or other types of memory cells (e.g., NAND cells). Each memory cell can be programmed to a “1-state” such that a predetermined amount of current can go through the memory cell when a voltage V is applied across the memory cell (e.g., across two terminals of a resistive memory cell). Alternatively, the memory cell can be programmed to a “0-state” such that only a negligible amount of current can go through the memory cell when the same voltage V is applied.

To avoid operability issues with snap-back behavior, when using chalcogenide memory cells, it is desired to apply the voltage V only in the sub-threshold region of the memory cell. In one example, the applied voltage is lower than but close to the threshold/snap voltage of each memory cell that is programmed to the “1-state”. In general, the memory cells can be operated in a sub-threshold mode for any types of cells as may be desired (e.g., other phase-change memory cells or NAND cells). However, sub-threshold mode operation is not required for all embodiments.

Thus, the memory cells can be programmed to the “1-state” or the “0-state” to represent a stored weight of “1” or “0” respectively.

An input voltage of V can be used to represent an input of “1”; and an input voltage of 0 can be used to represent an input of “0”. Alternatively, another voltage can be used to represent an input of “0” when the voltage is lower than V but only causes a negligible amount of current to go through the memory cell (regardless of the programmed state of the memory cell).

When a voltage configured to be representative of an input of either 1 or 0 as described above is applied on the memory cell, programmed to either the “1-State” or “0-State” to represent a weight of 1 or 0 as discussed above, the amount of current going through the memory cell is either the predetermined amount (representative of an output of “1”), or a negligible amount (representative of an output of “0”). Further, the input, weight and output relations satisfy the multiplication of a 1-bit input by a 1-bit weight to generate a 1-bit output in all possible variations of input and weight.

Thus, a memory cell is used to perform unsigned 1-bit to multi-bit multiplication via being programed to store a 1-bit weight (e.g., in a way as discussed above), applying an input voltage to represent a 1-bit input (e.g., in a way as discussed above), and to determine a 1-bit output from sensing whether the current going through the memory cell (the output current from the memory cell) is the predetermined amount.

Summation of results represented by output currents from memory cells can be implemented via connecting the currents to a common line (e.g., a bitline). The summation of results can be digitized to provide a digital output. In one example, an analog-to-digital converter is used to measure the sum as the multiple of the predetermined amount of current and to provide a digital output.

In one embodiment, a memory device implements unsigned 1-bit to multi-bit multiplication. A multi-bit weight can be implemented via multiple memory cells. Each of the memory cells is configured to store one of the bits of the multi-bit weight, as just described above.

A voltage represented by a 1-bit input can be applied to the multiple memory cells separately to obtain results of unsigned 1-bit to 1-bit multiplication as described above.

Each memory cell has a position corresponding to its stored bit in the binary representation of the multi-bit weight. Its digitized output (e.g., from the summing of output currents from memory cells on a common bitline) can be shifted left according to its position in the binary representation to obtain a shifted result. For example, the digitized output of the memory cell storing the least significant bit of the multi-bit weight is shifted by 0 bit; the digitized output of the memory cell storing the second least significant bit of the multi-bit weight is shifted by 1 bit; the digitized output of the memory cell storing the third least significant bit of the multi-bit weight is shifted by 2 bit; etc. The shifted results can be summed to obtain the result of the 1-bit input multiplied by the multi-bit weight stored in the multiple memory cells.

Summation of results represented by output currents from sets of memory cells, each set representing a separate multi-bit weight, can be summed bitwise, via currents connected in common lines, for the different bit positions in multi-bit weights. For example, the currents from memory cells storing the least significant bit are connected to a first common line to form the summed output of results derived from the least significant bits; the currents from memory cells storing the second least significant bit are connected to a second common line to form the summed output of results derived from the second least significant bits; the currents from memory cells storing the third least significant bit are connected to a third common line to form the summed output of results derived from the third least significant bits; etc. The summed outputs can be converted to a digital form, and then shifted for summation in a digital form. Alternatively, the respective currents may be scaled prior to digitization.

As mentioned above, the memory cells can be operated in a sub-threshold mode for any types of cells as may be desired (e.g., chalcogenide or other phase-change memory cells, or NAND cells). Sub-threshold mode operation is not required for all embodiments.

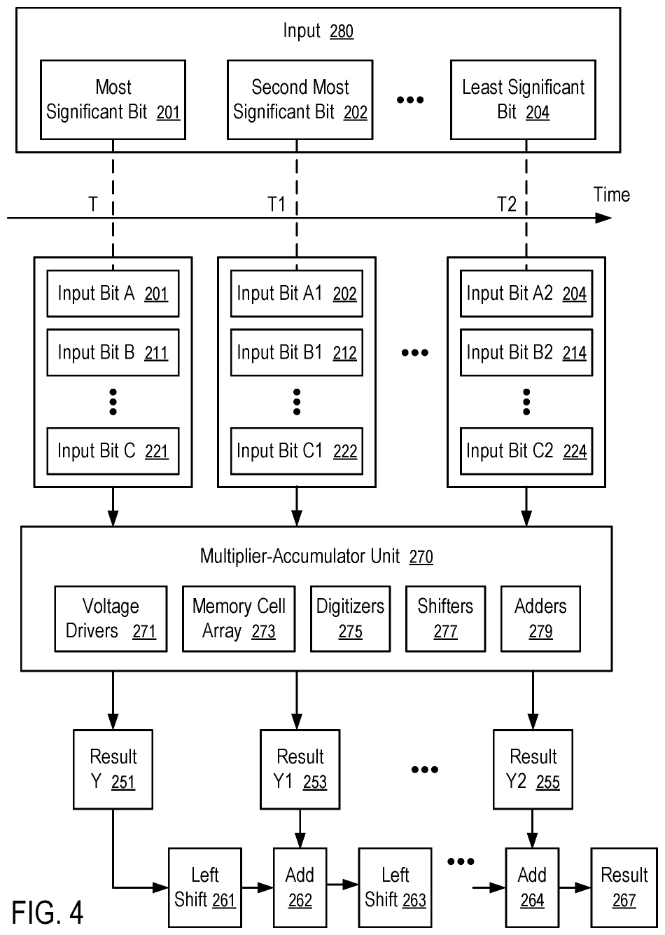

In one embodiment, a memory device implements time-sliced unsigned multi-bit to multi-bit multiplication. An input represented by a binary number having a predetermined number of bits (e.g., 4 bits) can be applied one bit at a time through the same predetermined number of clock cycles (e.g., applied at time instances T, T1, T2, etc. as in FIG. 4). Each cycle produces an output as described above for unsigned 1-bit to multi-bit multiplication.

The result of the unsigned 1-bit to multi-bit multiplication (e.g., as discussed above) obtained for each clock cycle can be shifted left according to the position of the bit of the input applied in the clock cycle. For example, the result of the clock cycle that applies the least significant bit of the input is not shifted; the result for the second least significant bit is shifted left by 1 bit; the result for the third least significant bit is shifted left by 2 bits; etc. The shifted results from the clock cycles are summed in a digital form.

As mentioned above, the memory cells can be operated in a sub-threshold mode for any types of cells as may be desired (e.g., chalcogenide or other phase-change memory cells, or NAND cells). Sub-threshold mode operation is not required for all embodiments.

In one embodiment, a memory device uses pulse width modulation (PWM) for performing unsigned multi-bit to multi-bit multiplication. An input voltage pulse is applied to multiple memory cells to produce current output as described above. The width of the voltage pulse (e.g., a length of time such as 5 nanoseconds, 10 nanoseconds, or 15 nanoseconds) is proportional to the multi-bit input. In one embodiment, the input voltage pulse is a constant voltage.

The output current from each memory cell is integrated over time to obtain the input multiplied by the 1-bit weight stored in the respective memory cell. The results from each memory cell can be digitized as a multiple of a predetermined amount of current integrated over a unit of time, corresponding to the width of the voltage pulse for an input of “1”. The digitized outputs are shifted according to their positions in the multi-bit weight for summation. The current integration over time can be implemented via charging a capacitor or by other methods. In one embodiment, the current integration is performed using any of various types of integrators.

As mentioned above, the memory cells can be operated in a sub-threshold mode for any types of cells as may be desired (e.g., chalcogenide or other phase-change memory cells, or NAND cells). Sub-threshold mode operation is not required for all embodiments.

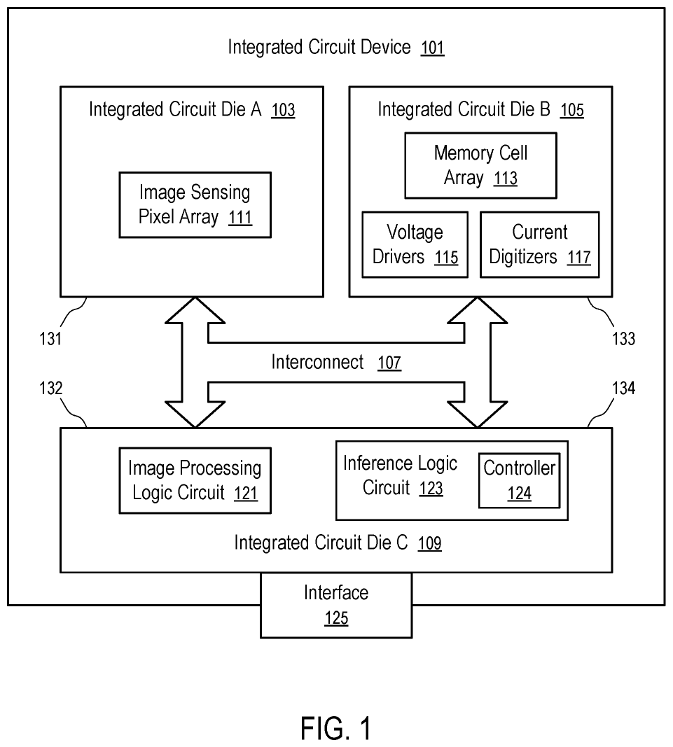

FIG. 1 shows an integrated circuit device 101 having an image sensing pixel array 111, a memory cell array 113, and circuits to perform inference computations according to one embodiment. In FIG. 1, the integrated circuit device 101 has an integrated circuit die 109 having logic circuits 121 and 123, an integrated circuit die 103 having the image sensing pixel array 111, and an integrated circuit die 105 having a memory cell array 113.

In one example, the integrated circuit die 109 having logic circuits 121 and 123 is a logic chip; the integrated circuit die 103 having the image sensing pixel array 111 is an image sensor chip; and the integrated circuit die 105 having the memory cell array 113 is a memory chip.

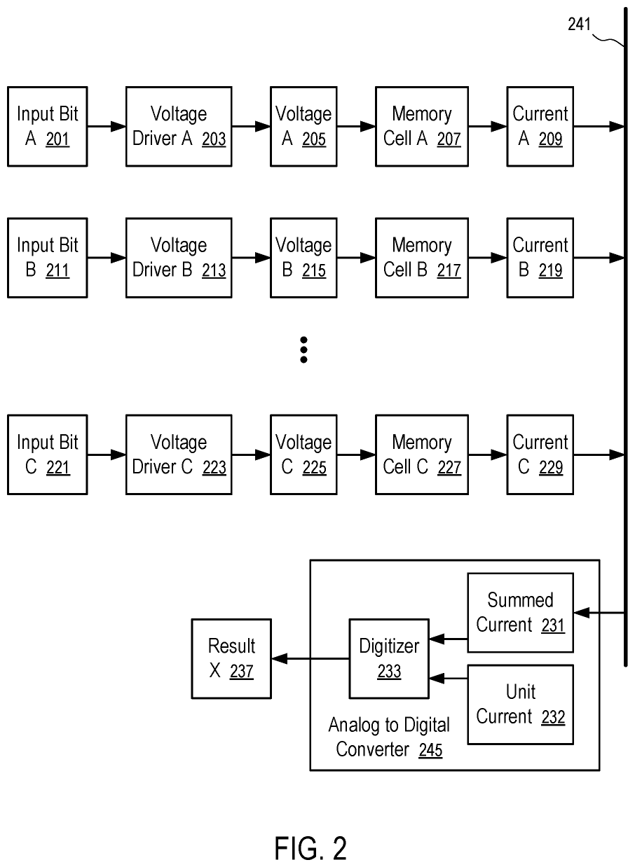

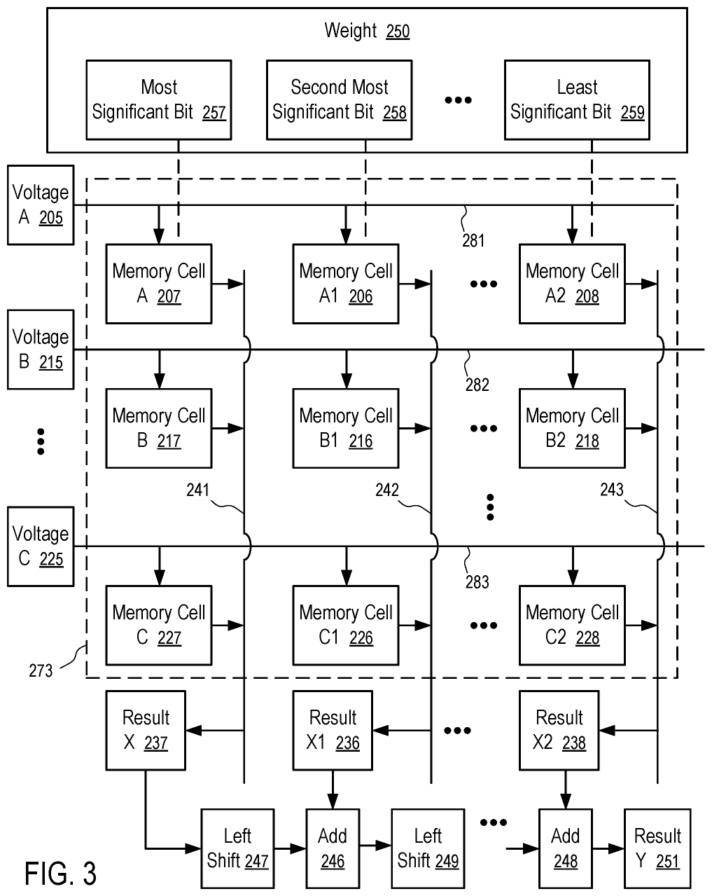

In FIG. 1, the integrated circuit die 105 having the memory cell array 113 further includes voltage drivers 115 and current digitizers 117. The memory cell array 113 is connected such that currents generated by the memory cells in response to voltages applied by the voltage drivers 115 are summed in the array 113 for columns of memory cells (e.g., as illustrated in FIG. 2 and FIG. 3); and the summed currents are digitized to generate the sum of bit-wise multiplications. The inference logic circuit 123 can be configured to instruct the voltage drivers 115 to apply read voltages according to a column of inputs, and perform shifts and summations to generate the results of a column or matrix of weights multiplied by the column of inputs with accumulation.

The inference logic circuit 123 can be further configured to perform inference computations according to weights stored in the memory cell array 113 (e.g., the computation of an artificial neural network) and inputs derived from the image data generated by the image sensing pixel array 111. Optionally, the inference logic circuit 123 can include a programmable processor that can execute a set of instructions to control the inference computation. Alternatively, the inference computation is configured for a particular artificial neural network with certain aspects adjustable via weights stored in the memory cell array 113. Optionally, the inference logic circuit 123 is implemented via an application-specific integrated circuit (ASIC), a field-programmable gate array (FPGA), or a core of a programmable microprocessor.

In one embodiment, inference logic circuit 123 includes controller 124. In one example, controller 124 manages communications with a host system via interface 125. In one example, controller 124 performs signed or unsigned multiplication using memory cell array 113. In one embodiment, controller 124 selects either of signed or unsigned multiplication to be performed based on the type of data to be used as an input for the multiplication. In one example, controller 124 selects signed multiplication in response to determining that inputs for the multiplication are signed.

In FIG. 1, the integrated circuit die 105 having the memory cell array 113 has a bottom surface 133; and the integrated circuit die 109 having the inference logic circuit 123 has a portion of a top surface 134. The two surfaces 133 and 134 can be connected via bonding to provide a portion of an interconnect 107 between metal portions on the surfaces 133 and 134.

Similarly, the integrated circuit die 103 having the image sensing pixel array 111 has a bottom surface 131; and the integrated circuit die 109 having the inference logic circuit 123 has another portion of its top surface 132. The two surfaces 131 and 132 can be connected via bonding to provide a portion of the interconnect 107 between metal portions on the surfaces 131 and 132.

An image sensing pixel in the array 111 can include a light sensitive element configured to generate a signal responsive to intensity of light received in the element. For example, an image sensing pixel implemented using a complementary metal-oxide-semiconductor (CMOS) technique or a charge-coupled device (CCD) technique can be used.

In some implementations, the image processing logic circuit 121 is configured to pre-process an image from the image sensing pixel array 111 to provide a processed image as an input to the inference computation controlled by the inference logic circuit 123.

Optionally, the image processing logic circuit 121 can also use the multiplication and accumulation function provided via the memory cell array 113.

In some implementations, interconnect 107 includes wires for writing image data from the image sensing pixel array 111 to a portion of the memory cell array 113 for further processing by the image processing logic circuit 121 or the inference logic circuit 123, or for retrieval via an interface 125.

The inference logic circuit 123 can buffer the result of inference computations in a portion of the memory cell array 113.

The interface 125 of the integrated circuit device 101 can be configured to support a memory access protocol, or a storage access protocol or any combination thereof. Thus, an external device (e.g., a processor, a central processing unit) can send commands to the interface 125 to access the storage capacity provided by the memory cell array 113.

For example, the interface 125 can be configured to support a connection and communication protocol on a computer bus, such as a peripheral component interconnect express (PCIe) bus, a serial advanced technology attachment (SATA) bus, a universal serial bus (USB) bus, a compute express link, etc. In some embodiments, the interface 125 can be configured to include an interface of a solid-state drive (SSD), such as a ball grid array (BGA) SSD. In some embodiments, the interface 125 is configured to include an interface of a memory module, such as a double data rate (DDR) memory module, a dual in-line memory module, etc. The interface 125 can be configured to support a communication protocol such as a protocol according to non-volatile memory express (NVMe), non-volatile memory host controller interface specification (NVMHCIS), etc.

The integrated circuit device 101 can appear to be a memory sub-system from the point of view of a device in communication with the interface 125. Through the interface 125, an external device (e.g., a processor, a central processing unit) can access the storage capacity of the memory cell array 113. For example, the external device can store and update weight matrices and instructions for the inference logic circuit 123, retrieve images generated by the image sensing pixel array 111 and processed by the image processing logic circuit 121, and retrieve results of inference computations controlled by the inference logic circuit 123.

In FIG. 1, the interface 125 is positioned, for example, at the bottom side of the integrated circuit device 101, while the image sensor chip is positioned at the top side of the integrated device 101 to receive incident light for generating images.

The voltage drivers 115 in FIG. 1 can be controlled to apply voltages to program the threshold voltages of memory cells in the array 113. Data stored in the memory cells can be represented by the levels of the programmed threshold voltages of the memory cells.

A typical memory cell in the array 113 has a nonlinear current to voltage curve. When the threshold voltage of the memory cell is programmed to a first level to represent a stored value of one, the memory cell allows a predetermined amount of current to go through when a predetermined read voltage higher than the first level is applied to the memory cell. When the predetermined read voltage is not applied (e.g., the applied voltage is zero), the memory cell allows a negligible amount of current to go through, compared to the predetermined amount of current.

On the other hand, when the threshold voltage of the memory cell is programmed to a second level higher than the predetermined read voltage to represent a stored value of zero, the memory cell allows a negligible amount of current to go through, regardless of whether the predetermined read voltage is applied. Thus, when a bit of weight is stored in the memory as discussed above, and a bit of input is used to control whether to apply the predetermined read voltage, the amount of current going through the memory cell as a multiple of the predetermined amount of current corresponds to the digital result of the stored bit of weight multiplied by the bit of input. Currents representative of the results of 1-bit by 1-bit multiplications can be summed in an analog form before being digitized for shifting and summing to perform multiplication and accumulation of multi-bit weights against multi-bit inputs, as further discussed below.

FIG. 2 shows the computation of a column of weight bits multiplied by a column of input bits to provide an accumulation result according to one embodiment. In FIG. 2, a column of memory cells 207, 217, . . . , 227 (e.g., in the memory cell array 113 of an integrated circuit device 101) can be programmed to have threshold voltages at levels representative of weights stored one bit per memory cell.

Voltage drivers 203, 213, . . . , 223 (e.g., in the voltage drivers 115 of an integrated circuit device 101) are configured to apply voltages 205, 215, . . . , 225 to the memory cells 207, 217, . . . , 227 respectively according to their received input bits 201, 211, . . . , 221.

For example, when the input bit 201 has a value of one, the voltage driver 203 applies the predetermined read voltage as the voltage 205, causing the memory cell 207 to output the predetermined amount of current as its output current 209 if the memory cell 207 has a threshold voltage programmed at a lower level, which is lower than the predetermined read voltage, to represent a stored weight of one, or to output a negligible amount of current as its output current 209 if the memory cell 207 has a threshold voltage programmed at a higher level, which is higher than the predetermined read voltage, to represent a stored weight of zero.

However, when the input bit 201 has a value of zero, the voltage driver 203 applies a voltage (e.g., zero) lower than the lower level of threshold voltage as the voltage 205 (e.g., does not apply the predetermined read voltage), causing the memory cell 207 to output a negligible amount of current at its output current 209 regardless of the weight stored in the memory cell 207. Thus, the output current 209 as a multiple of the predetermined amount of current is representative of the result of the weight bit, stored in the memory cell 207, multiplied by the input bit 201.

Similarly, the current 219 going through the memory cell 217 as a multiple of the predetermined amount of current is representative of the result of the weight bit, stored in the memory cell 217, multiplied by the input bit 211; and the current 229 going through the memory cell 227 as a multiple of the predetermined amount of current is representative of the result of the weight bit, stored in the memory cell 227, multiplied by the input bit 221.

The output currents 209, 219, . . . , and 229 of the memory cells 207, 217, . . . , 227 are connected to a common line 241 for summation. In one example, common line 241 is a bitline. A constant voltage (e.g., ground or −1 V) is maintained on the bitline when summing the output currents.

The summed current 231 is compared to the unit current 232, which is equal to the predetermined amount of current, by a digitizer 233 of an analog to digital converter 245 to determine the digital result 237 of the column of weight bits, stored in the memory cells 207, 217, . . . , 227 respectively, multiplied by the column of input bits 201, 211, . . . , 221 respectively with the summation of the results of multiplications.

The sum of negligible amounts of currents from memory cells connected to the line 241 is small when compared to the unit current 232 (e.g., the predetermined amount of current). Thus, the presence of the negligible amounts of currents from memory cells does not alter the result 237 and is negligible in the operation of the analog to digital converter 245.

In FIG. 2, the voltages 205, 215, . . . , 225 applied to the memory cells 207, 217, . . . 227 are representative of digitized input bits 201, 211, . . . , 221; the memory cells 207, 217, . . . , 227 are programmed to store digitized weight bits; and the currents 209, 219, . . . , 229 are representative of digitized results.

The result 237 is an integer that is no larger than the count of memory cells 207, 217, . . . , 227 connected to the line 241. The digitized form of the output currents 209, 219, . . . , 229 can increase the accuracy and reliability of the computation implemented using the memory cells 207, 217, . . . , 227.

In general, a weight involving a multiplication and accumulation operation can be more than one bit. Multiple columns of memory cells can be used to store the different significant bits of weights, as illustrated in FIG. 3 to perform multiplication and accumulation operations.

The circuit illustrated in FIG. 2 can be considered a multiplier-accumulator unit configured to operate on a column of 1-bit weights and a column of 1-bit inputs. Multiple such circuits can be connected in parallel to implement a multiplier-accumulator unit to operate on a column of multi-bit weights and a column of 1-bit inputs, as illustrated in FIG. 3.

The circuit illustrated in FIG. 2 can also be used to read the data stored in the memory cells 207, 217, . . . , 227. For example, to read the data or weight stored in the memory cell 207, the input bits 211, . . . , 221 can be set to zero to cause the memory cells 217, . . . , 227 to output a negligible amount of currents into the line 241 (e.g., as a bitline). The input bit 201 is set to one to cause the voltage driver 203 to apply the predetermined read voltage. Thus, the result 237 from the digitizer 233 provides the data or weight stored in the memory cell 207. Similarly, the data or weight stored in the memory cell 217 can be read via applying one as the input bit 211 and zeros as the remaining input bits in the column; and data or weight stored in the memory cell 227 can be read via applying one as the input bit 221 and zeros as the other input bits in the column.

In general, the circuit illustrated in FIG. 2 can be used to select any of the memory cells 207, 217, . . . , 227 for read or write. A voltage driver (e.g., 203) can apply a programming voltage pulse (e.g., one or more pulses or other waveform, as appropriate for a memory cell type) to adjust the threshold voltage of a respective memory cell (e.g., 207) to erase data, to store data or a weight, etc.

FIG. 3 shows the computation of a column of multi-bit weights multiplied by a column of input bits to provide an accumulation result according to one embodiment. In FIG. 3, a weight 250 in a binary form has a most significant bit 257, a second most significant bit 258, . . . , a least significant bit 259. The significant bits 257, 258, . . . , 259 can be stored in memory cells 207, 206, . . . , 208 in a number of columns respectively in an array 273. The significant bits 257, 258, . . . , 259 of the weight 250 are to be multiplied by the input bit 201 represented by the voltage 205 applied on a line 281 (e.g., a wordline) by a voltage driver 203 (e.g., as in FIG. 2).

Similarly, memory cells 217, 216, . . . , 218 can be used to store the corresponding significant bits of a next weight to be multiplied by a next input bit 211 represented by the voltage 215 applied on a line 282 (e.g., a wordline) by a voltage driver 213 (e.g., as in FIG. 2); and memory cells 227, 226, . . . , 228 can be used to store corresponding of a weight to be multiplied by the input bit 221 represented by the voltage 225 applied on a line 283 (e.g., a wordline) by a voltage driver 223 (e.g., as in FIG. 2).

The most significant bits (e.g., 257) of the weights (e.g., 250) stored in the respective rows of memory cells in the array 273 are multiplied by the input bits 201, 211, . . . , 221 represented by the voltages 205, 215, . . . , 225 and then summed as the current 231 in a line 241 and digitized using a digitizer 233, as in FIG. 2, to generate a result 237 corresponding to the most significant bits of the weights.

Similarly, the second most significant bits (e.g., 258) of the weights (e.g., 250) stored in the respective rows of memory cells in the array 273 are multiplied by the input bits 201, 211, . . . , 221 represented by the voltages 205, 215, . . . , 225 and then summed as a current in a line 242 and digitized to generate a result 236 corresponding to the second most significant bits.

Similarly, the least significant bits (e.g., 259) of the weights (e.g., 250) stored in the respective rows of memory cells in the array 273 are multiplied by the input bits 201, 211, . . . , 221 represented by the voltages 205, 215, . . . , 225 and then summed as a current in a line 243 and digitized to generate a result 238 corresponding to the least significant bit.

The most significant bit can be left shifted by one bit to have the same weight as the second significant bit, which can be further left shifted by one bit to have the same weight as the next significant bit. Thus, the result 237 generated from multiplication and summation of the most significant bits (e.g., 257) of the weights (e.g., 250) can be applied an operation of left shift 247 by one bit; and the operation of add 246 can be applied to the result of the operation of left shift 247 and the result 236 generated from multiplication and summation of the second most significant bits (e.g., 258) of the weights (e.g., 250). The operations of left shift (e.g., 247, 249) can be used to apply weights of the bits (e.g., 257, 258, . . . ) for summation using the operations of add (e.g., 246, . . . , 248) to generate a result 251. Thus, the result 251 is equal to the column of weights in the array 273 of memory cells multiplied by the column of input bits 201, 211, . . . 221 with multiplication results accumulated.

In general, an input involving a multiplication and accumulation operation can be more than 1 bit. For example, columns of input bits can be applied one column at a time to the weights stored in the array 273 of memory cells to obtain the result of a column of weights multiplied by a column of inputs with results accumulated as illustrated in FIG. 4.

The circuit illustrated in FIG. 3 can be used to read the data stored in the array 273 of memory cells. For example, to read the data or weight 250 stored in the memory cells 207, 206, . . . , 208, the input bits 211, . . . , 221 can be set to zero to cause the memory cells 217, 216, . . . , 218, . . . , 227, 226, . . . , 228 to output a negligible amount of currents into the line 241, 242, . . . 243 (e.g., as bitlines). The input bit 201 is set to one to cause the voltage driver 203 to apply the predetermined read voltage as the voltage 205. Thus, the results 237, 236, . . . , 238 from the digitizers (e.g., 233) connected to the lines 241, 242, . . . , 243 provide the bits 257, 258, . . . , 259 of the data or weight 250 stored in the row of memory cells 207, 206, . . . , 208. Further, the result 251 computed from the operations of shift 247, 249, . . . and operations of add 246, . . . , 248 provides the weight 250 in a binary form.

In general, the circuit illustrated in FIG. 3 can be used to select any row of the memory cell array 273 for read. Optionally, different columns of the memory cell array 273 can be driven by different voltage drivers. Thus, the memory cells (e.g., 207, 206, . . . , 208) in a row can be programmed to write data in parallel (e.g., to store the bits 257, 258, . . . , 259) of the weight 250.

FIG. 4 shows the computation of a column of multi-bit weights multiplied by a column of multi-bit inputs using inputs at multiple time instances to provide an accumulation result according to one embodiment. In FIG. 4, the significant bits of inputs (e.g., 280) are applied to a multiplier-accumulator unit 270 at a plurality of time instances T, T1, . . . , T2.

For example, a multi-bit input 280 can have a most significant bit 201, a second most significant bit 202, . . . , a least significant bit 204. At time T, the most significant bits 201, 211, . . . , 221 of the inputs (e.g., 280) are applied to the multiplier-accumulator unit 270 to obtain a result 251 of weights (e.g., 250), stored in the memory cell array 273, multiplied by the column of bits 201, 211, . . . , 221 with summation of the multiplication results.

For example, the multiplier-accumulator unit 270 can be implemented in a way as illustrated in FIG. 3. The multiplier-accumulator unit 270 has voltage drivers 271 connected to apply voltages 205, 215, . . . , 225 representative of the input bits 201, 211, . . . , 221. The multiplier-accumulator unit 270 has a memory cell array 273 storing bits of weights as in FIG. 3. The multiplier-accumulator unit 270 has digitizers 275 to convert currents summed on lines 241, 242, . . . , 243 for columns of memory cells in the array 273 to output results 237, 236, . . . , 238. The multiplier-accumulator unit 270 has shifters 277 and adders 279 connected to combine the column result 237, 236, . . . , 238 to provide a result 251 as in FIG. 3.

Similarly, at time T1, the second most significant bits 202, 212, . . . , 222 of the inputs (e.g., 280) are applied to the multiplier-accumulator unit 270 to obtain a result 253 of weights (e.g., 250) stored in the memory cell array 273 and multiplied by the vector of bits 202, 212, . . . 222 with summation of the multiplication results.

Similarly, at time T2, the least significant bits 204, 214, . . . , 224 of the inputs (e.g., 280) are applied to the multiplier-accumulator unit 270 to obtain a result 255 of weights (e.g., 250), stored in the memory cell array 273, multiplied by the vector of bits 202, 212, . . . , 222 with summation of the multiplication results.

The result 251 generated from multiplication and summation of the most significant bits 201, 211, . . . , 221 of the inputs (e.g., 280) can be applied an operation of left shift 261 by one bit; and the operation of add 262 can be applied to the result of the operation of left shift 261 and the result 253 generated from multiplication and summation of the second most significant bits 202, 212, . . . , 222 of the inputs (e.g., 280). The operations of left shift (e.g., 261, 263) can be used to apply weights of the bits (e.g., 201, 202, . . . ) for summation using the operations of add (e.g., 262, . . . , 264) to generate a result 267. Thus, the result 267 is equal to the weights (e.g., 250) in the array 273 of memory cells multiplied by the column of inputs (e.g., 280) respectively and then summed.

A plurality of multiplier-accumulator units 270 can be connected in parallel to operate on a matrix of weights multiplied by a column of multi-bit inputs over a series of time instances T, T1, . . . , T2.

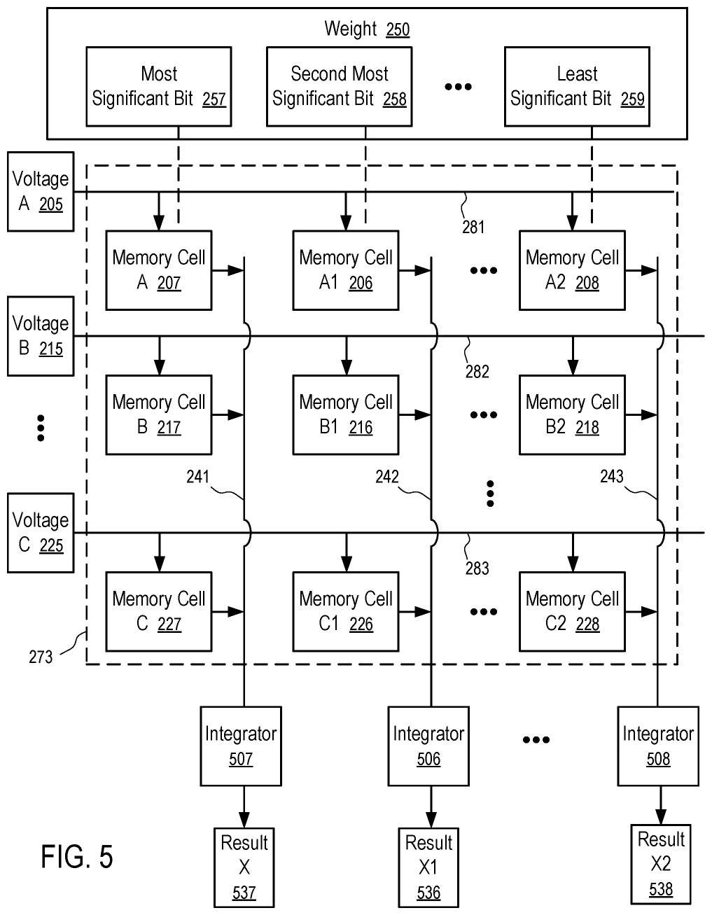

FIG. 5 shows the computation of a column of multi-bit weights 250 multiplied by a column of multi-bit inputs using pulse width modulation (PWM) of the inputs to provide an accumulation result according to one embodiment.

Memory cell array 273 includes various memory cells arranged in columns as illustrated. Each memory cell is programmable to store a respective bit for one of multi-bit weights 250. Each memory cell has a position in the array corresponding to a significance (e.g., MSB, LSB) of its stored respective bit. For example, memory cell 207 is in a column of the array that corresponds to a most significant bit 257, and memory cell 208 is in a column that corresponds to a least significant bit 259, similarly as discussed above.

Voltage drivers are configured to apply voltage pulses to the memory cells. The width of each pulse represents one of the multi-bit inputs (e.g., a pulse has a time length equal to a binary value of each input). Each pulse is applied with a constant voltage for a time corresponding to the pulse width.

For example, a column of voltage drivers 203, 213, . . . , 223 (e.g., as in FIG. 2) can apply, according to the column of multi-bit inputs, voltages 205, 215, . . . , 225 to the column of memory cells 207, 217, . . . , 227 respectively. The voltages are in the form of voltage pulses each having a width representing a respective one of the multi-bit inputs. The voltages are also applied to other columns of the memory cells as illustrated.

A line 241 is coupled to a first column of memory cells each storing a bit of a first significance (e.g., MSB 257). The line 241 is configured to collect output currents from each of these memory cells for accumulating a first electrical charge. For example, output currents from the column of memory cells 207, 217, . . . , 227 are accumulated in an analog form by integrator 507 coupled to line 241.

A line 242 similarly collects output currents from each of a second column of memory cells each storing a bit of second significance less than the first significance (e.g., 2^{nd} MSB 258). Line 242 collects the output currents from these cells for accumulating a second electrical charge. Integrator 506 accumulates these output currents.

A line 243 is coupled to a third column of memory cells each storing a bit of a third significance less than the second significance (e.g., LSB 259). Line 243 collects output currents from each of these memory cells for accumulating a third electrical charge. Integrator 508 accumulates these output currents.

A logic circuit (not shown) is configured to output the final accumulation result determined based on the accumulated first, second, and third charges above. The logic circuit includes shifters and adders (not shown) such as described above to perform shifting and adding of intermediate results to provide the final accumulation result.

In one example, integrators 507, 506, 508 include digitizers that convert the accumulated first, second, and third charges into digital outputs (e.g., Results 537, 536, 538). The digital outputs are shifted and added similarly as described above based on a bit significance corresponding to each digital output. The result of the foregoing shifting and adding is the final accumulation result from the multiplication of the column of multi-bit weights by the column of multi-bit inputs.

In one embodiment, the memory cells are operated in a sub-threshold mode. In one example, the memory cells are chalcogenide or NAND or NOR flash memory cells. The applied voltages are controlled so that the memory cells remain in the sub-threshold mode during the multiplication. It should be noted that operation in a sub-threshold mode for NAND or NOR memory cells is characterized differently than for chalcogenide memory cells.

In one embodiment, each of lines 241, 242, 243 is coupled to a respective capacitor to accumulate the charge from the line.

In one embodiment, a memory device with NAND memory cells uses pulse width modulation (PWM) for performing unsigned multi-bit to multi-bit multiplication. An input voltage pulse (e.g., voltages 205, 215, 225) is applied to multiple memory cells (e.g., 207, 217, 227, 206, 216, 226, etc.) to produce output currents from each memory cell. The width of the voltage pulse (e.g., a length of time between 5 to 100 nanoseconds) is proportional to the respective multi-bit input. The input voltage pulse is a constant voltage (e.g., 2-4 V across each memory cell).

The output current from each memory cell is integrated over time (e.g., by integrators 507, 506, 508) to obtain the input multiplied by the 1-bit weight stored in the respective memory cell. The results from each memory cell can be digitized as a multiple of a predetermined amount of current integrated over a unit of time, corresponding to the width of the voltage pulse for an input of “1”. The digitized outputs (e.g., Results 537, 536, 538) are shifted according to their positions (e.g., MSB 257, . . . , LSB 259) in the multi-bit weight 250 for summation.

The current integration over time can be implemented via charging a capacitor (not shown) using the output current, or using methods other than a capacitor. In one embodiment, the current integration is performed using any of various types of integrators. In one example, each integrator includes a capacitor to collect charge from a common line (e.g., line 241) while the respective voltage pulses 205, 215, 225 are applied to the memory cells (e.g., 207, 217, 227) having outputs connected to the common line.

The multiplier-accumulator units (e.g., 270) illustrated in FIGS. 2-5 can be implemented in integrated circuit device 101 in FIG. 1.

In one implementation, a memory chip (e.g., integrated circuit die 105) includes circuits of voltage drivers, digitizers, shifters, and adders to perform the operations of multiplication and accumulation. The memory chip can further include control logic configured to control the operations of the drivers, digitizers, shifters, and adders to perform the operations as in FIGS. 2-5.

The inference logic circuit 123 can be configured to use the computation capability of the memory chip (e.g., integrated circuit die 105) to perform inference computations of an application, such as the inference computation of an artificial neural network. The inference results can be stored in a portion of the memory cell array 113 for retrieval by an external device via the interface 125 of the integrated circuit device 101.

Optionally, at least a portion of the voltage drivers, the digitizers, the shifters, the adders, and the control logic can be configured in the integrated circuit die 109 for the logic chip.

The memory cells (e.g., memory cells of array 113) can include volatile memory, or non-volatile memory, or both. Examples of non-volatile memory include flash memory, memory units formed based on negative-and (NAND) logic gates, negative-or (NOR) logic gates, phase-change memory (PCM), magnetic memory (MRAM), resistive random-access memory, cross point storage and memory devices. A cross point memory device can use transistor-less memory elements, each of which has a memory cell and a selector that are stacked together as a column. Memory element columns are connected via two layers of wires running in perpendicular directions, where wires of one layer run in one direction in the layer located above the memory element columns, and wires of the other layer are in another direction and in the layer located below the memory element columns. Each memory element can be individually selected at a cross point of one wire on each of the two layers. Cross point memory devices are fast and non-volatile and can be used as a unified memory pool for processing and storage. Further examples of non-volatile memory include read-only memory (ROM), programmable read-only memory (PROM), erasable programmable read-only memory (EPROM) and electronically erasable programmable read-only memory (EEPROM) memory, etc. Examples of volatile memory include dynamic random-access memory (DRAM) and static random-access memory (SRAM).

The integrated circuit die 105 and the integrated circuit die 109 can include circuits to address memory cells in the memory cell array 113, such as a row decoder and a column decoder to convert a physical address into control signals to select a portion of the memory cells for read and write. Thus, an external device can send commands to the interface 125 to write weights (e.g., 250) into the memory cell array 113 and to read results from the memory cell array 113.

In some implementations, the image processing logic circuit 121 can also send commands to the interface 125 to write images into the memory cell array 113 for processing.

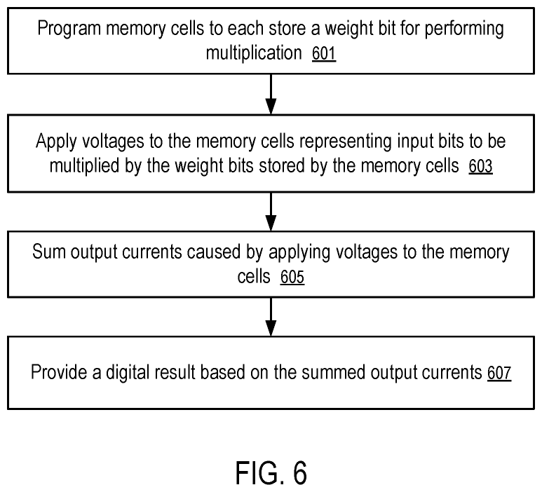

FIG. 6 shows a method of computation in an integrated circuit device according to one embodiment. For example, the method of FIG. 6 can be performed in an integrated circuit device 101 of FIG. 1 using multiplication and accumulation techniques of FIGS. 2-4.

The method of FIG. 6 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 6 is performed at least in part by one or more processing devices (e.g., a controller 124 of inference logic circuit 123 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 601, memory cells are each programmed to store a weight bit for performing multiplication. In one example, memory cells of memory cell array 113 are programmed. In one example, memory cells 207, 206, 208 are programmed to store weight bits of different bit significance. The weight bits correspond to a multi-bit weight 250.

At block 603, voltages are applied to the memory cells. The voltages represent input bits to be multiplied by the weight bits stored by the memory cells. In one example, voltage drivers apply input voltages 205, 215, 225.

At block 605, output currents from the memory cells caused by applying the voltages are summed. In one example, the output currents are collected and summed using line 241 as in FIG. 3.

At block 607, a digital result based on the summed output currents is provided. In one example, the summed output currents are used to generate Result X 237 of FIG. 3.

In one embodiment, a device comprises: a memory cell array (e.g., 113) having memory cells, wherein each memory cell is programmable to store a respective weight for performing a multiplication; voltage drivers (e.g., 115) configured to apply voltages to the memory cells for performing the multiplication, the voltages representing an input to be multiplied by the respective weight for each memory cell, wherein the voltages are applied so that operation of the memory cells remains in a sub-threshold mode during the multiplication; a line coupled to the memory cells, wherein the line is configured to sum output currents from each of the memory cells; and a digitizer (e.g., current digitizer 117) configured to generate a result for the multiplication based on the summed output currents.

In one embodiment, the line is a bitline.

In one embodiment, the memory cells do not threshold (e.g., do not snap) when operating in the sub-threshold mode.

In one embodiment, each memory cell is configured to output: a predetermined amount of current in response to an applied voltage when the memory cell has a threshold voltage programmed to represent a value of one; or a negligible amount of current in response to the applied voltage when the memory cell has a threshold voltage programmed to represent a value of zero.

In one embodiment, the negligible amount of current is less than five percent of the predetermined amount of current.

In one embodiment, some of the memory cells have a first threshold voltage programmed to represent a value of one, and the applied voltage is less than the first threshold voltage.

In one embodiment, the applied voltage is less than the first threshold voltage by at least 0.5 volts.

In one embodiment, the device further comprises an interface (e.g., 125) operable for a host system to write data into the memory cell array and to read data from the memory cell array.

In one embodiment, the memory cells include first and second memory cells; the respective weight stored by the first memory cell is a most significant bit (MSB) of a multi-bit weight; and the respective weight stored by the second memory cell is a least significant bit (LSB) of the multi-bit weight.

In one embodiment, the digitizer is configured in an analog-to-digital converter.

In one embodiment, each of the memory cells is a chalcogenide memory cell.

In one embodiment, a method comprises: programming memory cells in a memory cell array, wherein each memory cell is programmed to store a respective weight bit for performing a multiplication; applying voltages to the memory cells for performing the multiplication, each respective voltage representing a respective input bit to be multiplied by the respective weight bit for each memory cell, wherein the voltages are limited so that operation of the memory cells remains in a sub-threshold mode; summing output currents caused by applying the voltages to the memory cells; and providing a digital result based on the summed output currents.

In one embodiment, the respective input bits are a column of input bits; the respective weight bits are a column of weight bits, which is multiplied by the column of input bits when performing the multiplication; the output currents from the memory cells are summed in a bitline; and the digital result is provided by digitizing the summed output currents as a multiple of a predetermined amount of current.

In one embodiment, each respective memory cell is programmed to have a threshold voltage at: a first level to represent a first value of one; and a second level, higher than the first level, to represent a second value of zero; wherein the respective memory cell is configured to, when a predetermined read voltage between the first level and the second level is applied to the memory cell, output the predetermined amount of current when storing the first value of one, or output a negligible amount of current when storing the second value of zero.

In one embodiment, when the respective input bit is zero, a voltage lower than the first level is applied to the corresponding memory cell; and when the respective input bit is one, the predetermined read voltage is applied to the corresponding memory cell.

In one embodiment, an apparatus comprises: a memory cell array comprising memory cells, wherein each memory cell is programmable to store a respective bit for a multi-bit weight, and each memory cell has a position in the array corresponding to a significance (e.g., MSB, LSB) of its stored respective bit; voltage drivers configured to apply respective voltages to the memory cells, wherein each respective voltage represents a one-bit input, and wherein the voltages are applied so that the memory cells do not threshold; a first line coupled to first memory cells storing a respective bit of a first significance (e.g., MSB), wherein the first line is configured to sum first output currents from each of the first memory cells; a second line coupled to second memory cells storing a respective bit of a second significance (e.g., LSB), wherein the second significance is less than the first significance, and the second line is configured to sum second output currents from each of the second memory cells; and a logic circuit configured to provide an accumulation result (e.g., Result Y 251 of FIG. 3) based on the summed first output currents and the summed second output currents.

In one embodiment, the apparatus further comprises: at least one digitizer configured to provide a first result (e.g., Result X 237) based on the summed first output currents, and provide a second result (e.g., Result X2 238) based on the summed second output currents; at least one shifter configured to at least shift the first result (e.g., left shift the MSB result); and at least one adder configured to provide the accumulation result by at least adding the shifted first result to the second result.

In one embodiment, the first result is left shifted by one bit.

In one embodiment, the accumulation result is from multiplication of a column of multi-bit weights by a column of input bits.

In one embodiment, the memory cells are phase-change memory cells.

In one embodiment, an apparatus comprises: a memory cell array comprising memory cells, wherein each memory cell is programmable to store a respective bit for a multi-bit weight, and each memory cell has a position in the array corresponding to a significance (e.g., MSB, LSB) of its stored respective bit; and a multiplier-accumulator unit configured to perform a multiplication of the multi-bit weight by a multi-bit input and provide an accumulation result, wherein: the memory cells remain in a sub-threshold mode (e.g., cells do not threshold) during the multiplication; each bit of the multi-bit input is applied to the multiplier-accumulator unit at a respective time instance (e.g., T, T1, T2 as in FIG. 4) to obtain a respective result (e.g., Result Y 251), wherein the respective result is based on summing output currents from the memory cells; and the accumulation result (e.g., Result 267) is based on the respective results obtained from applying the bits of the multi-bit input.

In one embodiment, summing the output currents comprises summing currents on lines for columns of memory cells in the memory cell array to provide column results for the applied bit.

In one embodiment, the multiplier-accumulator unit (e.g., 270) comprises shifters and adders configured to combine the column results to provide the respective result for each applied bit.

In one embodiment, each respective result is shifted left according to a position of the applied bit of the multi-bit input to provide shifted results; and the shifted results are added to provide the accumulation result.

In one embodiment, an apparatus comprises: a memory cell array (e.g., 273) comprising memory cells, wherein each memory cell is programmable to store a respective bit for a multi-bit weight (e.g., 250), and each memory cell has a position in the array corresponding to a significance (e.g., MSB, LSB) of its stored respective bit; voltage drivers configured to apply voltage pulses to the memory cells, wherein a respective width (e.g., 20 or 40 nanoseconds) of each pulse represents a multi-bit input; a first line (e.g., 241) coupled to first memory cells storing a bit of a first significance (e.g., MSB), wherein the first line is configured to collect first output currents from each of the first memory cells for accumulating a first charge; a second line (e.g., 243) coupled to second memory cells storing a bit of a second significance (e.g., LSB), wherein the second significance is less than the first significance, and the second line is configured to collect second output currents from each of the second memory cells for accumulating a second charge; and a logic circuit configured to output a result based on the accumulated first charge and the accumulated second charge.

In one embodiment, the memory cells remain in a sub-threshold mode while the voltage pulses are applied.

In one embodiment, the apparatus further comprises a first capacitor coupled to the first line to accumulate the first charge, and a second capacitor coupled to the second line to accumulate the second charge.

In one embodiment, the apparatus further comprises at least one digitizer to provide a first result based on the accumulated first charge, and a second result based on the accumulated second charge, wherein the result from the logic circuit is determined at least based on shifting the first result and adding the shifted first result to the second result.

In one embodiment, each voltage pulse has the same constant voltage.

In one embodiment, the apparatus further comprises at least one integrator (e.g., integrators 507, 506, 508) to provide a first result based on the accumulated first charge and a second result based on the accumulated second charge, wherein the result from the logic circuit is based on the first and second results.

In one example, each respective memory cell (e.g., 207, 217, . . . , or 227) in the column of memory cells 207, 217, . . . , 227 can be programmed to have a threshold voltage at: a first level to represent a first value of one; and a second level, higher than the first level, to represent a second value of zero. When applying a predetermined read voltage between the first level and the second level, the respective memory cell (e.g., 207, 217, . . . , or 227) is configured to output the predetermined amount of current 232 when storing the first value of one or to output a negligible amount of current when storing the second value of zero. The resistance of the memory cell (e.g., 207, 217, . . . , or 227) is nonlinear in a voltage range including its threshold voltage.

When a respective input bit (e.g., 201, 211, . . . , or 221) corresponding to the respective memory cell (e.g., 207, 217, . . . , or 227) is zero, the voltage driver 203 connected to the respective memory cell (e.g., 207, 217, . . . , or 227) applies a voltage lower than the first level to the respective memory cell (e.g., 207, 217, . . . , or 227), resulting a negligible amount of current (e.g., 209, 219, . . . , or 229) from the respective memory cell (e.g., 207, 217, . . . , or 227). When the respective input bit (e.g., 201, 211, . . . , or 221) corresponding to the respective memory cell (e.g., 207, 217, . . . , or 227) is one, the predetermined read voltage between the first level and the second level is applied to the respective memory cell (e.g., 207, 217, . . . , or 227), resulting the predetermined amount of current 232 from the respective memory cell (e.g., 207, 217, . . . , or 227) when the respective memory cell (e.g., 207, 217, . . . , or 227) is storing the first value of one, or negligible amount of current when the respective memory cell (e.g., 207, 217, . . . , or 227) is storing the second value of one.

In one example, the interface 125 can be operable for a host system to write data into the memory cell array 113 and to read data from the memory cell array 113. For example, the host system can send commands to the interface 125 to write the weight matrices of the artificial neural network into the memory cell array 113 and read the output of the artificial neural network, the raw image data from the image sensing pixel array 111, or the processed image data from the image processing logic circuit 121, or any combination thereof.

The inference logic circuit 123 can be programmable and include a programmable processor, an application-specific integrated circuit (ASIC), or a field-programmable gate array (FPGA), or any combination thereof. Instructions for implementing the computations of the artificial neural network can also be written via the interface 125 into the memory cell array 113 for execution by the inference logic circuit 123.

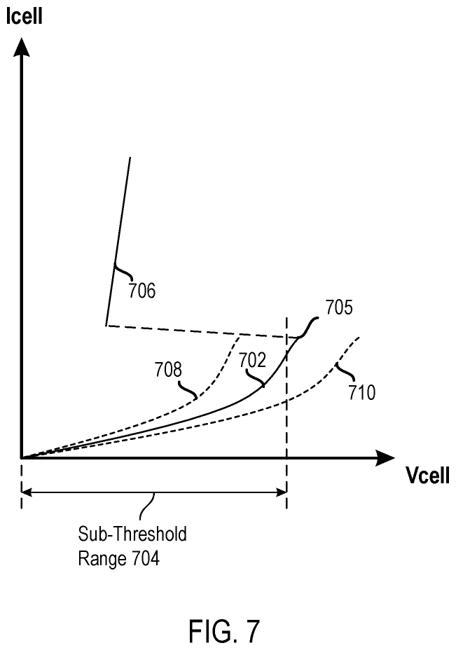

FIG. 7 shows an exemplary current-voltage (IV) curve 702 for a resistive memory cell according to one embodiment. The memory cell is for example a resistive random access memory (RRAM) cell using a chalcogenide memory element. In one example, the memory cell is configured in memory cell array 113 of FIG. 1.

The memory cell is a two terminal element having a voltage Vcell applied across its terminals. When performing multiplication as described above, the memory cell is operated in a sub-threshold range 704 that is below a threshold point 705 of the memory cell. Sub-threshold range 704 corresponds to a resistive regime of operation for the memory cell.

At threshold point 705, there is a transition of the memory cell from a state of low conductance to significantly high conductance, as illustrated in portion 706 of the IV curve. This transition is sometimes referred to as a snapping or a snap-back of the cell.

When performing multiplication, the memory cell is kept in sub-threshold range 704 below its threshold voltage. Otherwise, the significantly higher currents associated with portion 706 of the IV curve would interfere with proper operation for the multiplication.

IV curves 708, 710 illustrate variations in the IV curve that can be introduced by programming the memory cell. It should be noted that not all RRAM memory cells will exhibit the snap-back behavior described above.

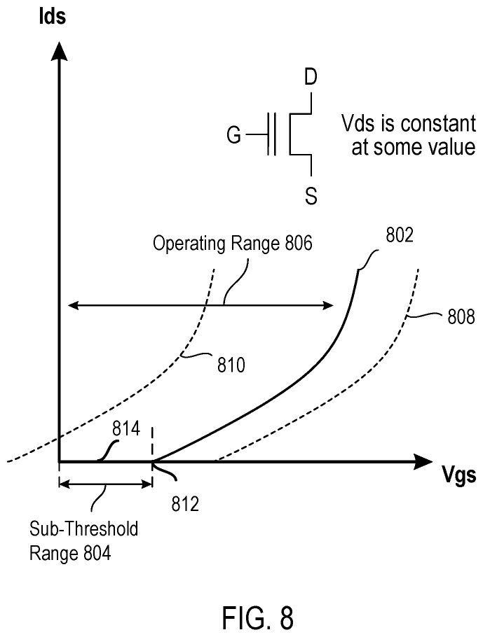

FIG. 8 shows an exemplary current-voltage (IV) curve 802 for a floating gate or charge trap memory cell according to one embodiment. In one example, the memory cell is a NAND or NOR flash memory cell. In one example, the memory cell is configured in memory cell array 113.

The memory cell is a three-terminal element. IV curve 802 corresponds to a characteristic of the cell when applying a constant drain source voltage Vds across the current terminals of the memory cell. A gate voltage Vgs is applied to the gate of the memory cell. The memory cell generally operates in operating range 806, which includes sub-threshold range 804. Portion 814 of the IV curve corresponds to operation in range 804.

The memory cell exhibits a threshold voltage 812. When performing multiplication as described above, the gate voltage can be below and/or above threshold voltage 812.

IV curves 808, 810 illustrate how the location of IV curve 802 can be varied by programming to shift the curve left or right. By programming the memory cell, the threshold voltage 812 can be moved to lower or higher voltages to represent different logic states.

In one example, a wordline voltage is applied to the gate of the memory cell. In one example, the drain of the memory cell is coupled to a digit line, and the source of the memory cell is coupled to a source line (e.g., an SRC line of a NAND flash memory device).

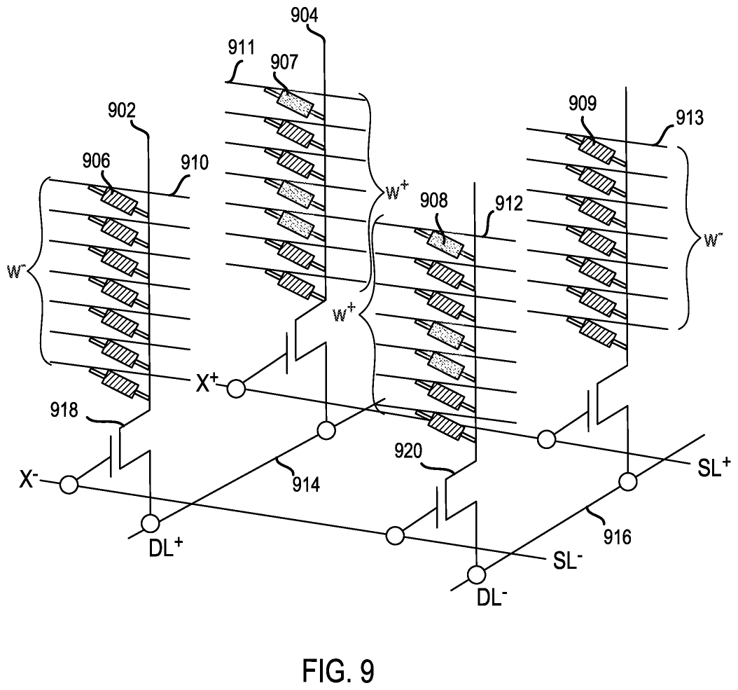

FIG. 9 shows a three-dimensional memory cell array having resistive random-access memory (RRAM) cells according to one embodiment. The memory cell array also can be considered to have a NOR configuration with memory cells connected in parallel. The memory cell array illustrated in FIG. 9 is an example of memory cell array 113 of FIG. 1.

The array includes memory cells arranged in various vertical pillars with each cell in a pillar connected to a vertical bitline 902, 904. The array is located above a semiconductor substrate (not shown). The memory cells are also arranged as horizontal tiers. For example, one of the tiers includes memory cells 906, 907, 908, 909. The tiers are stacked vertically. As an example, seven tiers or levels of memory cells are illustrated in FIG. 9.

Each of the cells is connected to a wordline that extends horizontally. Each memory cell is biased by applying a voltage to one of the wordlines and one of the bitlines to which the cell is connected.

When performing multiplication, memory cells in one of the tiers are selected. For example, memory cells 906, 907, 908, 909 are selected by applying a voltage to wordlines 910, 911, 912, 913.

In one embodiment, wordline portions 910, 912 are connected as a single wordline. Similarly, wordline portions 911, 913 are connected as a single wordline.

Each bitline 902, 904 of a pillar is connected to a digit line 914, 916 using a select transistor 918, 920. When performing multiplication, output currents from the selected memory cells of a tier are accumulated on digit lines 914, 916. In some embodiments, an additional distinct select transistor (selector) may be desired at each memory cell location. The selector is connected in series with the corresponding memory cell. In some embodiments of a resistive array, multiple tiers can be selected at the same time for computation.

In one embodiment, each of the memory cells is programmed to store a weight bit for performing multiplication. For the selected tier of memory cells that will be used for multiplication, a voltage is applied on the wordline of each cell so that each memory cell can contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors 918, 920 using select lines (SL−, SL+). Output currents from the memory cells are then summed on digit lines 914, 916, and a digital result provided, such as discussed above.

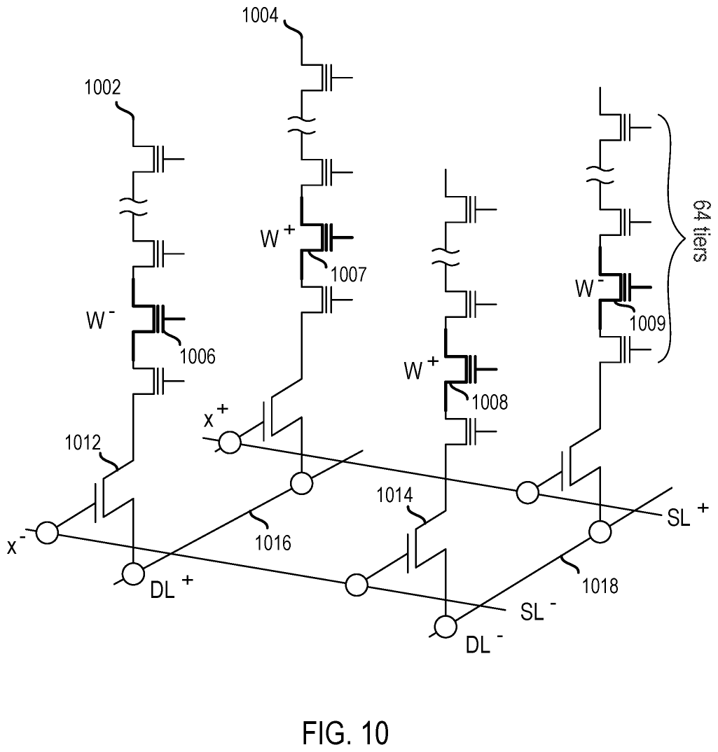

FIG. 10 shows a three-dimensional memory cell array having floating gate or charge trap memory cells in a NAND configuration according to one embodiment. The memory cell array illustrated in FIG. 10 is an example of memory cell array 113.

The memory cells are arranged vertically in pillars with the memory cells in each pillar connected in series as a string 1002, 1004. The memory cells are also arranged in horizontal tiers or levels (e.g., 64 tiers). For example, memory cells 1006, 1007, 1008, 1009 are arranged in one of these tiers. Each string 1002, 1004 is connected to a common source (SRC) line (not shown) and to a digit line 1016, 1018.

When performing multiplication, the memory cells in one of the tiers are selected (e.g., memory cells 1006, 1007, 1008, 1009 are selected). The cells are selected by applying a read voltage to a gate of each cell. The other non-selected cells in a same string with a selected memory cell are biased by applying a bypass voltage to the gates of the non-selected cells.

Each of the memory cells is connected to a wordline (not shown) that is used to apply the read or bypass voltage above. In one example, a common wordline (not shown) is connected to the gates of memory cells 1006, 1007, 1008, 1009. The common wordline is biased by applying a read voltage.

The memory cells of each string 1002, 1004 are electrically coupled to digit lines 1016, 1018 by select transistors 1012, 1014. Digit lines 1016, 1018 are sometimes referred to as bitlines when configured in a NAND flash memory device.

In one example, one of the tiers of the memory cell array is selected. The non-selected memory cells in the other tiers are disabled. The wordline voltage is made high enough so that each non-selected memory cell is conductive regardless of its programming state (thus, the state of the bypassed cells is ignored as the cells will conduct current regardless of logic state). The overall resistance in each string is dominated by the one selected memory cell, which provides an output current used for accumulation.

In one embodiment, each of the memory cells is programmed to store a weight bit for performing multiplication. For the selected tier of memory cells that will be used for multiplication, a voltage is applied on the wordline so that each memory cell is able to contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors 1012, 1014 using select lines (SL). Output currents from the memory cells are then summed on digit lines 1016, 1018, and a digital result provided, such as discussed above.

In one embodiment, the gate of each memory cell 1006, 1007, 1008, 1009 is connected to a separate, segmented wordline. In one embodiment, the gate of each memory cell is connected to a single conductive layer or sheet that acts as a wordline for all selected cells.

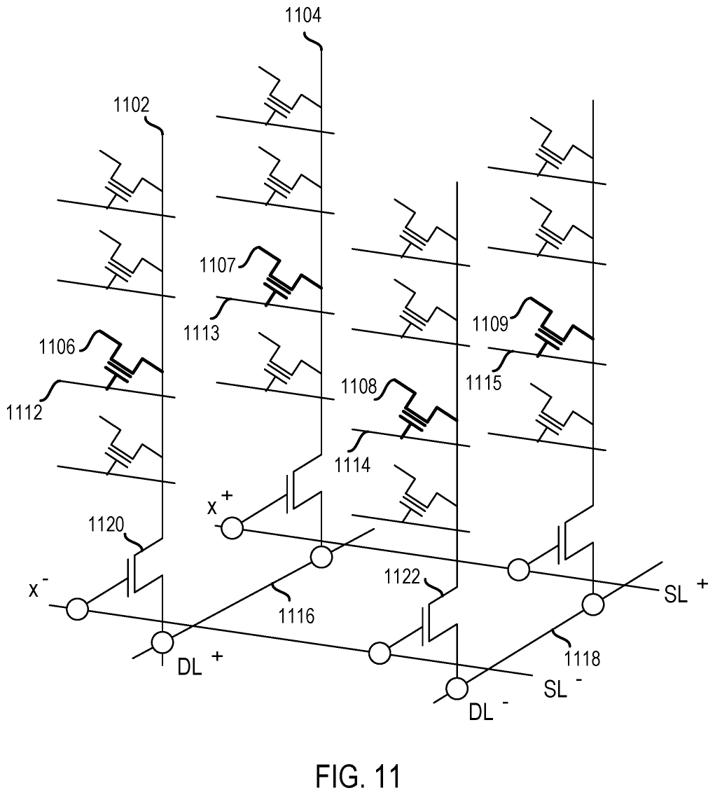

FIG. 11 shows a three-dimensional memory cell array having floating gate memory cells in a NOR configuration according to one embodiment. The memory cells are connected in parallel. The memory cell array illustrated in FIG. 11 is an example of memory cell array 113.

Similarly as discussed above, the memory cells are arranged in horizontal tiers. One of the tiers is selected for performing multiplication. For example, memory cells 1106, 1107, 1108, 1109 are selected by applying a gate voltage to each cell. The voltage is applied using wordlines 1112, 1113, 1114, 1115.

In one embodiment, wordlines 1112 and 1114 are connected as a single line. Wordlines 1113 and 1115 are also connected as a single line.

The memory cells of the array are arranged in pillars each having a vertical conducting line 1102, 1104. Each vertical conducting line is coupled to a digit line 1116, 1118 by select transistors 1120, 1122.

In one embodiment, each of the memory cells is programmed to store a weight bit for performing multiplication. For the selected tier of memory cells that will be used for multiplication, a voltage is applied on the wordline so that each memory cell can contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors 1120, 1122 using select lines (SL). Output currents from the memory cells are then summed on digit lines 1116, 1118, and a digital result provided, such as discussed above.

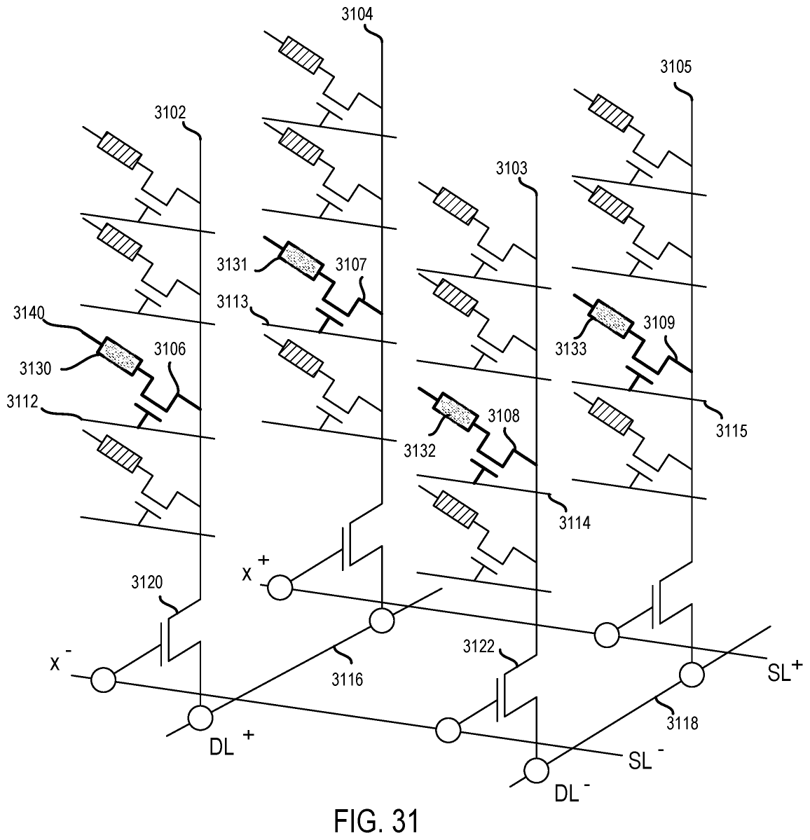

FIG. 31 shows a three-dimensional memory cell array having memory cells arranged in a parallel configuration with individual selectors according to one embodiment. Each memory cell has its own selector connected in series so that each memory cell can be selected individually as desired for a particular multiplication or other operation. For example, the memory cells are connected in parallel as illustrated in FIG. 31. The memory cell array illustrated in FIG. 31 is an example of memory cell array 113.

Similarly as discussed above, the memory cells are arranged in horizontal tiers. One of the tiers is selected for performing, for example, multiplication. For example, memory cells 3130, 3131, 3132, 3133 are selected and a voltage is applied to each cell. In one embodiment, the voltage is applied across the memory cells using wordlines 3112, 3113, 3114, 3115 by turning on or off individual select transistors 3106, 3107, 3108, 3109 for each cell.

In one embodiment, wordlines 3112 and 3114 are connected as a single line. Wordlines 3113 and 3115 are also connected as a single line.

The memory cells of the array are arranged in pillars (e.g., columns or strings of chalcogenide memory cells) each having a vertical conducting line 3102, 3103, 3104, 3105 connected to memory cells of the pillar (e.g., to accumulate output currents). Each vertical conducting line is coupled to a digit line 3116, 3118 by select transistors 3120, 3122.

In one embodiment, each of the memory cells is programmed to store a weight bit for performing multiplication. For the selected tier of memory cells that will be used for multiplication, a voltage is applied on the wordline so that each memory cell can contribute an extent of output current that is dependent on the programming state of the memory cell.

In one embodiment, memory cells on multiple tiers can be selected. For example, two or more of the memory cells connected to common vertical conducting line 3102 can be selected for performing multiplication.

Voltages are applied to the memory cells when performing multiplication, such as for example discussed above. The applied voltages represent input bits to be multiplied by the weight bits stored by the memory cells. In one embodiment, the voltages are applied to gates of individual select transistors and each gate corresponds to the input for the corresponding memory cell. Output currents from the memory cells are then summed on digit lines 3116, 3118, and a digital result is provided, such as for example discussed above.

The terminal of each memory cell (e.g., 3140) not connected to its corresponding individual selector is connected to a biasing source. In one example, the biasing source applies a fixed voltage during multiplication.

In one embodiment, each memory cell in the array of FIG. 31 is a resistive random-access memory (RRAM) cell (e.g., operating in a sub-threshold range as described above). In one example, the memory cell array can be considered to have a NOR configuration with memory cells connected in parallel.

In one example, the array includes memory cells arranged in various vertical pillars with each cell in a pillar connected to a vertical bitline (e.g., 3102, 3104). The array is located above a semiconductor substrate (not shown).

Each of the cells is connected to a wordline that extends horizontally. Each memory cell is biased by applying a voltage to one of the wordlines to turn on an individual selector and one of the bitlines to which that cell is connected.

Voltages are applied to the memory cells when performing multiplication, such as discussed above. In one embodiment, the applied voltages represent input bits to be multiplied by the weight bits stored by the memory cells.

In one embodiment, multiplication operations are performed by a controller using the array of FIG. 31 in a similar way as done for a NOR configuration of memory cells (e.g., using the array of FIG. 11).

In one embodiment, a device comprises: a memory cell array having memory cells, wherein each memory cell is programmable to store a respective weight for performing a multiplication; voltage drivers configured to apply voltages to the memory cells for performing the multiplication, the voltages representing an input to be multiplied by the respective weight for each memory cell; at least one line coupled to the memory cells, wherein the line is configured to sum output currents from each of the memory cells; and a digitizer configured to generate a result for the multiplication based on the summed output currents.

In one embodiment, each memory cell is programmable to vary a conductance or resistance of the memory cell, and an extent of the output current from the memory cell corresponds to the conductance or resistance.

In one embodiment, the at least one line includes a bitline.

In one embodiment, the memory cells are organized in horizontal tiers of cells, the tiers are stacked vertically above a semiconductor substrate, and first memory cells in a first tier are selected and coupled to the line for performing the multiplication.

In one embodiment, the memory cells are resistive random access memory (RRAM) cells with a local selector, RRAM cells without a local selector, NAND flash memory cells, or NOR flash memory cells.

In one embodiment, the memory cells are programmable by varying charge stored in a floating gate or a charge trap of each memory cell.

In one embodiment, the memory cells are programmable by varying a resistance of each memory cell.

In one embodiment, the memory cells are further organized in pillars of memory cells, and the respective memory cells in each pillar are connected by a respective vertical bitline.

In one embodiment, the respective vertical bitline is coupled to a digit line by a select transistor.

In one embodiment, the respective memory cells in each pillar are connected in series as a string of cells.

In one embodiment, the respective memory cells in each pillar are connected in parallel.

In one embodiment, each memory cell has a floating gate, and the memory cells are arranged in a NOR configuration.

In one embodiment, each memory cell has a floating gate or charge trap, and the memory cells are arranged in a NAND configuration.

In one embodiment, the at least one line comprises digit lines that extend horizontally; the digit lines are located above the semiconductor substrate; and the first memory cells are coupled to the digit lines by select transistors.

In one embodiment, each memory cell is connected to a wordline that extends horizontally, and the memory cell is selected for performing the multiplication by applying a voltage to the wordline.

In one embodiment, the memory cell array is a three-dimensional cross-point array; the memory cells are arranged in vertical pillars; the at least one line extends horizontally; and the at least one line connects to at least a portion of the pillars.

In one embodiment, the memory cells do not snapback.

In one embodiment, operation of the memory cells in the sub-threshold mode comprises operating the memory cells in a resistive regime.

In one embodiment, each memory cell is configured to output: a predetermined amount of current in response to an applied voltage when the memory cell has a threshold voltage programmed to represent a value of one; or a negligible amount of current in response to the applied voltage when the memory cell has a threshold voltage programmed to represent a value of zero.

In one embodiment, the negligible amount of current is less than five percent of the predetermined amount of current.

In one embodiment, some of the memory cells have a first threshold voltage programmed to represent a value of one, and the applied voltage is less than the first threshold voltage.

In one embodiment, the applied voltage is less than the first threshold voltage by at least 0.5 volts.

In one embodiment, the device further comprises an interface operable for a host system to write data into the memory cell array and to read data from the memory cell array.

In one embodiment, the memory cells include first and second memory cells; the respective weight stored by the first memory cell is a most significant bit (MSB) of a multi-bit weight; and the respective weight stored by the second memory cell is a least significant bit (LSB) of the multi-bit weight.

In one embodiment, the digitizer is configured in an analog-to-digital converter.

In one embodiment, each of the memory cells is a chalcogenide memory cell; and the voltages are applied to keep operation of the memory cells in a sub-threshold mode during the multiplication.

In one embodiment, a method comprises: programming memory cells in a memory cell array, wherein each memory cell is programmed to store a respective weight bit for performing a multiplication; applying voltages to the memory cells for performing the multiplication, each respective voltage representing a respective input bit to be multiplied by the respective weight bit for each memory cell, wherein the voltages are limited to keep operation of the memory cells in a sub-threshold mode; summing output currents caused by applying the voltages to the memory cells; and providing a digital result based on the summed output currents.

In one embodiment, the respective input bits are a column of input bits; the respective weight bits are a column of weight bits, which is multiplied by the column of input bits when performing the multiplication; the output currents from the memory cells are summed in a bitline; and the digital result is provided by digitizing the summed output currents as a multiple of a predetermined amount of current.

In one embodiment, each respective memory cell is programmed to have a threshold voltage at: a first level to represent a first value of one; and a second level, higher than the first level, to represent a second value of zero; wherein the respective memory cell is configured to, when a predetermined read voltage between the first level and the second level is applied to the memory cell, output the predetermined amount of current when storing the first value of one, or output a negligible amount of current when storing the second value of zero.

In one embodiment, when the respective input bit is zero, a voltage lower than the first level is applied to the corresponding memory cell; and when the respective input bit is one, the predetermined read voltage is applied to the corresponding memory cell.

Various embodiments related to memory devices for performing signed multiplication using logical states of memory cells are now described below. The generality of the following description is not limited by the various embodiments described above.

Various memory cell implementations can be used for performing signed multiplication. In one embodiment, the signed multiplication is performed in a so-called four-quadrant system, in which each of an input and a weight to be multiplied can have a positive or negative sign. For example, some neural network models make use of matrix vector multiplication in which the weights of the model are signed. In one example, resistive random-access memory (RRAM) cells are used. In one example, NAND or NOR flash memory cells are used.

In one embodiment, matrix vector multiplication is performed using stored weights. Input signals are multiplied by the weights to provide a result. In one example, the weights are determined by training a neural network model. The model uses both positive and negative values for the weights. In one example, the weights are stored in memory cells of memory cell array 113 of FIG. 1. In one example, the model is trained using image data, and the trained model provides inference results based on inputs from an image sensor.

In one embodiment, a multiplier accumulator unit uses signed multiplication.

Weights may be represented by multi-bit values (e.g., 8-64 bits). An extra bit is used to represent the sign of a weight value. For example, a system may use 8 bit signed weights, where values of the weights are represented by seven bits, and the eighth bit is used to represent the sign. An extra bit can be used in a similar manner for signed inputs.

In one embodiment, a signed 1-bit number (e.g., an input and/or weight) has one of three possible values: −1, 0, 1. For example, a signed weight can be represented by a 2-bit number, where a 2-bit value of 01 represents a signed 1-bit value of −1; a 2-bit value of 00 represents a signed 1-bit value of 0; and a 2-bit value of 10 represents a signed 1-bit value of +1. The 2-bit value of 11 is not used. In other examples, the various combinations of the 2 bits can represent different signed values, as may be desired for a given implementation.

In one example, a controller that controls multiplications manages the two bit values by keeping track of the meaning represented by each bit (e.g., sign or magnitude). In one example, the controller is part of inference logic circuit 123 of FIG. 1.

1-bit by 1-bit multiplications of the two-bit numbers representing the signed 1-bit input and the signed 1-bit weight can be configured to produce a result for signed 1-bit to 1-bit multiplication. In one example, the result has been determined in response to a request from a host system over interface 125 of FIG. 1. In one example, the signed inputs used to produce the result are based on data collected by image sensing pixel array 111 of FIG. 1.

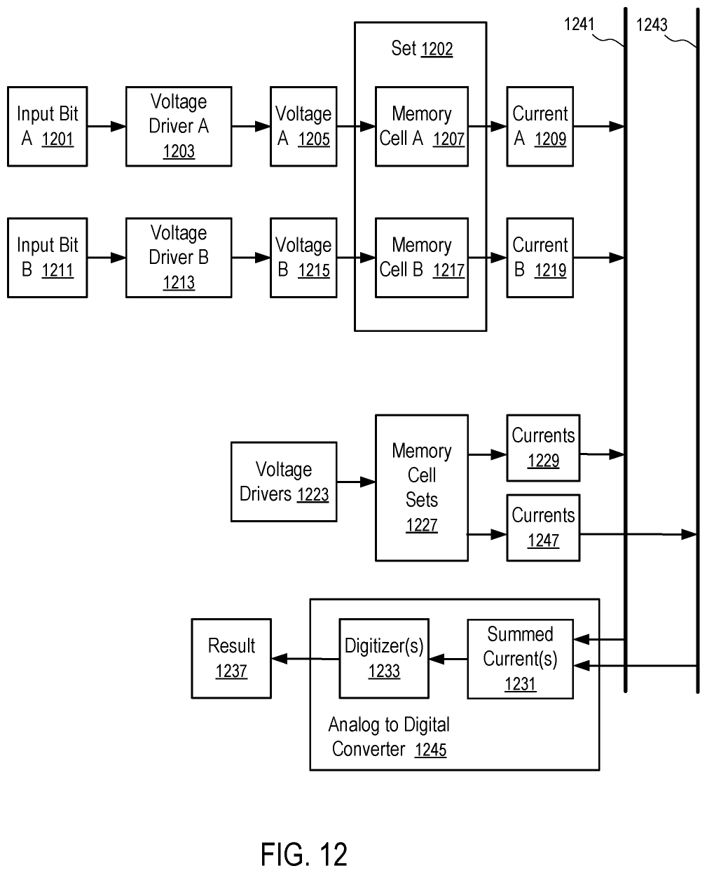

FIG. 12 shows sets of memory cells storing signed weights used for multiplication according to one embodiment. In one example, the memory cells are configured in memory cell array 113.

In one embodiment, set 1202 includes memory cells 1207, 1217, which together store two bits of data that represent a 1-bit signed weight. For example, memory cell 1207 stores a 1 and memory cell 1217 stores a 0, which together represent a 1-bit signed weight of +1. In one example, memory cells 1207, 1217 can be programmed to store appropriate values of bits as discussed above.

The 1-bit signed weight is multiplied by a 1-bit signed input, which is represented by two input bits 1201, 1211. For example, input bit 1201 is 0, and input bit 1211 is 1, which together represent a 1-bit signed input of −1.

To perform the multiplication, voltage drivers 1203, 1213 apply voltages 1205, 1215 to memory cells 1207, 1217 in a way that corresponds to the values of input bits 1201, 1211. In one example, voltage drivers 1203, 1213 apply voltages similarly as discussed above for voltage drivers 203, 213.

Currents 1209, 1219 are output from memory cells 1207, 1217 based on the applied voltages 1205, 1215. The currents are summed on a line 1241 to provide a summed current 1231. In one example, the currents are summed similarly as discussed above for line 241.

The result from the signed multiplication will be a signed result represented by two bits. Each of the bits is determined based on summing currents on line 1241. Multiplications for other signed inputs provided to other sets (not shown) of cells can be done similarly as for set 1202. Line 1241 can be used to sum output currents for these other multiplications.

In one embodiment, the two bits of the signed result are determined based on summing currents at two time instances. At a first time instance, summed current 1231 from multiplying input bits 1201, 1211 by the stored weight of set 1202 is digitized by digitizer 1233 of analog to digital converter 1245. This provides the first bit of the result. In one example, analog-to-digital converter 1245 and digitizer 1233 are similar to analog-to-digital converter 245 and digitizer 233.

At a second time instance, input bits 1201, 1211 are inverted to a negative version. For example, input bits of 1,0 are inverted to the negative version of 0,1. Voltages corresponding to the negative version are applied by voltage drivers 1203, 1213 to memory cells 1207, 1217. Currents 1209, 1219 at this second time instance are summed and digitized to provide the second bit of the result.

The first and second bits determined from summing of the first and second time instances above provide result 1237. These two bits correspond to the 1-bit signed result 1237 for the multiplication.

In general, numerous memory cell sets 1227 may be configured in a memory cell array. Set 1202 above has two memory cells. In other embodiments, each set may include four memory cells. Voltage drivers 1223 are used to apply voltages to memory cells in sets 1227. Currents 1229, 1247 are output from these memory cells and can be summed. In one embodiment, the currents are summed on a single line 1241 at various time instances, similarly as discussed above. In one example, the same integrated circuit device can include both sets having two memory cells each, and other sets having four memory cells each. Other combinations of different types of cell sets is possible.

In one embodiment, the currents are summed on more than one line, and each line is used to determine a different bit of the signed result 1237. For example, line 1241 is used to determine a first bit, and line 1243 is used to determine a second bit. In one example, each set contains four memory cells, and lines 1241, 1243 are used to sum currents 1229, 1247 simultaneously. In other words, multiple time instances are not required to determine the two bits of result 1237.

In one embodiment, voltages 1205, 1215 are applied in a controlled manner to keep the memory cells in a sub-threshold mode. In one example, the memory cells are chalcogenide cells, which exhibit a snapback behavior. The chalcogenide cells are kept in the sub-threshold mode to avoid any snapping of the memory cells. The snapping is undesired because of the resulting large cell currents that interfere with proper multiplication.

In one embodiment, memory cells 1207 are NAND or NOR flash memory cells and can be operated above and/or below their threshold voltages during multiplication.

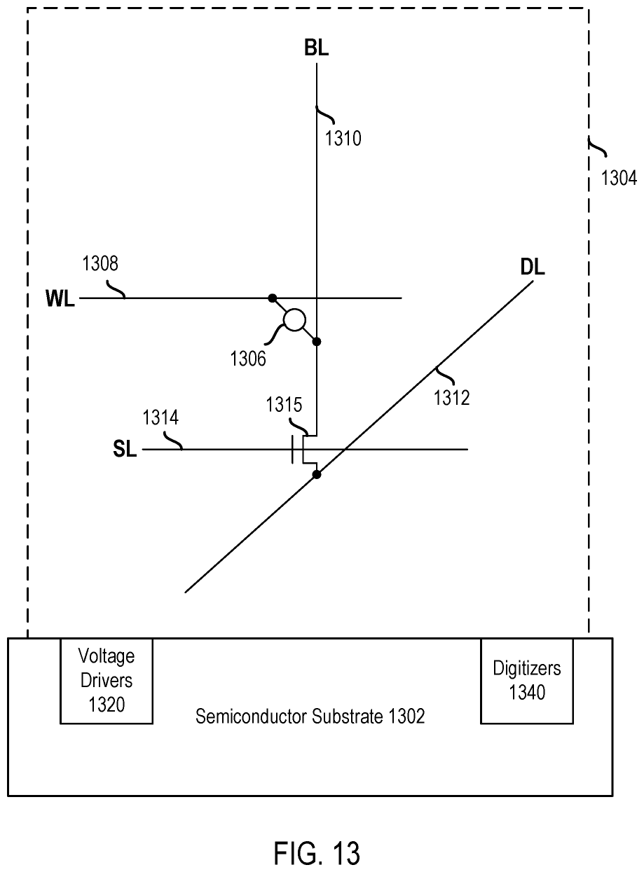

FIG. 13 shows an exemplary memory cell 1306 of a memory array 1304 formed above a semiconductor substrate 1302 according to one embodiment. In one example, the semiconductor substrate 1302 is integrated circuit die 109 of FIG. 1. In one example, memory array 1304 is memory cell array 113 of FIG. 1. In one example, memory cell 1306 is memory cell 1207, 1217.

Memory cell 1306 is one of many memory cells formed in a three-dimensional memory array. Various bitlines 1310 extend in a vertical direction above semiconductor substrate 1302. Various wordlines 1308 extend in a horizontal direction above semiconductor substrate 1302. Various digit lines 1312 extend in a horizontal direction above semiconductor substrate 1302. Bitlines 1310 are coupled to digit lines 1312 by select transistors 1315, which are controlled by applying voltages to the gates of the select transistors 1315 using select lines 1314.

In one embodiment, the memory cells in array 1304 are organized in horizontal tiers of cells. The tiers are stacked vertically above semiconductor substrate 1302. In one example, the memory cells are arranged in horizontal tiers as illustrated in FIG. 9. For example, one of the tiers includes four memory cells 1306 (e.g., 906, 907, 908, 909) that are used as a set to store a signed weight, as discussed above.

Voltage drivers 1320 are used to apply voltages to the memory cells of memory cell array 1304 for performing multiplication. For example, voltage drivers 1320 bias wordline 1308 and bitline 1310 to apply a voltage across memory cell 1306. Bitline 1310 is biased, for example, by driving a voltage on digit line 1312 and turning on select transistor 1315 to connect bitline 1310 to digit line 1312. Examples of voltage drivers 1320 include voltage drivers 1203, 1213, 1223.

Digitizers 1340 generate digital output (e.g., in the form of bits of result 1237 of FIG. 12) based on summed currents from memory array 1304. Examples of digitizers 1340 include digitizers 1233. In one example, currents are summed from various memory cells (not shown other than cell 1306) on a common digit line 1312. In an alternative embodiment, currents can be summed from a common wordline 1308.

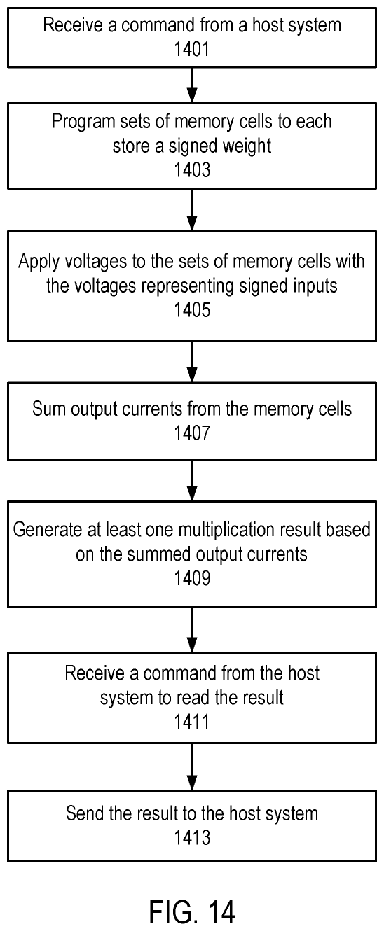

FIG. 14 shows a method for performing signed multiplication using weights stored in sets of memory cells according to one embodiment. For example, the method of FIG. 14 can be performed in an integrated circuit device 101 of FIG. 1 using multiplication and accumulation as illustrated in FIG. 12 and/or FIG. 13.

The method of FIG. 14 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 14 is performed at least in part by one or more processing devices (e.g., a controller of inference logic circuit 123 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 1401, a command is received from a host system. In one example, the command is received by interface 125 of FIG. 1. In one example, the command is a write command to store data in memory cell array 113. In one example, the stored data is signed weights obtained from training a neural network model.

At block 1403, sets of memory cells are programmed so that each set stores a signed weight. In one example, memory cells 1207, 1217 are programmed to store a 1-bit signed weight.

At block 1405, voltages are applied to the sets of memory cells. The voltages represent different signed inputs for each set. In one example, voltage drivers 1203, 1213 apply voltages to memory cells 1207, 1217 in a first set of several sets.

At block 1407, output currents from the memory cells are summed. In one example, output currents from memory cells 1207, 1217 are summed on a bitline or digit line of a three-dimensional memory cell array.

At block 1409, at least one multiplication result is generated based on the summed output currents. In one example, digitizer 1233 generates result 1237.

At block 1411, a command is received from the host system to read the result. In one example, the command is a read command received via interface 125.

At block 1413, the result is sent to the host system. In one example, result 1237 is sent to the host system.

In one embodiment, a device comprises: a semiconductor substrate (e.g., 1302); a plurality of sets (e.g., 1202, 1227) of memory cells, wherein each set of memory cells is programmable to store a signed weight for performing a multiplication, wherein the memory cells are organized in horizontal tiers of cells, and wherein the tiers are stacked vertically above the semiconductor substrate; voltage drivers (e.g., 1223, 1320) configured to apply voltages to the sets of memory cells for performing the multiplication, the voltages representing a signed input to be multiplied by the stored weight for each set; at least one line (e.g., 1241, 1243, 1312) coupled to the memory cells in each set, wherein the line is configured to sum output currents from the memory cells; and at least one digitizer (e.g., 1233, 1340) for each set, the digitizer configured to generate a result based on the summed output currents from the memory cells in the set.

In one embodiment, the voltages are applied so that the memory cells are kept in a sub-threshold mode (e.g., memory cell operates in sub-threshold range 704) during the multiplication.

In one embodiment, the memory cells of each set are configured so that the stored weight has a value of negative one, zero, or positive one.

In one embodiment, the voltages are applied so that the signed input has a value of negative one, zero, or positive one.

In one embodiment, the signed weight and signed input (e.g., the ordered combination of input bits 1201, 1211) are each represented by a respective 2-bit number having possible values of 01, 00, or 10.

In one embodiment, each set represents a 1-bit signed weight; the voltages applied to each set represent a 1-bit signed input; and the result for the set represents a signed multiplication of the 1-bit signed weight by the 1-bit signed input.

In one embodiment, the result is a 2-bit number having a value of 01, 00, or 10.

In one embodiment, a first memory cell of a first set has a first threshold voltage programmed to represent a value of one, and the voltage applied to the first memory cell is less than the first threshold voltage.

In one embodiment, the digitizer is configured in an analog-to-digital converter (e.g., 1245).

In one embodiment, the memory cells are resistive random-access memory (RRAM) cells, NAND flash memory cells, or NOR flash memory cells.

In one embodiment, an apparatus comprises: a memory cell array (e.g., 113) having sets of memory cells; an interface (e.g., 125) operable for a host system to write data into the memory cell array and to read data from the memory cell array; and a controller configured to: program the sets of memory cells to store a signed weight in each set; apply voltages (e.g., 1205, 1215) to the sets of memory cells, the voltages representing signed inputs to be multiplied by the signed weights; determine at least one digital result (e.g., 1237) based on summing output currents from the memory cells in one or more sets; and send, via the interface, the digital result to the host system.

In one embodiment, each memory cell is configured to output either of: a predetermined amount of current in response to an applied voltage when the memory cell has a threshold voltage programmed to represent a value of one; or a negligible amount of current in response to the applied voltage when the memory cell has a threshold voltage programmed to represent a value of zero.

In one embodiment, the negligible amount of current is less than five percent of the predetermined amount of current.

In one embodiment, the voltages are limited so that the memory cells are kept in a sub-threshold mode.

In one embodiment, each memory cell in the memory cell array is programmable to have a threshold voltage at either of: a first level to represent a first value of one; or a second level, higher than the first level, to represent a second value of zero; wherein the memory cell is configured to, when a predetermined read voltage between the first level and the second level is applied to the memory cell, output a predetermined amount of current when storing the first value of one, or output a negligible amount of current when storing the second value of zero.

In one embodiment, when a signed input is zero, a voltage lower than the first level is applied to the corresponding set of memory cells; and when the signed input is positive or negative one, the predetermined read voltage is applied to at least one first memory cell of the corresponding set of memory cells, and the voltage lower than the first level is applied to at least one second memory cell of the corresponding set.

In one embodiment, a method comprises: receiving a command from a host system to write data; in response to receiving the command to write the data, programming sets (e.g., 1227) of memory cells in a memory cell array, wherein each set of memory cells is programmable to store a signed weight for matrix vector multiplication; applying voltages to the sets of memory cells for performing the multiplication, the voltages representing signed inputs to be multiplied by the signed weights; summing, using at least one common line coupled to the memory cells in each set, output currents from the memory cells; generating, using at least one digitizer, at least one result for the multiplication based on the summed output currents from the memory cells; receiving a command from the host system to read the result; and in response to receiving the command to read the result, sending the result to the host system.

In one embodiment, the at least one common line is at least one digit line, and the system further comprises: bitlines coupled to the memory cells in each set; and select transistors configured to electrically connect the bitlines of each set to the at least one digit line.

In one embodiment, the digitizer includes at least one integrator that accumulates current on the at least one common line for each set, and the digitizer provides the result as a binary number.

In one embodiment, the at least one common line is at least one bitline.

In one embodiment, a device comprises: a memory cell array having sets of memory cells, wherein each set of memory cells is programmable to store a signed weight for performing a multiplication; voltage drivers configured to apply voltages to the sets of memory cells for performing the multiplication, the voltages representing a signed input to be multiplied by the stored weight for each set; at least one line coupled to the memory cells in each set, wherein the line is configured to sum output currents from the memory cells; and at least one digitizer for each set, the digitizer configured to generate a result based on the summed output currents from the memory cells in the set.

In one embodiment, the voltages are applied so that the memory cells are kept in a sub-threshold mode during the multiplication.

In one embodiment, the memory cells do not snapback when operating in the sub-threshold mode.

In one embodiment, each set comprises two memory cells.

In one embodiment, each set comprises four memory cells; a first pair of memory cells in the set stores a positive version (e.g., 01) of the signed weight; and a second pair of memory cells in the set stores a negative version (e.g., 10, which is a bit by bit inversion of bits 0 and 1) of the signed weight.

In one embodiment, the memory cells of each set are configured so that the stored weight has a value of negative one, zero, or positive one.

In one embodiment, the voltages are applied so that the signed input has a value of negative one, zero, or positive one.

In one embodiment, the signed weight and signed input are each represented by a respective 2-bit number having possible values of 01, 00, or 10.

In one embodiment, each set represents a 1-bit signed weight; the voltages applied to each set represent a 1-bit signed input; and the result for the set represents a signed multiplication of the 1-bit signed weight by the 1-bit signed input.

In one embodiment, the result is a 2-bit number having a value of 01, 00, or 10.

In one embodiment, the at least one line is at least one digit line, and the system further comprises: bitlines coupled to the memory cells in each set; and select transistors configured to electrically connect the bitlines of each set to the at least one digit line.

In one embodiment, applying voltages to the sets of memory cells comprises applying voltages to gates of the select transistors to cause a change in voltage on the bitlines.

In one embodiment, the digitizer for each set includes an integrator that accumulates current on the at least one line for the set, and the digitizer provides the result as a binary number.

In one embodiment, the at least one line is at least one bitline.

In one embodiment, each memory cell of the memory cell array is configured to output either of: a predetermined amount of current in response to an applied voltage when the memory cell has a threshold voltage programmed to represent a value of one; or a negligible amount of current in response to the applied voltage when the memory cell has a threshold voltage programmed to represent a value of zero.

In one embodiment, the negligible amount of current is less than five percent of the predetermined amount of current.

In one embodiment, a first memory cell of a first set has a first threshold voltage programmed to represent a value of one, and the voltage applied to the first memory cell is less than the first threshold voltage.

In one embodiment, the device further comprises an interface operable for a host system to write data into the memory cell array and to read data from the memory cell array.

In one embodiment, the digitizer is configured in an analog-to-digital converter.

In one embodiment, the memory cells are phase-change memory cells, NAND flash memory cells, or NOR flash memory cells.

In one embodiment, an apparatus comprises: a memory cell array having sets of memory cells; and a controller configured to: program the sets of memory cells to store a signed weight in each set; apply voltages to the sets of memory cells, the voltages representing signed inputs to be multiplied by the signed weights; and determine at least one digital result based on summing output currents from the memory cells in one or more sets.

In one embodiment, the voltages are limited so that operation of the memory cells remains in a sub-threshold mode.

In one embodiment, each memory cell in the memory cell array is programmable to have a threshold voltage at either of: a first level to represent a first value of one; or a second level, higher than the first level, to represent a second value of zero; wherein the memory cell is configured to, when a predetermined read voltage between the first level and the second level is applied to the memory cell, output a predetermined amount of current when storing the first value of one, or output a negligible amount of current when storing the second value of zero.

In one embodiment, when a signed input is zero, a voltage lower than the first level is applied to the corresponding set of memory cells; and when the signed input is positive or negative one, the predetermined read voltage is applied to at least one first memory cell of the corresponding set of memory cells, and the voltage lower than the first level is applied to at least one second memory cell of the corresponding set.

In one embodiment, a method comprises: programming sets of memory cells in a memory cell array, wherein each set of memory cells is programmable to store a signed weight for matrix vector multiplication; applying voltages to the sets of memory cells for performing the multiplication, the voltages representing signed inputs (e.g., inputs based on data collected by image sensing pixel array 111 of FIG. 1) to be multiplied by the signed weights; summing, using at least one common line coupled to the memory cells in each set, output currents from the memory cells; and generating, using at least one digitizer (e.g., current digitizers 117), at least one result for the multiplication based on the summed output currents from the memory cells.

In one embodiment, the voltages are applied so that the memory cells are kept in a sub-threshold mode during the multiplication.

Various embodiments related to memory devices for performing signed multiplication using sets each containing two memory cells are now described below. The generality of the following description is not limited by the various embodiments described above.

In one memory cell implementation, signed multiplication is performed for a memory cell array in which each set has two memory cells (sets organized as pairs of memory cells). In one example, resistive random-access memory (RRAM) cells are used. In one example, NAND or NOR flash memory cells are used.

In one embodiment, a signed 1-bit number (e.g., an input and/or weight) has one of three possible values: −1, 0, 1. For example, a signed weight can be represented by a 2-bit number, as described above. The signed weight can be represented by values stored in a memory cell pair. One bit value can be stored in a first cell of the pair, and a second bit value stored in a second cell of the pair. The two bit values represent the 1-bit signed weight.

In one embodiment, a two-cell implementation is used for signed 1-bit to 1-bit multiplication. Two memory cells of a set are used to store the two bits of the signed 1-bit weight in the two-bit representation.

Two input lines are used to apply the two bits of the signed 1-bit input (two-bit representation) (sometimes referred to herein as a “positive version”) at a first time instance (e.g., a first clock cycle, T0), and then a negative version of the input at a second time instance (e.g., a second clock cycle, T1).

In one example, the input lines provide voltages 1205, 1215 of FIG. 12. In one example, the input lines can be wordlines, bitlines, or select gate lines (SL), depending on type of memory cell and the particular set configuration (e.g., memory cells arranged in series as for NAND flash versus memory cells arranged in parallel as for RRAM or NOR).

The first memory cell is multiplied by the first input line via 1-bit to 1-bit multiplication (e.g., similarly as described for FIG. 2). The second memory cell is multiplied by the second input line via 1-bit to 1-bit multiplication (e.g., similarly as described for FIG. 2). The output currents are summed on a line. In one example, the line is 1241.

The result (e.g., 0 or 1) for the first time instance (e.g., first clock cycle) on the line is the same as the first bit of the signed 1-bit to 1-bit multiplication (two-bit representation). The result (e.g., 0 or 1) for the second time instance (e.g., second clock cycle) on the line is the same as the second bit of the signed 1-bit to 1-bit multiplication (two-bit representation). In one example, these first and second bit results provide a 1-bit signed result 1237 of FIG. 12.

In one embodiment, the 2 bits stored (see “2-Bit Stored” in table below) in the first and second memory cells for a Signed Weight are as set forth in the table below. The positive and negative versions of the Signed Input are as set forth in the table below. For example, for a signed input of −1, values of 01 are input on a first clock cycle, and values of 10 are input one a second clock cycle (represented in the table as 01, 10). The result of the multiplication is given at the intersection of the signed input and signed weight. For example, signed input −1 multiplied by signed weight −1 provides a 2-bit result of 1, 0.

| | | | |
|---|---|---|---|
| Signed Weight | −1 | 0 | +1 |
| 2-Bit Stored | 01 | 00 | 10 |

Signed Input

| | | | | |
|---|---|---|---|---|
| −1 | (01, 10) | 1, 0 | 0, 0 | 0, 1 |
| 0 | (00, 00) | 0, 0 | 0, 0 | 0, 0 |
| +1 | (10, 01) | 0, 1 | 0, 0 | 1, 0 |

In one example, a controller (e.g., 124 of FIG. 1) causes voltage drivers to apply two input voltages (e.g., that represent 2 bits 10) corresponding to a signed input of +1 at a first time to get a first bit result, then applies two input voltages for a negative version of the input (e.g., that represent 2 bits 01) at a second time to get a second bit result. For example, for a stored weight of +1, the first bit result is 1, and the second bit result is 0 (e.g., see bottom right-hand corner of result in the table above).

In other embodiments, equivalent variations of the logic configuration of the table above can be used. For example, the order of applying positive and negative versions of inputs can be varied. The controller manages the appropriate corresponding logical interpretation and/or combination of the polarity of bit results to provide a proper final signed result to generate as an output (e.g., send to a host requesting a result).

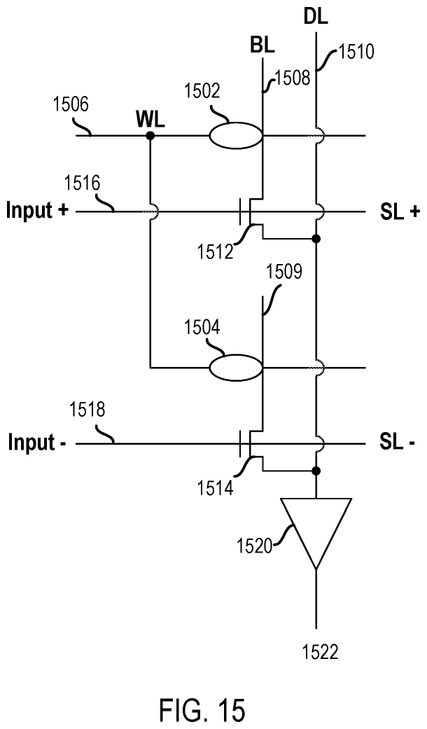

FIG. 15 shows a set of two memory cells 1502, 1504 for storing a signed weight used for multiplication according to one embodiment. The signed weight is represented by two bits. A first bit is stored in memory cell 1502, and the second bit stored in memory cell 1504. In one example, the values of the bits correspond to the table of signed inputs discussed above. In one example, memory cells 1502, 1504 are examples of memory cells 1207, 1217 of FIG. 12.

A voltage is applied to memory cell 1502 using wordline 1506 and bitline 1508. A voltage is applied to memory cell 1504 using wordline 1506 and bitline 1509.

Bitline 1508 is connected to digit line 1510 by select transistor 1512. Bitline 1509 is connected to digit line 1510 by select transistor 1514. The select transistors 1512, 1514 are controlled by applying a gate voltage using select lines 1516, 1518.

When performing multiplication, a signed input is represented by voltages applied to select lines 1516, 1518. Output currents from memory cells 1502, 1504 are summed on digit line 1510, for example similarly as discussed above.

Digitizer 1520 generates a digital bit result 1522 based on the summed output currents, for example similarly as discussed above. In one example, digitizer 1520 is digitizer 1233.

A first bit result is generated by digitizer 1520 for a first time instance (e.g., T0), and a second bit result is generated by digitizer 1520 for second time instance (e.g., T1). The first and second bits represent the signed result of the multiplication.

In one example, memory cells 1502, 1504 are configured as one set of many memory cells sets arranged in three-dimensional memory cell array. In one example, the memory cell array is an array as illustrated in FIG. 9.

In an alternative embodiment, memory cells 1502, 1504 are configured as one set of many memory cells sets arranged in a planar array. The planar array does not use select transistors. Output currents from the two memory cells are summed on bitlines. Two different wordlines are used to select each memory cell. The signed input is applied to the two wordlines.

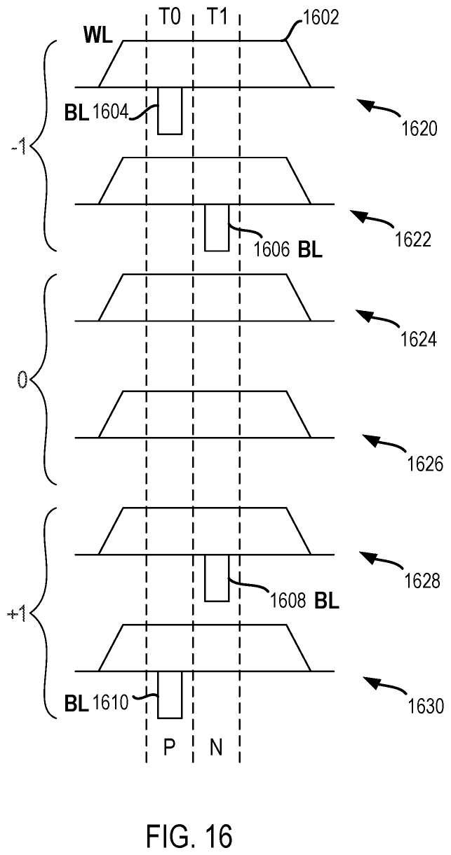

FIG. 16 shows voltage waveforms used for the memory cell configuration of FIG. 15 according to one embodiment. Waveforms for bitline BL and wordline WL voltages are illustrated. Time is represented on the horizontal axis. Positive and negative voltages are represented in the vertical direction above and below the horizontal axis.

An exemplary voltage pattern of waveforms is applied at time instances T0 and T1. The voltage pattern corresponds to the value of the signed input for the multiplication. The difference between the wordline and bitline voltage is the voltage applied to each memory cell, as illustrated.

Voltages for patterns 1620, 1622 correspond to a signed input of negative one (−1). Voltages for pattern 1620 are applied to a first memory cell 1502. Voltages for pattern 1622 applied to a second memory cell 1504.

For example, wordline waveform 1602 is fixed at a constant voltage in both time instances. Bitline voltage 1604 corresponds to a bit value of 1. Bitline voltage 1606 corresponds to a bit value of 1. So, at time T0 input bits of 1,0 are applied, and at time T1 input bits of 0,1 are applied.

The letters “P” and “N” at the bottom of the figure represent positive and negative versions of the signed input. However, the illustrated positive/negative polarity is arbitrary and can be varied in other implementations.

Voltages for patterns 1624, 1626 correspond to a signed input of zero. In this case, the wordline voltage is fixed, and the bitline voltage is zero.

Voltages for patterns 1628, 1630 correspond to a signed input of positive one (+1). Bitline voltage 1610 corresponds to a bit value of 1. Bitline voltage 1608 corresponds to bit value of 1.

In one example, the voltage patterns selected for these waveforms is managed by controller 124. In one example, the voltage patterns are applied by voltage drivers 1203, 1213.

In one embodiment, the designations in FIG. 15 of Input+ and Input− refer to input polarity representation. In a four-quadrant cell, positive and negative inputs can be represented in parallel by applying a magnitude of an input value on either the Input+ or Input− line. The sign of the input is represented by which of these input lines is active, while the other line is inactive (e.g., no voltage pulses are applied to the memory cell). Other representations are possible.

In one example, the time instances T0 and T1 applied to positive or negative representations is arbitrary. The polarity is determined by how the digitizer, analog to digital converter, and/or controller combines the two bit results.

In one example, positive and negative polarities of digit lines (e.g., DL+ and DL− of FIG. 10) is arbitrary and handled by controller 124. In one example, the digit lines can be considered as first and second digit lines DL. One digit line or the other digit line captures the negative or positive contributions that eventually are combined to generate a signed output.

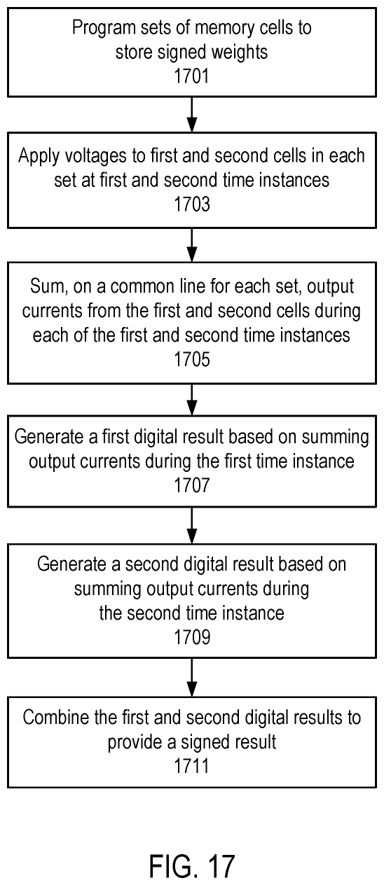

FIG. 17 shows a method for performing signed multiplication using weights stored in sets each containing two memory cells according to one embodiment. For example, the method of FIG. 17 can be performed in an integrated circuit device 101 of FIG. 1 using multiplication and accumulation as illustrated in FIGS. 12-16.

The method of FIG. 17 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 17 is performed at least in part by one or more processing devices (e.g., controller 124 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 1701, sets of memory cells are programmed to store signed weights. In one example, the set includes memory cells 1502, 1504.

At block 1703, voltages are applied to first and second cells in each set at first and second time instances. In one example, voltages are applied on select lines 1516, 1518 at times T0 and T1.

At block 1705, output currents from the first and second cells are summed on a common line for each set during each of the first and second time instances. In one example, output currents are summed on digit line 1510.

At block 1707, a first digital result is generated based on summing output currents during the first time instance. In one example, digitizer 1520 generates a first bit at time T0.

At block 1709, a second digital result is generated based on summing output currents during the second time instance. In one example, digitizer 1520 generates a second bit at time T1.

At block 1711, the first and second digital results are combined to provide a signed result. In one example, the first and second bits generated by digitizer 1520 are combined to provide a signed result.

In one embodiment, a system comprises: a first integrated circuit (IC) die (e.g., 103 of FIG. 1) having a sensor (e.g., image sensing pixel array 111 of FIG. 1); a second integrated circuit (IC) die (e.g., 105) including a memory cell array (e.g., 113) having sets of memory cells, wherein each set is configured to store a signed weight; an interconnect (e.g., 107) connecting the first and second IC dies; voltage drivers (e.g., 115) configured to apply voltages to first and second cells in each set at first and second time instances, wherein the voltages are based on data from the sensor and correspond to a signed input to be multiplied by the stored weight in each set; an interface (e.g., 125) configured to communicate with a host; and a controller configured to: program each set to store the signed weight; sum, on a common line for each set, output currents from the first and second cells during each of the first and second time instances; generate a first digital result based on summing output currents during the first time instance; generate a second digital result based on summing output currents during the second time instance; combining the first and second digital results to provide a signed result (e.g., result 1237); and send, via the interface, the signed result to the host.

In one embodiment, each of the memory cells in the memory cell array is a NOR flash memory cell.

In one embodiment, each of the memory cells in the memory cell array is a chalcogenide memory cell.

In one embodiment, the signed weight and signed input are each represented by a respective 2-bit number having possible values of 01, 00, or 10.

In one embodiment, the voltages (e.g., 1205, 1215) applied to each set represent a 1-bit signed input; and applying the voltages comprises applying first and second bits of the signed input at the first time instance (e.g., time T0 of FIG. 16), and applying a negative version of the first and second bits of the signed input at the second time instance (e.g., time T1 of FIG. 16).

In one embodiment, the system further comprises first and second input lines (e.g., select lines 1516, 1518) coupled to the voltage drivers and used to apply the voltages, wherein: the first input line is coupled to the first cell (e.g., 1502) and used to apply a voltage corresponding to the first bit; and the second input line is coupled to the second cell (e.g., 1504) and used to apply a voltage corresponding to the second bit.

In one embodiment, the first and second input lines are wordlines, and the line coupled to the first and second cells is a bitline.

In one embodiment, a device comprises: a memory cell array having sets of memory cells, wherein each set includes a first cell (e.g., 1207) and a second cell (e.g., 1217), and each set is programmable to store a signed weight for performing multiplication; voltage drivers configured to apply voltages to the first and second cells in each set at first and second time instances, the voltages corresponding to a signed input to be multiplied by the stored weight in each set, wherein the voltages applied at the first time instance (e.g., time T0 of FIG. 16) represent a positive version of the signed input, and the voltages applied at the second time instance (e.g., time T1 of FIG. 16) represent a negative version of the signed input; a line coupled to the first and second cells in each set, wherein the line is configured to sum output currents from the first and second cells for each of the first and second time instances; and a digitizer (e.g., 1520) for each set, the digitizer configured to provide a first result based on summing output currents for the first time instance, and a second result based on summing output currents for the second time instance, wherein a combination of the first and second results is a signed result.

In one embodiment, the voltages are applied so that operation of the first and second cells in each set is kept in a sub-threshold mode during multiplication.

In one embodiment, the signed result has first and second bits; the first result is the first bit of the signed result; and the second result is the second bit of the signed result.

In one embodiment, the line is a digit line (e.g., 1510), and the device further comprises: bitlines (e.g., 1508, 1509) coupled to the first and second cells in each set; and select transistors (e.g., 1512, 1514) configured to electrically connect the bitlines of each set to the digit line.

In one embodiment, applying voltages to the first and second cells comprises applying voltages to gates of the select transistors to cause a change in voltage on the bitlines.

In one embodiment, the first and second cells in each set are accessed using a common wordline.

In one embodiment, the wordline is held at a constant voltage during each of the first and second time instances; and the voltage drivers are further configured to apply the voltages by varying voltages of at least one bitline connected to the first and second cells in each set.

In one embodiment, an apparatus comprises: a plurality of sets of NAND flash memory cells, wherein each set includes a first cell and a second cell; and a controller (e.g., 124) configured to: program the first and second cells of each set to store a respective signed weight, wherein the programming comprises biasing gates of the first and second cells; apply voltages at first and second time instances to the sets of memory cells, wherein for each set the voltages represent a respective signed input to be multiplied by the signed weight stored in the set; and determine a respective signed result for each set based on summing output currents from the first and second cells at the first and second time instances.

In one embodiment, when performing the multiplication, the first and second cells are selected by applying a respective read voltage to the gates of the first and second cells.

In one embodiment, non-selected cells in a respective same string with the first and second cells are biased by applying a bypass voltage to gates of the non-selected cells.

In one embodiment, each of the NAND flash memory cells is connected to a respective wordline that is used to apply read or bypass voltages when performing the multiplication.

In one embodiment, the controller is further configured to receive, by the interface from the host system, first data associated with an artificial neural network; and the signed weights stored in the sets of memory cells are based on the first data.

In one embodiment, the apparatus further comprises bitlines or wordlines coupled to the sets of memory cells, wherein the voltages are applied to the bitlines or wordlines.

In one embodiment, a device comprises: a memory cell array having sets of memory cells, wherein each set includes a first cell and a second cell, and each set is programmable to store a signed weight for performing multiplication; voltage drivers configured to apply voltages to the first and second cells in each set at first and second time instances, the voltages corresponding to a signed input to be multiplied by the stored weight in each set; a line coupled to the first and second cells in each set, wherein the line is configured to sum output currents from the first and second cells for each of the first and second time instances; and a digitizer for each set, the digitizer configured to provide a first result based on summing output currents for the first time instance, and a second result based on summing output currents for the second time instance, wherein a combination of the first and second results is a signed result.

In one embodiment, the voltages are applied so that operation of the first and second cells in each set is kept in a sub-threshold mode during multiplication.

In one embodiment, the voltages applied at the first time instance represent a positive version of the signed input; and the voltages applied at the second time instance represent a negative version of the signed input.

In one embodiment, the signed result has first and second bits; the first result is the first bit of the signed result; and the second result is the second bit of the signed result.

In one embodiment, the line is a digit line, and the device further comprises: bitlines coupled to the first and second cells in each set; and select transistors configured to electrically connect the bitlines of each set to the digit line.

In one embodiment, applying voltages to the first and second cells comprises applying voltages to gates of the select transistors to cause a change in voltage on the bitlines.

In one embodiment, the first and second cells in each set are accessed using a common wordline.

In one embodiment, the wordline is held at a constant voltage during each of the first and second time instances (e.g., wordline waveform 1602 in FIG. 16); and the voltage drivers are further configured to apply the voltages by varying voltages of at least one bitline connected to the first and second cells in each set (e.g., bitline waveforms 1604, 1606 in FIG. 16).

In one embodiment, the line is a bitline.

In one embodiment, the voltages applied to each set represent a 1-bit signed input; and applying the voltages comprises applying first and second bits of the signed input at the first time instance, and applying a negative version of the first and second bits of the signed input at the second time instance.

In one embodiment, the device further comprises first and second input lines coupled to the voltage drivers and used to apply the voltages, wherein: the first input line is coupled to the first cell and used to apply a voltage corresponding to the first bit; and the second input line is coupled to the second cell and used to apply a voltage corresponding to the second bit.

In one embodiment, the first and second input lines are wordlines, and the line coupled to the first and second cells is a bitline.

In one embodiment, each of the memory cells in the memory cell array is a NAND or NOR flash memory cell.

In one embodiment, each of the memory cells in the memory cell array is a chalcogenide memory cell.

In one embodiment, the signed weight and signed input are each represented by a respective 2-bit number having possible values of 01, 00, or 10.

In one embodiment, an apparatus comprises: a memory cell array having sets of memory cells, wherein each set includes a first cell and a second cell; and a controller configured to: program the first and second cells of each set to store a respective signed weight; apply voltages at first and second time instances to the sets of memory cells, wherein for each set the voltages represent a respective signed input to be multiplied by the signed weight stored in the set; and determine a respective signed result for each set based on summing output currents from the first and second cells at the first and second time instances.

In one embodiment, the apparatus further comprises a digitizer coupled to each set, wherein the digitizer is configured to generate the signed result.

In one embodiment, the output currents are summed on a respective common line (e.g., 1510, 1241, 1243) for each set that is coupled to the first and second cells of the set.

In one embodiment, the common line is a bitline or digit line.

In one embodiment, the apparatus further comprises an interface operable for a host system to write data into the memory cell array and to read data from the memory cell array.

In one embodiment, the controller is further configured to receive, by the interface from the host system, first data associated with an artificial neural network; and the signed weights stored in the sets of memory cells are based on the first data.

In one embodiment, the apparatus further comprises bitlines or wordlines coupled to the sets of memory cells, wherein the voltages are applied to the bitlines or wordlines.

In one embodiment, a method comprises: programming sets of memory cells to store a signed weight; applying voltages to first and second cells in each set at first and second time instances, the voltages corresponding to a signed input to be multiplied by the stored weight in each set; summing, on a common line for each set, output currents from the first and second cells during each of the first and second time instances; generating a first digital result based on summing output currents during the first time instance; generating a second digital result based on summing output currents during the second time instance; and combining the first and second digital results to provide a signed result.

Various embodiments related to memory devices for performing signed multiplication using sets each containing four memory cells are now described below. The generality of the following description is not limited by the various embodiments described above.

In one memory cell implementation, signed multiplication is performed for a memory cell array in which each set has four memory cells (sets organized as units of four memory cells). In one example, resistive random-access memory (RRAM) cells are used. In one example, NAND or NOR flash memory cells are used.

In one embodiment, a signed 1-bit number (e.g., an input and/or weight) has one of three possible values: −1, 0, 1. For example, a signed weight can be represented by a 2-bit number, as described above. The signed weight can be represented by values stored in a memory cell set of four cells. A first pair of cells stores 2 bits representing the 1-bit signed weight. A second pair of cells stores a negative version of the 2 bits.

In one embodiment, a four-cell implementation is used for signed 1-bit to 1-bit multiplication. Four memory cells of a set are used to store the two bits of the signed 1-bit weight in the two-bit representation (sometimes referred to herein as a “positive version”) and also in a negative version of the two-bit representation. Two input lines are used to apply the two bits of the signed 1-bit input (two-bit representation).

In one example, the input lines provide voltages to a memory cell set 1227 of FIG. 12. The set 1227 has four memory cells as described above. In one example, the input lines can be wordlines, bitlines, or select gate lines (SL), depending on type of memory cell and the particular set configuration (e.g., memory cells arranged in series as for NAND flash versus memory cells arranged in parallel as for RRAM or NOR).

The first pair of memory cells is multiplied by the signed input. The output currents are summed on a first line. In one example, the first line is 1241. The second pair of memory cells is also multiplied by the signed input. The output currents are summed on a second line. In one example, the line is 1243.

The bit result (e.g., 0 or 1) for the first line provides the first bit of the signed 1-bit to 1-bit multiplication (two-bit representation). The bit result (e.g., 0 or 1) for the second line provides the second bit of the signed 1-bit to 1-bit multiplication (two-bit representation). In one example, these first and second bit results provide a 1-bit signed result 1237 of FIG. 12.

In one embodiment, the 2 bits stored (see “2-Bit Stored” in table below) in the four memory cells of a set for a Signed Weight are as set forth in the table below. The positive and negative versions of the Signed Weight are as set forth in the table below. For example, for a signed weight of −1, values of 01 are stored in a first pair of cells, and values of 10 are stored in a second pair of cells (represented in the table as 01, 10 in the second row of the heading). The result of the multiplication is given at the intersection of the signed input and signed weight. For example, signed input −1 multiplied by signed weight −1 provides a 2-bit result of 1, 0.

| | | | |
|---|---|---|---|
| Signed Weight | −1 | 0 | +1 |
| 2-Bit Stored | 01, 10 | 00, 00 | 10, 01 |

Signed Input

| | | | |
|---|---|---|---|
| −1 (01) | 1, 0 | 0, 0 | 0, 1 |
| 0 (00) | 0, 0 | 0, 0 | 0, 0 |
| +1 (10) | 0, 1 | 0, 0 | 1, 0 |

In one example, a controller (e.g., 124 of FIG. 1) causes voltage drivers to apply two input voltages (e.g., that represent 2 bits 10) corresponding to a signed input of +1. The voltages are applied to a first and second pair of memory cells as described above. By summing output currents, a first line provides a first bit result, and a second line provides a second bit result as described above. For example, for a stored weight of +1, the first bit result from the first line 1241 is 1, and the second bit result from the second line 1243 is 0 (e.g., see bottom right-hand corner of result in the table above).

In one example, a set of memory cells is configured in a NAND flash memory array such as illustrated in FIG. 10. The set includes a first pair of memory cells 1008, 1009 and a second pair of memory cells 1006, 1007. Two select lines SL are used to apply two voltages corresponding to 2 bits of a signed input. The voltages are applied to gates of select transistors (e.g., 1012, 1014). First and second digit lines 1016, 1018 are used to sum currents to provide 2 bits of a signed result as described above.

In one example, a memory array includes a set of four RRAM cells 906, 907, 908, 909 as illustrated in FIG. 9. A first pair of the RRAM cells stores two bits of the signed 1-bit weight in the two-bit representation. A second pair of the RRAM cells stores the two bits of the negative version of the signed 1-bit weight (two-bit representation). Two input lines (e.g., select lines SL) are used to apply the two bits of the signed 1-bit input (two-bit representation). Currents are summed on digit lines 914, 916.

In one embodiment, the 1-bit by 1-bit multiplication and summation between the input lines and the first two memory cells is done as described for memory cells 1207, 1217 of FIG. 12 with output currents summed on line 1241. The same is done for the multiplication and summation between the input lines and the second two memory cells with output currents summed on line 1243.

The bit result of the multiplication between the input lines and the first two memory cells is determined by digitizer 1233 for line 1241. The bit result of the multiplication between the input lines and the second two memory cells is determined by digitizer 1233 for line 1243. Thus, the bit results provide the two-bits of the signed result 1237 of signed 1-bit to 1-bit multiplication (two-bit representation).

In other embodiments, equivalent variations of the logic configuration of the table above can be used. For example, the order of applying positive and negative versions of inputs can be varied. The controller manages the appropriate corresponding logical interpretation and/or combination of the polarity of bit results to provide a proper final signed result to generate as an output (e.g., send to a host requesting a result).

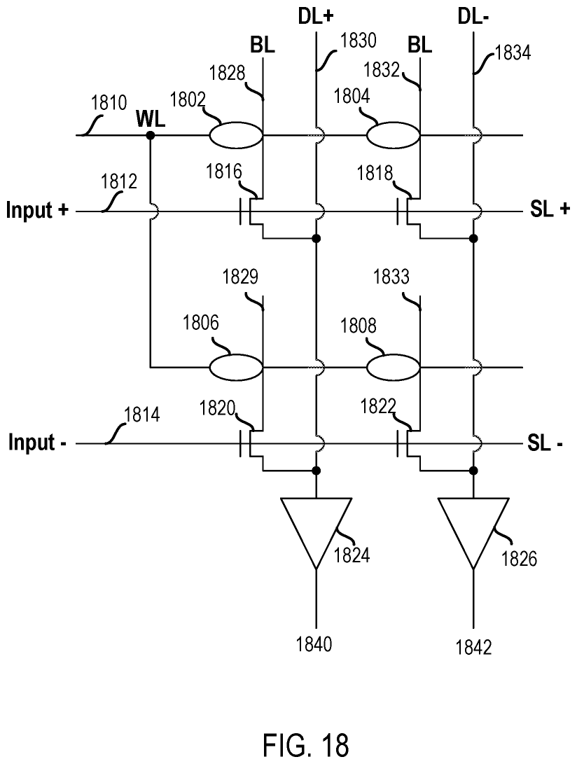

FIG. 18 shows a multiplication architecture having two digitizers 1840, 1842 and using a set of four memory cells for storing a signed weight according to one embodiment. A first pair of memory cells 1802, 1806 stores a positive version of a signed weight. A second pair of memory cells 1804, 1808 stores a negative version of the signed weight, as discussed above.

Voltages are applied to the memory cells using wordline 1810 and bitlines 1828, 1829, 1832, 1833. The bitlines are coupled to select lines 1812, 1814 using select transistors 1816, 1820, 1818, 1822, for example as described above.

Two bits of a signed input are represented by voltages applied to the gates of the select transistors using select lines 1812, 1814. A first bit the input is applied using select line 1812. A second bit is applied using select line 1814.

For performing multiplication, output currents are summed on digit lines 1830, 1834. Digitizer 1824 generates a first bit 1840 based on the summed output currents on digit line 1830. Digitizer 1826 generates a second bit 1842 based on the summed output currents on digit line 1834. Bits 1840, 1842 provide the signed result.

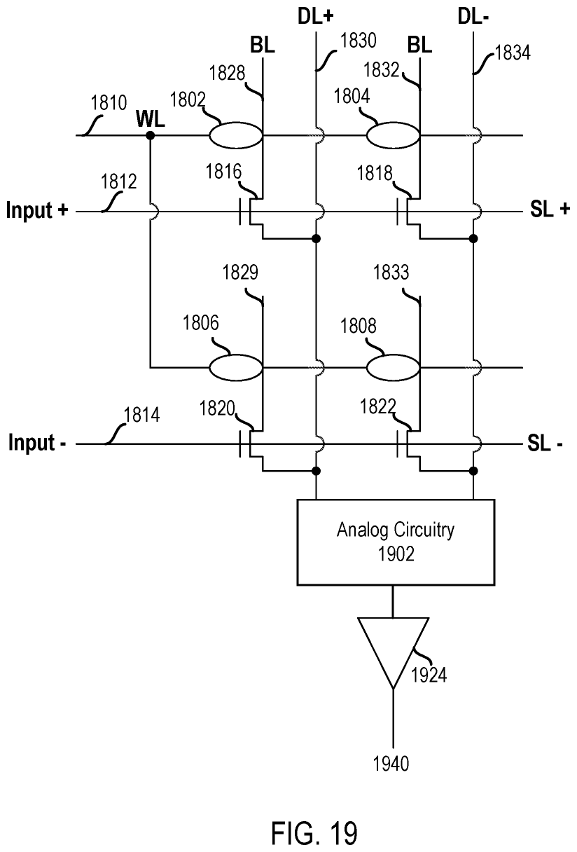

FIG. 19 shows a multiplication architecture having analog circuitry 1902 to combine output currents from two common lines and using a set of four memory cells for storing a signed weight according to one embodiment. The architecture of FIG. 19 is similar to that of FIG. 18 except as described below.

Analog circuitry 1902 combines summed output currents from digit lines 1830, 1834. Analog circuitry 1902 provides an output signal used by digitizer 1924 to generate a signed result 1940. In one example, the signed result 1940 is provided as two bits (e.g., 01, or 11).

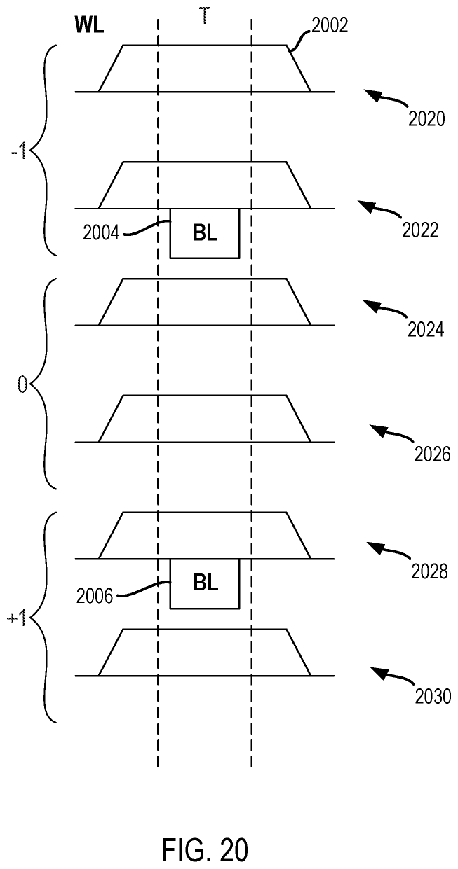

FIG. 20 shows voltage waveforms used as a signed input for the memory cell configuration of FIG. 18 or FIG. 19 according to one embodiment. Waveforms for bitline BL and wordline WL voltages are illustrated. Time is represented on the horizontal axis. Positive and negative voltages are represented in the vertical direction above and below the horizontal axis. As for FIG. 16 above, if the bitline voltage is zero, then the waveform coincides with the horizontal axis (and is not separately shown).

An exemplary voltage pattern of waveforms is applied at a time T (e.g., in the same clock cycle). The voltage pattern corresponds to the value of the signed input for the multiplication. The difference between the wordline and bitline voltage is the voltage applied to each memory cell, as illustrated.

Voltages for patterns 2020, 2022 correspond to a signed input of negative one (−1). Voltages for pattern 2020 (e.g., corresponding to a first bit Input+) are applied to memory cells 1802, 1804. Voltages for pattern 2022 (e.g., corresponding to a second bit Input−) are applied to memory cells 1806, 1808.

For example, wordline waveform 2002 is fixed at a constant voltage. Bitline voltage 2004 corresponds to a bit value of 1. So, for example, at time T input bits of 0,1 are applied. It should be noted that the exemplary positive/negative polarity of FIG. 20 is arbitrary and can be varied in other implementations.

Voltages for patterns 2024, 2026 correspond to a signed input of zero. In this case, the wordline voltage is fixed, and the bitline voltage is zero for both bits.

Voltages for patterns 2028, 2030 correspond to a signed input of positive one (+1). Bitline voltage 2006 corresponds to a bit value of 1. Thus, input bits of 1, 0 are applied.

In one example, the voltage patterns selected for these waveforms are managed by controller 124. In one example, the voltage patterns are applied by voltage drivers 1223.

In one example, the positive or negative representations are arbitrary. The polarity is determined by how the digitizer, analog to digital converter, and/or controller combines the two bit results of a signed result.

In one example, positive and negative polarities of digit lines (e.g., DL+ and DL− of FIG. 10) is arbitrary and handled by controller 124. In one example, the digit lines can be considered as first and second digit lines DL. One digit line or the other digit line captures the negative or positive contributions that eventually are combined to generate a signed output.

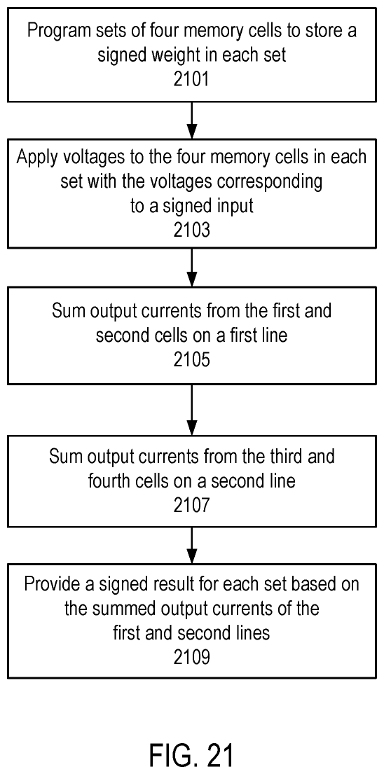

FIG. 21 shows a method for performing signed multiplication using weights stored in sets each containing four memory cells according to one embodiment. For example, the method of FIG. 21 can be performed in an integrated circuit device 101 of FIG. 1 using multiplication and accumulation as illustrated in FIGS. 12, and 18-20.

The method of FIG. 21 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 21 is performed at least in part by one or more processing devices (e.g., controller 124 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2101, sets having four memory cells in each set are programmed to store a signed weight in each set. In one example, memory cells 1802, 1804, 1806, 1808 are programmed to store a signed weight.

At block 2103, voltages are applied to the four memory cells in each set. The voltages correspond to a signed input. In one example, voltages are applied to the memory cells using select lines 1812, 1814. The select lines turn on some or all of select transistors 1816, 1818, 1820, 1822, depending on the bit value of the respective input.

At block 2105, output currents from the first and second cells are summed on a first line. In one example, the first line is digit line 1830.

At block 2107, output currents from the third and fourth cells are summed on a second line. In one example, the second line is digit line 1834.

At block 2109, a signed result is provided for each set. The signed result is based on the summed output currents of the first and second lines. In one example, digitizers 1824, 1826 provide the signed result. In one example, digitizer 1924 provides the signed result.

In one embodiment, a device comprises: a memory cell array having sets of memory cells, wherein each set includes first and second cells (e.g., 1802, 1806) programmable to store a signed weight, and third and fourth cells (e.g., 1804, 1808) programmable to store a negative version of the signed weight; voltage drivers (e.g., 1223) configured to apply voltages to the first, second, third, and fourth cells in each set, the voltages corresponding to a signed input to be multiplied by the signed weight in each set; a first line (e.g., 1241) coupled to the first and second cells in each set, wherein the first line is configured to sum output currents from the first and second cells; a second line (e.g., 1243) coupled to the third and fourth cells in each set, wherein the second line is configured to sum output currents from the third and fourth cells; a first digitizer (e.g., 1233) for each set, the first digitizer configured to provide a first result based on summing the output currents from the first and second cells; and a second digitizer (e.g., 1233) for each set, the second digitizer configured to provide a second result based on summing the output currents from the third and fourth cells; wherein a combination of the first and second results is a signed result (e.g., 1237) from multiplication of the signed input by the signed weight.

In one embodiment, the signed weight is a signed 1-bit weight; the first and second cells are used to store two bits of the signed 1-bit weight; and the third and fourth cells are used to store two bits of the negative version of the signed 1-bit weight.

In one embodiment, the device further comprises two input lines (e.g., select lines 1812, 1814) configured to apply two bits of the signed input to each set of memory cells.

In one embodiment, the voltages are applied so that operation of the first, second, third, and fourth cells in each set is kept in a sub-threshold mode when performing multiplication.

In one embodiment, the signed result has first and second bits; the first result is a first bit of the signed result; and the second result is a second bit of the signed result.

In one embodiment, the voltages applied to each set represent a 1-bit signed input. Applying the voltages comprises applying a first bit of the signed input to the first and third cells, and applying a second bit of the signed input to the second and fourth cells.

In one embodiment, the device further comprises first and second input lines coupled to the voltage drivers and used to apply the voltages, wherein: the first input line (e.g., select line 1812) is coupled to the first and third cells and used to apply at least one voltage corresponding to the first bit; and the second input line (e.g., select line 1814) is coupled to the second and fourth cells and used to apply at least one voltage corresponding to the second bit.

In one embodiment, the device further comprises: bitlines (e.g., 1828, 1829, 1832, 1833) coupled to the first, second, third, and fourth cells in each set; and select transistors (e.g., 1816, 1818, 1820, 1822) configured to electrically connect the bitlines of each set to the first and second lines; wherein the voltages are applied to gates of the select transistors to cause a change in voltage on the bitlines.

In one embodiment, the first, second, third, and fourth cells in each set are accessed using a common wordline (e.g., 1810).

In one embodiment, applying the voltages comprises: holding the common wordline in each set at a constant voltage; and varying voltages on bitlines connected to the first, second, third, and fourth cells in each set, wherein the voltages on the bitlines are varied based on a value of the signed input for the set.

In one embodiment, the first digitizer (e.g., 1824) is coupled to a first digit line (e.g., 1830), and the second digitizer (e.g., 1826) is coupled to a second digit line (e.g., 1834).

In one embodiment, an apparatus comprises: a semiconductor substrate (e.g., 1302); a memory cell array (e.g., 1304) arranged as sets of at least four memory cells per set, wherein each set of memory cells is programmable to store a signed weight for performing a multiplication, wherein the memory cells are organized in horizontal tiers of cells, and wherein the tiers are stacked vertically above the semiconductor substrate; and a controller (e.g., 124) configured to: program first and second cells of each set to store a signed weight, and third and fourth cells of each set to store a negative version of the signed weight; apply voltages to the sets of memory cells, wherein for each set the voltages represent a respective signed input to be multiplied by the signed weight stored in the set; and determine a respective signed result for each set based on summing output currents from the first and second cells on a first line, and summing output currents from the third and fourth cells on a second line.

In one embodiment, the apparatus further comprises first and second digitizers (e.g., 1340) for each set of memory cells, wherein: the first digitizer is configured to provide a first result based on the summing of output currents on the first line; the second digitizer is configured to provide a second result based on the summing of output currents on the second line; and the respective signed result is a combination of the first and second results.

In one embodiment, the apparatus further comprises an interface (e.g., 125) operable for a host to write data into the memory cell array and to read data from the memory cell array.

In one embodiment, the controller is further configured to receive, by the interface from the host, first data associated with an artificial neural network; the signed weights stored in the sets of memory cells are based on the first data; and the signed weights are used for matrix vector multiplication to provide the signed result for each set.

In one embodiment, a system comprises: a plurality of memory cells organized as sets (e.g., 1227), wherein each set includes first and second cells programmable to store a signed weight, and third and fourth cells programmable to store a negative version of the signed weight; voltage drivers configured to apply voltages to the first, second, third, and fourth cells in each set, the voltages corresponding to a signed input to be multiplied by the signed weight in each set; a first line coupled to the first and second cells in each set, wherein the first line is configured to sum output currents from the first and second cells; a second line coupled to the third and fourth cells in each set, wherein the second line is configured to sum output currents from the third and fourth cells; analog circuitry (e.g., 1902) configured to combine the summed output currents of the first and second lines for each set; and a digitizer (e.g., 1924) for each set, the digitizer coupled to the analog circuitry and configured to provide a signed result (e.g., 1940) from multiplication of the signed input by the signed weight, wherein the signed result is determined based on the combination of the summed output currents by the analog circuitry.

In one embodiment, the first line is a first digit line, and the second line is a second digit line. The system further comprises: bitlines coupled to the first, second, third, and fourth cells in each set; and select transistors configured to electrically connect the bitlines of each set to the first and second digit lines.

In one embodiment, each of the plurality of memory cells is a NAND or NOR flash memory cell.

In one embodiment, each of the plurality of memory cells is a chalcogenide memory cell.

In one embodiment, the signed weight and signed input are each represented by a respective 2-bit number having possible values of 01, 00, or 10.

In one embodiment, a device comprises: a memory cell array having sets of memory cells, wherein each set includes first and second cells programmable to store a signed weight, and third and fourth cells programmable to store a negative version of the signed weight; voltage drivers (e.g., 1320) configured to apply voltages (see, e.g., FIG. 20) to the first, second, third, and fourth cells in each set, the voltages corresponding to a signed input to be multiplied by the signed weight in each set; a first line coupled to the first and second cells in each set, wherein the first line is configured to sum output currents from the first and second cells; a second line coupled to the third and fourth cells in each set, wherein the second line is configured to sum output currents from the third and fourth cells; a first digitizer for each set, the first digitizer configured to provide a first result based on summing the output currents from the first and second cells; and a second digitizer for each set, the second digitizer configured to provide a second result based on summing the output currents from the third and fourth cells; wherein a combination of the first and second results is a signed result from multiplication of the signed input by the signed weight.

In one embodiment, the signed weight is a signed 1-bit weight; the first and second cells are used to store two bits of the signed 1-bit weight; and the third and fourth cells are used to store two bits of the negative version of the signed 1-bit weight.

In one embodiment, the device further comprises two input lines (e.g., two select lines 1314) configured to apply two bits of the signed input to each set of memory cells.

In one embodiment, the two input lines are wordlines or gate lines (e.g., select lines 1812, 1814).

In one embodiment, the voltages are applied so that operation of the first, second, third, and fourth cells in each set is kept in a sub-threshold mode when performing multiplication.

In one embodiment, the signed result has first and second bits; the first result is a first bit of the signed result; and the second result is a second bit of the signed result.

In one embodiment, the voltages applied to each set represent a 1-bit signed input. Applying the voltages comprises applying a first bit of the signed input to the first and third cells, and applying a second bit of the signed input to the second and fourth cells.

In one embodiment, the device further comprises first and second input lines coupled to the voltage drivers and used to apply the voltages, wherein: the first input line is coupled to the first and third cells and used to apply at least one voltage corresponding to the first bit; and the second input line is coupled to the second and fourth cells and used to apply at least one voltage corresponding to the second bit.

In one embodiment, the first and second input lines are wordlines, and the first and second lines are bitlines.

In one embodiment, the first line is a first digit line, and the second line is a second digit line. The device further comprises: bitlines coupled to the first, second, third, and fourth cells in each set; and select transistors configured to electrically connect the bitlines of each set to the first and second digit lines.

In one embodiment, the voltages are applied to gates of the select transistors to cause a change in voltage on the bitlines.

In one embodiment, the first, second, third, and fourth cells in each set are accessed using a common wordline.

In one embodiment, applying the voltages comprises: holding the common wordline in each set at a constant voltage; and varying voltages on bitlines connected to the first, second, third, and fourth cells in each set, wherein the voltages on the bitlines are varied based on a value of the signed input for the set.

In one embodiment, the first digitizer is coupled to a first digit line, and the second digitizer is coupled to a second digit line.

In one embodiment, each of the memory cells in the memory cell array is a NAND or NOR flash memory cell.

In one embodiment, each of the memory cells in the memory cell array is a chalcogenide memory cell.

In one embodiment, the signed weight and signed input are each represented by a respective 2-bit number having possible values of 01, 00, or 10.

In one embodiment, a device comprises: a memory cell array having sets of memory cells, wherein each set includes first and second cells programmable to store a signed weight, and third and fourth cells programmable to store a negative version of the signed weight; voltage drivers configured to apply voltages to the first, second, third, and fourth cells in each set, the voltages corresponding to a signed input to be multiplied by the signed weight in each set; a first line coupled to the first and second cells in each set, wherein the first line is configured to sum output currents from the first and second cells; a second line coupled to the third and fourth cells in each set, wherein the second line is configured to sum output currents from the third and fourth cells; analog circuitry configured to combine the summed output currents of the first and second lines; and a digitizer for each set, the digitizer coupled to the analog circuitry and configured to provide a signed result from multiplication of the signed input by the signed weight, wherein the signed result is determined based on the combination of the summed output currents by the analog circuitry.

In one embodiment, an apparatus comprises: a memory cell array arranged as sets of at least four memory cells per set; and a controller configured to: program first and second cells of each set to store a signed weight, and third and fourth cells of each set to store a negative version of the signed weight; apply voltages to the sets of memory cells, wherein for each set the voltages represent a respective signed input to be multiplied by the signed weight stored in the set; and determine a respective signed result for each set based on summing output currents from the first and second cells on a first line, and summing output currents from the third and fourth cells on a second line.

In one embodiment, the apparatus further comprises first and second digitizers for each set of memory cells, wherein: the first digitizer is configured to provide a first result based on the summing of output currents on the first line; and the second digitizer is configured to provide a second result based on the summing of output currents on the second line; and the respective signed result is a combination of the first and second results.

In one embodiment, the apparatus further comprises an interface operable for a host to write data into the memory cell array and to read data from the memory cell array.

In one embodiment, the controller is further configured to receive, by the interface from the host, first data associated with an artificial neural network; the signed weights stored in the sets of memory cells are based on the first data; and the signed weights are used for matrix vector multiplication to provide the signed result for each set.

In one embodiment, a method comprises: programming (e.g., using firmware of controller 124) sets of four memory cells to store a signed weight in each set; applying voltages to the four memory cells in each set, the voltages corresponding to a signed input to be multiplied by the stored weight in the set; summing output currents from the first and second cells on a first line (e.g., 1830); summing output currents from the third and fourth cells on a second line (e.g., 1834); generating a first result based on summing the output currents from the first and second cells on the first line; generating a second result based on summing the output currents from the third and fourth cells on the second line; and combining the first and second results to provide a signed result for each set.

Various embodiments related to memory devices that sum outputs from signed multiplications performed by sets of memory cells are now described below. The generality of the following description is not limited by the various embodiments described above.

In one implementation, a memory cell array has sets organized as units of a fixed number of memory cells (e.g., two or four cells per set, such as above). Each set performs a signed multiplication (e.g., a signed input to a set multiplied by a signed weight stored by the set) to provide a signed result as an output. These outputs are summed on one or more common lines (e.g., bitline(s)) to provide a signed result for the summation.

In one embodiment, a memory device uses a memory cell array organized as sets of memory cells. In one example, resistive random-access memory (RRAM) cells are used. In one example, NAND or NOR flash memory cells are used.

Each set is programmable to store a signed weight. After being programmed, voltage drivers apply voltages to the memory cells in each set. The voltages represent a signed input to be multiplied by the signed weight for each set.

One or more common lines are coupled to each set. The lines receive one or more output currents from the memory cells in each set (e.g., as discussed above for sets of two or four cells). Each common line accumulates the currents to sum the output currents from the sets.

In one example, the line(s) are bitline(s) extending vertically above a semiconductor substrate as discussed above for FIG. 13. As an example, 512 memory cell sets are coupled to the line(s). The output currents from each of the 512 sets are collected on the line(s), and then one or more total current magnitudes are digitized to provide one or more digital values (e.g., first and second bits of a signed result from the summation of multiplication outputs).

In one example, the memory device includes one or more digitizers. The digitizer(s) provides a signed result based on summing the output currents from each of the 512 sets.

In one embodiment, a memory device implements summation of outputs of signed 1-bit to 1-bit multiplications. Each bit of the results of a column of signed 1-bit to 1-bit multiplications is summed via connecting the output currents to respective first and second lines. In one example, each bit is one of the 2 bits (e.g., 0, 1 for multiplication of +1×−1) of a result in the table below, which was described for a four-cell set implementation above.

| | | | |
|---|---|---|---|
| Signed Weight | −1 | 0 | +1 |
| 2-Bit Stored | 01, 10 | 00, 00 | 10, 01 |

Signed Input

| | | | |
|---|---|---|---|
| −1 (01) | 1, 0 | 0, 0 | 0, 1 |
| 0 (00) | 0, 0 | 0, 0 | 0, 0 |
| +1 (10) | 0, 1 | 0, 0 | 1, 0 |

A first digital count (e.g., an integer) of the current on the first line is summed for the first bit as the multiple of a predetermined current (e.g., as described above) representing 1. A second digital count of the current on the second line is summed for the second bit as the multiple of the predetermined current. The first and second digital counts are, for example, outputs from a digitizer(s).

The magnitude of the first and second counts can be reduced by the smaller one of the two counts to cancel out an equal number of representations of 1 and −1 in the items being summed up. After this magnitude reduction, the sign of the summation is represented by the position of the zero (e.g., negative if in the first bit, positive if in the second bit). The magnitude of the result is represented by the non-zero count (e.g., either in the first bit or in the second bit).

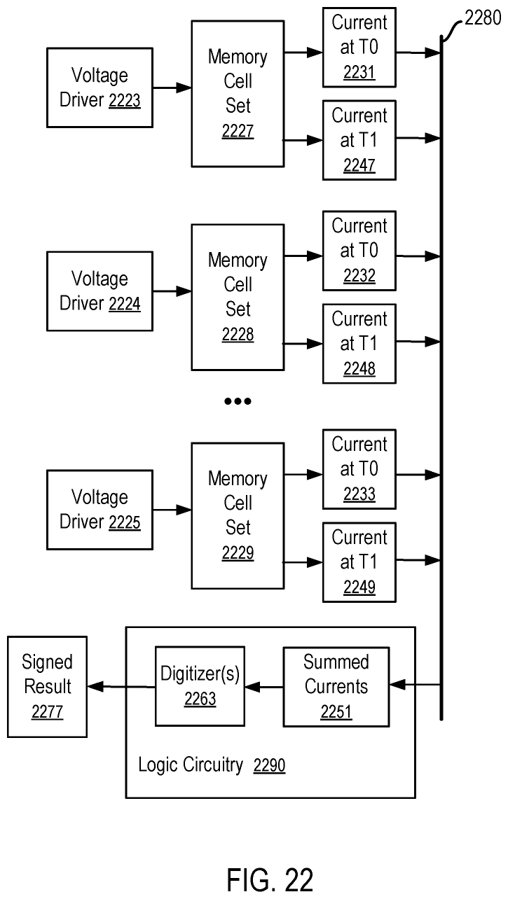

FIG. 22 shows a multiplication architecture for summing outputs from multiplications at two different time instances using a single line according to one embodiment. Voltage drivers 2223, 2224, 2225 apply voltages to two or more memory cells in each of memory cell sets 2227, 2228, 2229. The voltages applied to each set correspond to a respective signed input to that set.

Each set stores a signed weight. In one example, each set has two cells. In one example, each set has an architecture similar to that illustrated in FIG. 15 or FIG. 18. The signed input is multiplied by the stored weight for each set to provide an output from that set, which is a result of the multiplication. For example, as described above, the output is represented by one or more output currents from one or more cells of each set. The output currents are accumulated on line 2280.

The summation of the outputs of the multiplication results from the sets is represented by summed currents 2251. For example, as described above, the sum of currents is a multiple of a predetermined amount of unit current. Summed currents 2251 are converted into one or more digital values by one or more digitizers 2263 (e.g., similarly as described above).

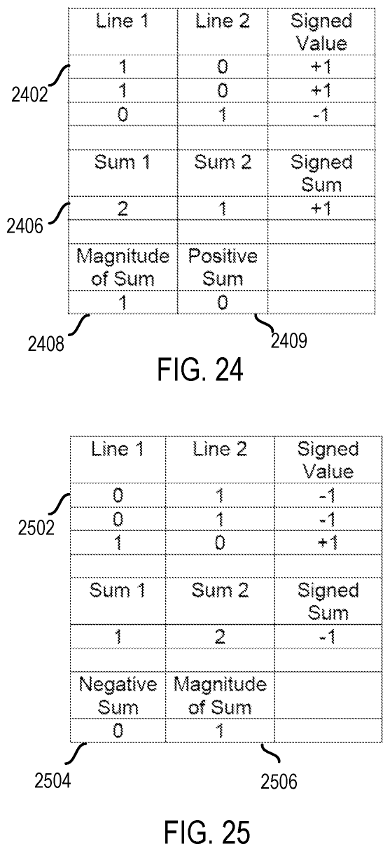

In one embodiment, digitizer 2263 is part of logic circuitry 2290, which uses the digital values from digitizer 2263 to determine signed result 2277. In one example, signed result 2277 is represented by two values (e.g., sums 2406 of FIG. 24) determined by digitizer 2263. A first value of the two values is determined based on an accumulation of currents on line 2280 at a first time instance T0. A second value of the two values is determined based on an accumulation of current online 2280 at a second time instance T1. In one example, voltages are applied to the memory cell sets similarly as illustrated in FIG. 16.

Memory cell set 2227 generates a current 2231 at time T0, and a current 2247 at time T1. In one example, currents 2231, 2247 correspond to output currents accumulated on digit line 1510 of FIG. 15. Set 2228 similarly provides currents 2232, 2248 at the times T0, T1. Set 2229 similarly provides currents 2233, 2249 at the times T0, T1.

The output currents at time T0 are summed to provide summed currents 2251, which corresponds to a first value of signed result 2277. The output currents at time T1 are summed to provide summed currents 2251, which corresponds to a second value of signed result 2277. Digitizer 2263 provides the first and second values in digital form. The two values together represent the magnitude and sign of the signed result.

In one embodiment, logic circuitry 2290 determines a difference in magnitudes of the two values from digitizer 2263. The difference is subtracted from the largest of the two values. The magnitude of the largest value after subtraction (reduced sum) is the magnitude of signed result 2277. The sign of the signed result 2277 is determined by the one of the two values that is reduced to a value of zero by the subtraction. For example, if the first value (reduced sum) is zero after subtraction, then the signed result 2277 is negative. If the second value is zero after subtraction, the signed result 2277 is positive.

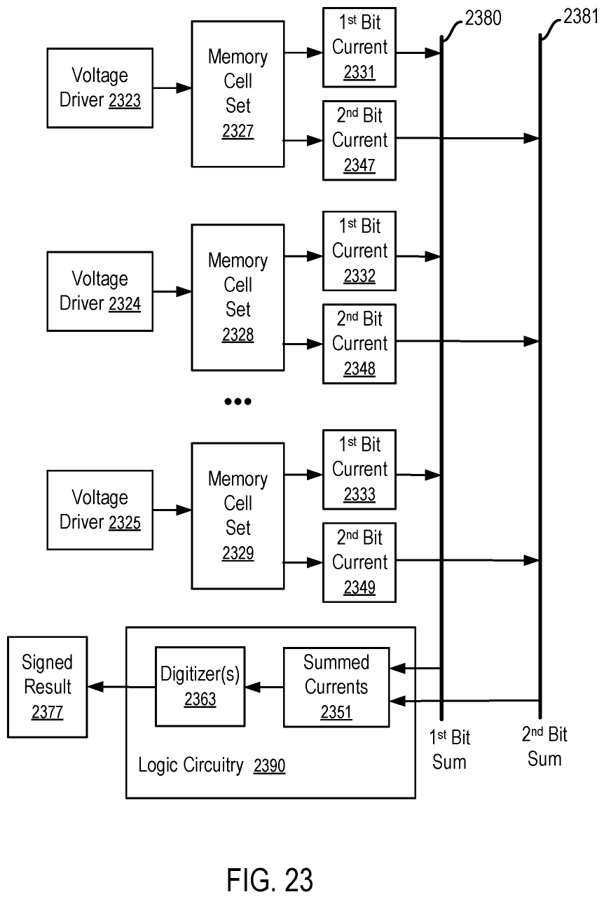

FIG. 23 shows a multiplication architecture for summing outputs from multiplications at a same time using two lines according to one embodiment. In one example, the outputs from the multiplications are summed in the same clock cycle.

Voltage drivers 2323, 2324, 2325 apply voltages to four or more memory cells in each of sets 2327, 2328, 2329. Output currents from the sets are accumulated on lines 2380, 2381. The sum of the currents accumulated on line 2380 correspond to a first value (sum of first bits) of the signed result 2377. The sum of the current accumulated on line 2381 correspond to a second value (sum of second bits) of the signed result 2377.

For example, output currents 2331, 2347 from set 2327 are accumulated as illustrated. Current 2331 corresponds to a first bit of a multiplication result generated by set 2327. Current 2347 corresponds to a second bit of the multiplication result.

Currents 2332, 2348 from set 2328 correspond to first and second bits of a multiplication result generated by set 2328. Currents 2333, 2349 from set 2329 correspond to first and second bits of a multiplication result generated by set 2329.

In one example, current 2331 is one of the output currents accumulated on digit line 1830 of FIG. 18. Current 2347 is one of the output currents accumulated on digit line 1834 of FIG. 18.

Summed currents 2351 from line 2380 are digitized by digitizer 2363 to provide a digital number corresponding to a first value of signed result 2377. Summed currents 2351 from line 2381 are digitized by digitizer 2363 to provide a digital number corresponding to a second value of signed result 2377.

As mentioned above, for example, logic circuitry 2390 uses these first and second digital values provided by digitizer 2363 to determine a magnitude and sign of signed result 2377. The magnitude of signed result 2377 is based on a difference between magnitudes of the first and second values. The sign of signed result 2377 corresponds to the one of the first and second values having the smallest magnitude.

In one example, voltage drivers 2323, 2324, 2325 apply voltages that correspond to a column of signed inputs to be multiplied by a column of signed weights stored in sets 2327, 2328, 2329. The sum of these multiplications is signed result 2377.

In one embodiment, sets 2327, 2328, 2329 are configured using memory cells of memory cell array 113. Data is collected by image sensing pixel array 111. The data is used by controller 124 to determine signed inputs, and to control the voltages applied by voltage drivers 2323, 2324, 2325.

In one embodiment, memory cells in sets 2327, 2328, 2329 are programmed in response to a write command received from a host by interface 125. In one embodiment, signed result 2377 is sent to the host. In one embodiment, signed result 2377 is sent to the host in response to receiving a read command from the host by interface 125.

FIGS. 24-26 show exemplary reductions of summation counts according to one embodiment. The counts refer to a digital value corresponding to a summation of output currents as discussed above. In one example, two digital values are provided by digitizer 2263, 2363.

As an example, each row 2402 as illustrated in the table of FIG. 24 is a digital representation of a result output from a multiplication performed by each of multiple sets. Each result has two bits. A first bit corresponds to a Line 1, and a second bit corresponds to a Line 2, each line used to sum outputs.

In one example, the sets are 2327, 2328, 2329. Line 1 is an example of line 2380. Line 2 is an example of line 2381.

The counts are summed to provide sums 2406 for each of Lines 1, 2. A magnitude 2408 of a signed result is determined by the difference in magnitudes of the sums 2406. The sign 2409 of the signed result is determined by the line position of the Line 1 or 2 having the lowest magnitude.

Magnitude 2408 can also be considered as the magnitude remaining after subtracting the smaller of sums 2406 from the larger of sums 2406 (e.g., 2−1=1). The sign 2409 can also be considered as the one of the Sums 1, 2 having a zero value after subtracting (sometimes referred to as being reduced by) the smallest of the sums from each sum (e.g., 1−1=0).

As illustrated, the signed result has a magnitude 2408 of 1, and a positive sign 2409 after the subtraction/reduction above.

As another example, each row 2502 as illustrated in the table of FIG. 25 is a digital representation of a result output from a multiplication performed by each of multiple sets. Each result has two bits. A first bit corresponds to a Line 1, and a second bit corresponds to a Line 2, similar to above.

In one example, the sets are 2327, 2328, 2329. Line 1 is an example of line 2380. Line 2 is an example of line 2381.

The counts are summed for each of Line 1, 2 similarly as described above. A magnitude 2506 of a signed result is determined by the difference in magnitudes of the sums. The sign 2504 of the signed result is determined by the position of the Line 1 or 2 having the lowest magnitude.

Magnitude 2506 can also be considered as the magnitude remaining after subtracting the smaller Sum 1 from the larger Sum 2 (e.g., 2−1=1). The sign 2504 can also be considered as the one of the Sums 1, 2 having a zero value after subtracting the smallest of the sums from each sum (e.g., 1−1=0).

As illustrated, the signed result has a magnitude 2506 of 1, and a negative sign 2504.

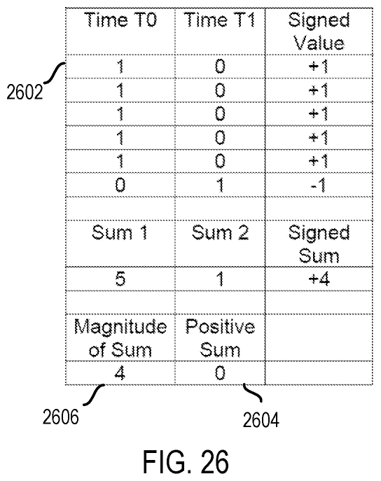

As another example, each row 2602 as illustrated in the table of FIG. 26 is a digital representation of a result output from a multiplication performed by each of multiple sets. Each result has two bits. A first bit corresponds to a Line 1, and a second bit corresponds to a Line 2.

In one example, the sets are 2327, 2328, 2329. Line 1 is an example of line 2380. Line 2 is an example of line 2381.

The counts are summed for each of Line 1, 2 similarly as described above. A magnitude 2606 of a signed result is determined by the difference in magnitudes of the sums. The sign 2604 of the signed result is determined by the position of the Line 1 or 2 having the lowest magnitude.

Magnitude 2606 can also be considered as the magnitude remaining after subtracting the smaller Sum 2 from the larger Sum 1 (e.g., 5−1=4). The sign 2604 can also be considered as the one of the Sums 1, 2 having a zero value after subtracting the smallest of the sums from each sum (e.g., 1−1=0).

As illustrated, the signed result has a magnitude 2606 of 4, and a positive sign 2604.

In one example, the magnitude and sign of the signed result is determined by logic circuitry 2290, 2390. In one example, the magnitude and sign of the signed result is determined by controller 124.

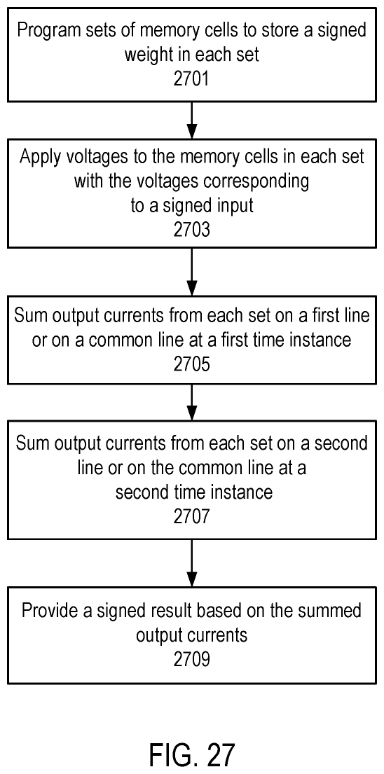

FIG. 27 shows a method for performing summation of outputs from signed multiplications performed by sets of memory cells according to one embodiment. For example, the method of FIG. 27 can be performed in an integrated circuit device 101 of FIG. 1 using multiplication and accumulation as illustrated in FIGS. 22 and 23.

The method of FIG. 27 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 27 is performed at least in part by one or more processing devices (e.g., controller 124 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2701, sets of memory cells are programmed to store a signed weight in each set. In one example, sets 2227, 2228, 2229 are programmed. In one example, sets 2327, 2328, 2329 are programmed.

At block 2703, voltages are applied to the memory cells in each set. The voltages correspond to a signed input. The voltages may be applied to only a portion of memory cells in each set at a given time instance or clock cycle. In one example, voltages are applied by voltage drivers 2223, 2224, 2225. In one example, voltages are applied by voltage drivers 2323, 2324, 2325.

At block 2705, output currents from each set are summed on a first line. Alternatively, output currents from each set are summed on a common line at a first time instance. In one example, the first line is line 2380. In one example, the common line is line 2280.

At block 2707, output currents from each set are summed on a second line. Alternatively, output currents from each set are summed on the common line at a second time instance. In one example, the second line is line 2381. In one example, the first and second time instances are times T0, T1 of FIG. 16.

At block 2709, a signed result based on the summed output currents is provided. In one example, the signed result is result 2277, 2377.

In one embodiment, a memory device comprises: a memory cell array (e.g., 113) having sets (e.g., 2227, 2327) of memory cells, wherein each set is programmable to store a signed weight; voltage drivers (e.g., 2223, 2323) configured to apply voltages to the memory cells in each set, the voltages corresponding to a signed input to be multiplied by the signed weight for each set; at least one line (e.g., 2280, 2380, 2381) coupled to each set, wherein the line is configured to sum output currents from the sets; and at least one digitizer (e.g., 2263, 2363), the digitizer configured to provide a signed result (e.g., 2277, 2377) based on summing the output currents from the sets.

In one embodiment, each set includes first and second cells programmable to store a positive version of the signed weight, and third and fourth cells programmable to store a negative version of the signed weight.

In one embodiment, the at least one line comprises: a first line coupled to the first and second cells in each set; and a second line coupled to the third and fourth cells in each set.

In one embodiment, a first bit result and a second bit result are based on summing the output currents from the sets; and a magnitude (e.g., 2408) of the signed result is determined based on a difference between magnitudes of sums of the first and second bit results (e.g., Sum 1, Sum 2 of FIG. 24).

In one embodiment, a first bit result and a second bit result are based on summing the output currents from the sets; and a sign (e.g., 2409) of the signed result corresponds to the one of the first or second bit results having a smaller magnitude.

In one embodiment, the voltages are applied to first and second cells in each set at first and second time instances; and the voltages applied at the first time instance represent the signed input, and the voltages applied at the second time instance represent a negative version of the signed input.

In one embodiment, the voltages are applied to each set at first and second time instances; and the at least one line is configured to sum the output currents from the sets for each of the first and second time instances.

In one embodiment, the memory cells are resistive random-access memory (RRAM) cells, NAND flash memory cells, or NOR flash memory cells.

In one embodiment, an apparatus comprises: an image sensing pixel array (e.g., 111); a plurality of sets each having two or more memory cells, wherein the memory cells of each set are programmable to store a respective signed weight; an interface configured to communicate with a host; and a controller (e.g., 124) configured to: receive data from the image sensing pixel array; program the memory cells of each set to store the respective signed weight; apply voltages to the sets, wherein the voltages are based on the data received from the image sensing pixel array, and wherein for each set the voltages represent a respective signed input to be multiplied by the respective signed weight stored in the set; determine a signed result based on summing output currents from the sets on at least one line; and send, via the interface (e.g., 125), the signed result to the host.

In one embodiment, the at least one line comprises first and second lines. Summing the output currents comprises determining a first sum of output currents on the first line, and determining a second sum of output currents on the second line.

In one embodiment, a magnitude of the signed result is based on a difference in magnitudes of the first and second sums.

In one embodiment, a sign of the signed result is determined by comparing magnitudes of the first and second sums.

In one embodiment, the line is a digit line, and the apparatus further comprises: bitlines coupled to each set; and select transistors configured to electrically connect the bitlines of each set to the digit line.

In one embodiment, the voltages are applied to gates of the select transistors.

In one embodiment, summing the output currents comprises determining a first sum of output currents on the line in a first clock cycle, and determining a second sum of output currents on the line in a second clock cycle.

In one embodiment, the memory cells of each set are NAND flash memory cells.

In one embodiment, when performing multiplication, one or more memory cells in each set are selected by applying a respective read voltage to gates of the memory cells.

In one embodiment, gates of non-selected memory cells in a respective same string with the selected memory cells are biased by applying a bypass voltage to the gates during the multiplication.

In one embodiment, a method comprises: receiving a command from a host system to write data; in response to receiving the command to write the data, programming sets of memory cells in a memory cell array, wherein each set of memory cells is programmed to store a signed weight; applying voltages to the sets, wherein for each set the voltages represent a respective signed input to be multiplied by the signed weight stored in the set; determining a signed result based on summing output currents from the sets on at least one line; receiving a command from the host system to read data; and in response to receiving the command to read data, sending the signed result to the host system.

In one embodiment, summing the output currents comprises using at least one integrator (e.g., 507 of FIG. 5) to accumulate current on the line.

Various embodiments related to memory devices that perform signed multi-bit to multi-bit multiplications using sets of memory cells in a memory cell array are now described below. The generality of the following description is not limited by the various embodiments described above.

In one embodiment, a memory cell array has sets organized as units of a fixed number of memory cells (e.g., two or four cells per set, such as above). Each set performs a signed multiplication (e.g., a multi-bit signed input to a set multiplied by a multi-bit signed weight stored by the set) to provide output currents. These output currents are summed on one or more common lines (e.g., bitline(s)) to provide one or more signed results. Each signed result corresponds to a bit significance of the weights and a bit significance of the inputs used to generate the respective signed result.

In a simplified example, a column of 2-bit inputs is multiplied by a column of 2-bit weights in a first time slice of a series of time slices. A column of 1-bit inputs using the LSB of each input is multiplied by a column of 1-bit signed weights using the MSB of each weight. A first signed result is obtained corresponding to the LSBs of the inputs and the MSBs of the weights. The same LSBs of the inputs are next multiplied by the LSBs of the weights to obtain a second signed result corresponding to the LSBs of the inputs and the LSBs of the weights.

Then, in a second time slice the MSB of each 2-bit input is multiplied by the MSB of each weight. A third signed result is obtained corresponding to the MSBs of the inputs and the MSBs of the weights. The same MSBs of the 2-bit inputs are next multiplied by the LSBs of the weights to obtain a fourth signed result corresponding to the MSBs of the inputs and the LSBs of the weights.

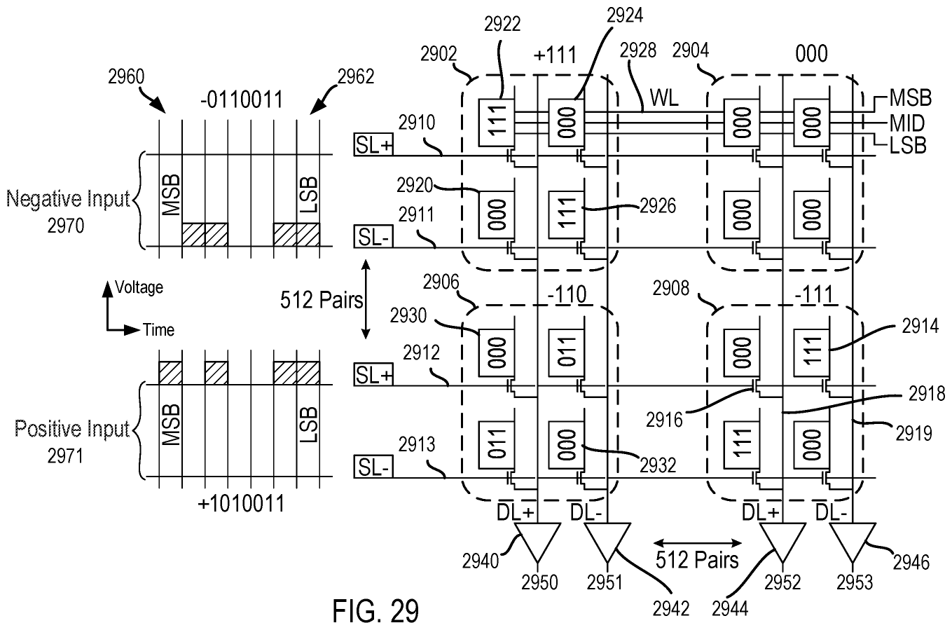

The first, second, third, and fourth signed results are added together taking into account the bit significance of each signed result. In one embodiment, this is done by adjusting each signed result exponentially by powers of two as appropriate based on the significance of the corresponding bits for both the inputs and weights. Each signed result is a pair of digital values that are added as two separate sums. In an alternative embodiment, the magnitudes of the output currents are adjusted to account for bit significance as described below (see, e.g., FIG. 29).

For example, the third signed result corresponding to the MSBs of the inputs and the MSBs of the weights is adjusted by 2× (for input MSB significance) and 2× (for weight MSB significance) for an adjustment of 4× to the third signed result when adding to the first, second, and fourth signed results. In one example, the powers of two adjustment is done using left shifting and adding similarly as described above.

The sum of the first, second, third, and fourth signed results provides a signed accumulation result represented by first and second digital values (e.g., from first and second digit lines). A sign and magnitude of the signed accumulation result can be determined using the first and second digital values (e.g., similarly as described for cancellation/reduction of magnitudes above).

In one embodiment, a memory device uses a memory cell array organized as sets of memory cells. In one example, resistive random-access memory (RRAM) cells are used. In one example, NAND or NOR flash memory cells are used.

Each set is programmable to store a multi-bit signed weight. After being programmed, voltage drivers apply voltages to the memory cells in each set. The voltages represent multi-bit signed inputs to be multiplied by the multi-bit signed weights.

One or more common lines are coupled to each set. The lines receive one or more output currents from the memory cells in each set (e.g., similarly as discussed above for sets of two or four cells). Each common line accumulates the currents to sum the output currents from the sets.

In one example, the line(s) are bitline(s) extending vertically above a semiconductor substrate as discussed above for FIG. 13. As an example, 512 memory cell sets are coupled to the line(s). Inputs are provided using 512 pairs of select lines (e.g., SL+, SL−), with one pair used per set (see, e.g., FIG. 29). The output currents from each of the 512 sets are collected on the line(s), and then one or more total current magnitudes are digitized to provide first and second digital values.

In one example, the memory device includes one or more digitizers. The digitizer(s) provide signed results (e.g., as described above) based on summing the output currents from each of the 512 sets on first and second digit lines.

A first digital value (e.g., an integer) representing the current on the first digit line is determined as the multiple of a predetermined current (e.g., as described above) representing 1. A second digital value representing the current on the second digit line is determined as the multiple of the predetermined current. The first and second digital values are, for example, outputs from a digitizer(s).

In one embodiment, the magnitude of the first and second digital values can be reduced by the smaller one of the two values to cancel out an equal number of representations of 1 and −1 in the items being summed up. After this magnitude reduction, the sign of the summation is represented by the position of the zero (e.g., negative if the first reduced value from the first digit line, positive if the second reduced value from the second digit line). The magnitude of the result is represented by the non-zero one of the first or second reduced values.

In one embodiment, signed multi-bit to multi-bit multiplications are performed. The sign of the input can be carried to each bit of the signed input to present each bit as a signed 1-bit in a two-bit representation. Similarly, the sign of the weight can be carried to each bit of the signed weight to present each bit as a signed 1-bit in a two-bit representation. Results of signed 1-bit to 1-bit multiplication can be summed with the respective significance of the bits in the input and/or the respective significance of the bits in the weight taken into consideration.

In one embodiment, a memory device includes a memory cell array having sets of NAND flash memory cells. Each set is programmable to store a multi-bit signed weight. Voltage drivers apply voltages to each set. The voltages correspond to a multi-bit signed input, which is multiplied by the multi-bit signed weight for each set. Two common lines are coupled to each set. Each common line sums a respective output current from each set. A digitizer on each common line provides signed results based on summing the output currents from the sets. Each signed result corresponds to a bit significance of the input and a bit significance of the weight, for example as described above. The signed results are added together taking respective bit significance into consideration to provide first and second digital values that represent a signed accumulation result from the multi-bit to multi-bit multiplication.

In one embodiment, a signed input is applied to a set of memory cells on two wires (e.g., two select lines), each wire carrying a signal. Whether the input is positive or negative depends on where the magnitude of the signal is provided. In other words, the sign depends on which wire carries the signal. The other wire carries a signal of constant value (e.g., a constant voltage corresponding to zero).

Every signed input applied to the set is treated as having a positive magnitude. One of the two wires is always biased as a zero (biased as a constant signal more generally). The other wire carries the magnitude of the input pattern.

In one embodiment, a multi-bit input is represented as a serial or time-sliced input provided on the two wires. For example, the input pattern is a number of bits (e.g., 1101011) for which corresponding voltages are serially applied to the wire, one bit per time slice (see, e.g., inputs 2970, 2971 of FIG. 29).

In one example, input bits are applied serially one at a time as described for FIG. 4 above.

In one embodiment, a memory cell set has four groups of cells, with each group having three memory cells (see, e.g., group 2922 of FIG. 29). Each group stores values representing three bits of a multi-bit weight. One bit is for an MSB, one bit is for a bit of middle significance (sometimes indicated as “MID” herein), and one bit is for an LSB. This provides a multi-bit representation for the stored weight.

Two of the groups store all zeros (e.g., groups 2920, 2924 of FIG. 29). The positioning of the groups storing all zeros corresponds to the sign of the weight. In general, a consistent pattern of groups of cells that store all zeros is used in the memory cell array to indicate the sign of the stored weight. The other two groups store bits indicating the magnitudes of the three bits in the weight.

In one embodiment, the contribution of output current to common lines from each one of the memory cells varies corresponding to the MSB, MID, or LSB significance of the bit stored by the memory cell (e.g., stored for 3 bits in a group of 3 memory cells above). The contribution for MSB significance (e.g., 100 nA) is two times greater than for MID significance (e.g., 50 nA). The contribution for MID significance is two times greater than for LSB significance (e.g., 25 nA).

When the output current contribution takes bit significance into consideration, then the left shifting described above is not required when adding the signed results (e.g., first, second, third, and fourth signed results above) to obtain a signed accumulation result. Instead, the signed results can be added directly without left shifting.

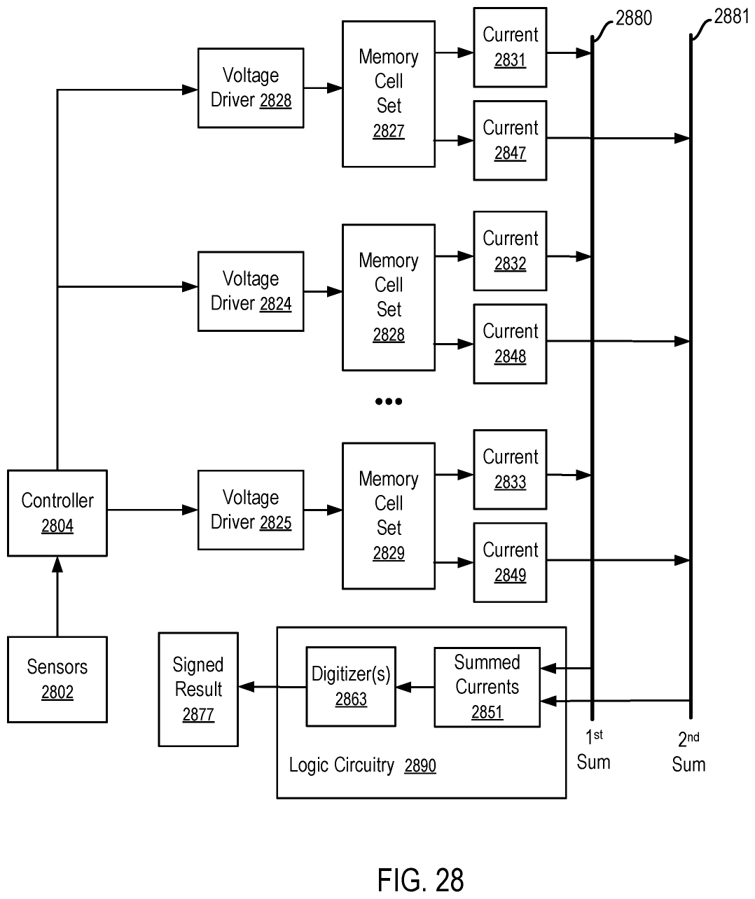

FIG. 28 shows an architecture for performing signed multi-bit to multi-bit multiplications using sets (e.g., 2827, 2828, 2829) of memory cells to provide a signed result 2877 according to one embodiment. Each memory cell set stores a multi-bit signed weight.

Voltage drivers 2828, 2824, 2825 apply voltages to the memory cells in each memory cell set 2827, 2828, 2829. The applied voltages represent multi-bit inputs to be multiplied by the weights stored by the sets.

Each memory cell set 2827, 2828, 2829 provides output currents representing a result of multiplication of the weights by the inputs. Two output currents are provided from each memory cell set so that first and second digital values can be determined by digitizing the first and second sums of the accumulated currents. The output currents are summed on common lines 2880, 2881.

Line 2880 accumulates output currents 2831, 2832, 2833. Line 2881 accumulates output currents 2847, 2848, 2849.

A first sum of currents is accumulated on line 2880. A second sum of currents is accumulated on line 2881. The summed currents 2851 from lines 2880, 2881 are provided to one or more digitizers 2863 and converted to two digital values representing signed result 2877.

In one embodiment, logic circuitry 2890 includes digitizer 2863. Logic circuitry 2890 uses digital values provided by digitizer 2863 to determine a sign and a magnitude of signed result 2877. Signed result 2877 is provided to controller 2804 for further processing, such as sending to a host device and/or configuring operation of one or more sensors 2802.

In one embodiment, sensors 2802 collect sensor data. In one example, sensors 2802 include cameras, accelerometers, GPS location sensors, and/or temperature sensors. Controller 2804 receives the sensor data from sensors 2802.

Controller 2804 determines input signal patterns to apply to memory cell sets 2827, 2828, 2829 based at least in part on the sensor data. Controller 2804 causes voltage drivers 2828, 2824, 2825 to apply voltages to the memory cell sets that are representative of the input signal patterns.

In one embodiment, each of memory cell sets 2827, 2828, 2829 includes four NAND flash memory cells similarly as illustrated in FIG. 18, except that each memory cell stores more than one bit (e.g., using MLC, TLC, or QLC). Two of the memory cells provide output current 2831. The other two of the memory cells provide output current 2847.

In one embodiment, each of memory cell sets 2827, 2828, 2829 includes some memory cells storing a most significant bit of the stored weight, some memory cells storing a middle significance bit of the stored weight, and some memory cells storing a least significant bit of the stored weight (e.g., set 2902 of FIG. 29).

In one embodiment, voltages are applied by the voltage drivers to the memory cell sets using pairs of wires. One of the wires is held at a constant voltage and the position of the wire (e.g., first or second position) indicates a sign of the input to a set. The other of the wires varies in voltage and indicates the magnitude of the bits of the input to the set.

As mentioned above, memory cell sets can be used to generate a plurality of signed results 2877. Each signed result 2877 corresponds to the bit significances of the input bit and the weight bit used to generate the signed result 2877.

The signed results 2877 are added together to provide a signed accumulation result. Exponential power of two adjustments (e.g., similarly as described for FIG. 3 to obtain result 251) are made to each signed result when adding, for example as described above.

FIG. 29 shows an architecture for performing signed multi-bit to multi-bit multiplications using serial multi-bit inputs 2970, 2971 according to one embodiment. Memory cell sets 2902, 2904, 2906, 2908 each store a multi-bit signed weight. Voltages corresponding to inputs 2970, 2971 are applied to the memory cell sets using select lines 2910, 2911, 2912, 2913. Memory cell sets 2902, 2904, 2906, 2908 are an example of memory cell set 2827 of FIG. 28.

Inputs 2970, 2971 are applied serially in time slices 2960, 2962, as illustrated. For example, an MSB of input 2970 is applied in time slice 2960. An LSB of input 2970 is applied in time slice 2962. The bits of input 2971 are applied serially in a similar manner. A signed result is obtained for each time slice (e.g., represented by first and second digital values 2950, 2951).

Input 2970 has a negative sign. To indicate the negative sign, voltage(s) representing all zeros are applied to select line 2910. Voltages corresponding to the magnitude (e.g., 1 or 0) of the bits of input 2970 are applied to select line 2911.

Input 2970 has a positive sign. To indicate the positive sign, voltage(s) representing all zeros are applied to select line 2913. Voltages corresponding to the magnitude of the bits of input 2971 are applied to select line 2912. The selection of the first or second select line for applying all zeros is used consistently to define the sign of the input. The sign of the input is associated with (e.g., carried to) all bits of the input by using this approach.

Each memory cell set has four groups 2920, 2922, 2924, 2926 of cells. Each group contains three memory cells accessed by wordlines 2928. Each wordline corresponds to a different bit significance (e.g., MSB, MID, LSB). Although not illustrated for purposes of simplicity, all groups in all sets are similarly connected to wordlines 2928.

The position of the groups (e.g., the storage pattern of groups) in the memory cell sets is used to indicate a sign of the stored weight. For example, two groups 2920, 2924 store all zeros in one pattern as illustrated. This corresponds to a positive sign. In contrast, two groups 2930, 2932 store all zeros in an opposite pattern for another weight. This corresponds to a negative sign.

The other two groups 2922, 2926 in each memory cell set indicate a magnitude of the stored weight.

The groups of cells in each set provide output current(s) to digit lines (e.g., 2918, 2919). The cells in each set provide the output currents to bitlines 2914, which are coupled to the digit lines by select transistors (e.g., 2916). Select lines 2910, 2911, 2912, 2913 are connected to gates of the select transistors to control the providing of output currents from the memory cells to the digit lines.

Output currents accumulated on the digit lines are provided to digitizers 2940, 2942, 2944, 2946. Each pair of digitizers provides first and second digital values (e.g., 2950, 2951 or 2952, 2953) representing a signed result. In one example, the signed result is signed result 2877 of FIG. 28.

In one embodiment, each group 2920, 2922, 2924, 2926 contains resistive random access memory (RRAM) cells or NOR flash memory cells. Voltages are applied to wordlines 2928 to select all cells in each group so that output currents from the cells are accumulated on the digit line simultaneously. This can be done due to the parallel cell arrangement of the memory cell array.

In one embodiment, the contribution of output current from each one of the wordlines 2928 (LSB, MID, MSB) through the memory cells to the digit lines varies. The contribution from the MID wordline is greater than from the LSB wordline. The contribution from the MSB wordline is greater than from the MID wordline.

In one embodiment, each group 2920, 2922, 2924, 2926 contains a single NAND flash memory cell. The cell stores three bits that represent the stored weight. Multiple bits are stored in single cells due to the series cell arrangement of the memory cell array.

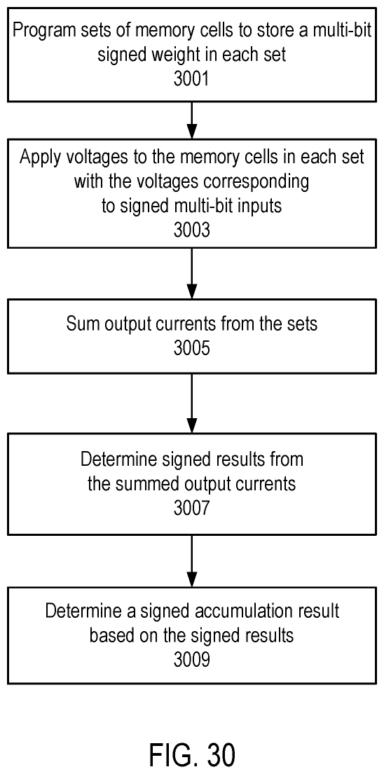

FIG. 30 shows a method for performing signed multi-bit to multi-bit multiplications in a memory cell array according to one embodiment. For example, the method of FIG. 30 can be performed in an integrated circuit device 101 of FIG. 1 using multiplication and accumulation as illustrated in FIGS. 28 and 29.

The method of FIG. 30 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 30 is performed at least in part by one or more processing devices (e.g., controller 124 of FIG. 1, controller 2804 of FIG. 28).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 3001, sets of memory cells are programmed to each store a multi-bit signed weight. In one example, memory cell sets 2827, 2828, 2829 are programmed.

At block 3003, voltages are applied to the memory cells in each set. The voltages correspond to signed multi-bit inputs to be multiplied by the stored weights in the sets. In one example, inputs 2970, 2971 are applied to memory cell sets 2902, 2904, 2906, 2908.

At block 3005, output currents from the sets are summed. In one example, currents 2831, 2832, 2833 are summed on line 2880. Currents 2847, 2848, 2849 are summed on line 2881.

At block 3007, signed results from the summed output currents are determined. In one example, signed result 2877 is determined based on summed currents 2851.

At block 3009, a signed accumulation result is determined based on the signed results. In one example, the signed results are added together after adjusting for the bit significance of the respective input bit and/or weight bit used during multiplication to obtain the respective signed result.

In one embodiment, a device comprises: a memory cell array (e.g., 113) having sets (e.g., 2827, 2828, 2829) of memory cells, wherein each set is programmable to store a multi-bit signed weight; voltage drivers (e.g., 2828, 2824, 2025) configured to apply voltages to each set, wherein the voltages correspond to a multi-bit signed input to be multiplied by the multi-bit signed weight for each set; at least one common line (e.g., 2880, 2881) coupled to each set, wherein the common line is configured to sum output currents from the sets; and at least one digitizer (e.g., 2863), the digitizer configured to provide at least one signed result based on summing the output currents from the sets.

In one embodiment, the device further comprises respective first and second input lines (e.g., select lines 2910, 2911, 2912, 2913) configured to apply the voltages to each set, wherein: the multi-bit signed input comprises a plurality of bits; for each set, a constant voltage is applied to one (e.g., 2910, 2913) of the first or second input lines to represent a sign of the bits of the respective signed input; and for each set, a varying voltage magnitude is applied to the other one (e.g., 2911, 2912) of the first or second input lines to represent a respective magnitude of the bits of the signed input.

In one embodiment, voltages corresponding to each bit of the signed input are applied serially to the respective set.

In one embodiment, voltages corresponding to each bit of the signed input are applied to the respective set in a series of time slices (e.g., 2960, 2962), with each time slice corresponding to one bit of the signed input.

In one embodiment, summing the output currents from the sets provides a first current sum and a second current sum.

In one embodiment, the digitizer is further configured to generate a first digital value based on the first current sum, and a second digital value based on the second current sum; and a sign and magnitude of the signed result are determined based on the first and second digital values.

In one embodiment, first memory cells (e.g., a first two cells) in each set are configured to store a zero for each bit of the signed weight (e.g., store 000 in each of the first two cells for a 3-bit weight); second memory cells (e.g., a second two cells) in the set are configured to store values representing a respective magnitude for each bit of the signed weight (e.g., store 110 in each of the second two cells for the 3-bit weight); and the position in the set of the first memory cells corresponds to a sign of the signed weight.

In one embodiment, the at least one common line comprises a first digit line and a second digit line (e.g., digit lines 2918, 2919); and at least one of the first memory cells is coupled to the first digit line, and at least another one of the first memory cells is coupled to the second digit line.

In one embodiment, an apparatus comprises: at least one sensor (e.g., 2802); a plurality of sets each having two or more memory cells, wherein the memory cells of each set are programmable to store a respective multi-bit signed weight; an interface configured to communicate with a host; and a controller (e.g., 124, 2804).

The controller is configured to: program the memory cells of each set to store the respective multi-bit signed weight; receive data from the sensor; apply voltages to the sets, wherein the voltages are based on the data received from the sensor, and wherein the voltages represent multi-bit signed inputs to be multiplied by the multi-bit signed weights stored in the sets; determine a plurality of signed results (e.g., 2877) based on summing output currents from the sets on at least one common line, wherein each of the signed results corresponds to a respective bit significance (e.g., MSB, MID, LSB) in the signed weights; determine at least one accumulation result based on the plurality of signed results; and send, via the interface, the accumulation result to the host.

In one embodiment, each signed weight comprises a first bit of a first significance (e.g. MSB), and a second bit of a second significance (e.g. LSB); the plurality of signed results comprises a first signed result and a second signed result; the first signed result is determined using the first bit of each signed weight; the second signed result is determined using the second bit of each signed weight; and determining the accumulation result comprises adding the first and second signed results.

In one embodiment, the apparatus further comprises respective first and second input lines configured to apply the voltages to each set, wherein: each multi-bit signed input comprises a plurality of bits; for each set, a constant voltage is applied to one of the first or second input lines to represent a sign of the bits of the respective signed input; and for each set, a varying voltage magnitude is applied to the other one of the first or second input lines to represent a respective magnitude of the bits of the signed input.

In one embodiment, voltages corresponding to each bit of the signed input are applied to the set in a series of time slices, with each time slice corresponding to one bit of the signed input.

In one embodiment, the at least one accumulation result comprises a first accumulation result determined at a first of the time slices, and a second accumulation result determined at a second of the time slices.

In one embodiment, a magnitude of each output current from those memory cells programmed at a state representing 1 corresponds to the respective bit significance (e.g., MSB, MID, LSB) in the signed weights.

In one embodiment, the magnitudes of the output currents vary by a power of two based on the bit significance corresponding to the respective output current (e.g., the output current for an MSB bit is two times the output current for a MID bit, and four times the output current for an LSB bit).

In one embodiment, the apparatus further comprises a plurality of wordlines (e.g., 2928) coupled to memory cells in each set, wherein each of the wordlines corresponds to a bit significance in the signed weights.

In one embodiment, the at least one common line is at least one digit line, the apparatus further comprising: bitlines coupled to memory cells in each set; select transistors coupling the bitlines to the digit line; and select lines (e.g., 2910, 2911, 2912, 2913) configured to control the select transistors, wherein applying the voltages comprises applying voltages on the select lines to bias gates of the select transistors.

In one embodiment, the memory cells are NAND flash memory cells; each set has four memory cells; and each memory cell of the set stores a plurality of bits representing the signed weight stored by the set.

In one embodiment, a method comprises: receiving a command from a host system to write data; in response to receiving the command to write the data, programming sets of memory cells in a memory cell array, wherein each set of memory cells is programmed to store a multi-bit signed weight; applying voltages to the sets, wherein for each set the voltages represent a respective multi-bit signed input to be multiplied by the multi-bit signed weight stored in the set; determining a plurality of signed results based on summing output currents from the sets, wherein each of the signed results corresponds to a respective bit significance (e.g., MSB, MID, LSB) in the signed weights; determining at least one signed accumulation result based on the plurality of signed results; receiving a command from the host system to read data; and in response to receiving the command to read data, sending the signed accumulation result to the host system.

In one embodiment, the output currents are summed on a first and second line. The method further comprises: determining a magnitude of the accumulation result based on a difference in first and second magnitudes of sums of the output currents on the first and second lines, respectively; and determining a sign of the accumulation result based on the one of the first or second magnitudes having a smaller magnitude.

Integrated circuit devices 101 (e.g., as in FIG. 1) can be configured as a storage device, a memory module, or a hybrid of a storage device and memory module. Examples of a storage device include a solid-state drive (SSD), a flash drive, a universal serial bus (USB) flash drive, an embedded multi-media controller (eMMC) drive, a universal flash storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The integrated circuit devices 101 (e.g., as in FIG. 1) can be installed in a computing system as a memory sub-system having an embedded image sensor and an inference computation capability. Such a computing system can be a computing device such as a desktop computer, a laptop computer, a network server, a mobile device, a portion of a vehicle (e.g., airplane, drone, train, automobile, or other conveyance), an internet of things (IoT) enabled device, an embedded computer (e.g., one included in a vehicle, industrial equipment, or a networked commercial device), or such a computing device that includes memory and a processing device.

In general, a computing system can include a host system that is coupled to one or more memory sub-systems (e.g., integrated circuit device 101 of FIG. 1). In one example, a host system is coupled to one memory sub-system.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

For example, the host system can include a processor chipset (e.g., processing device) and a software stack executed by the processor chipset. The processor chipset can include one or more cores, one or more caches, a memory controller (e.g., NVDIMM controller), and a storage protocol controller (e.g., PCIe controller, SATA controller). The host system uses the memory sub-system, for example, to write data to the memory sub-system and read data from the memory sub-system.

The host system can be coupled to the memory sub-system via a physical host interface. Examples of a physical host interface include, but are not limited to, a serial advanced technology attachment (SATA) interface, a peripheral component interconnect express (PCIe) interface, a universal serial bus (USB) interface, a fibre channel, a serial attached SCSI (SAS) interface, a double data rate (DDR) memory bus interface, a small computer system interface (SCSI), a dual in-line memory module (DIMM) interface (e.g., DIMM socket interface that supports double data rate (DDR)), an open NAND flash interface (ONFI), a double data rate (DDR) interface, a low power double data rate (LPDDR) interface, a compute express link (CXL) interface, or any other interface. The physical host interface can be used to transmit data between the host system and the memory sub-system. The host system can further utilize an NVM express (NVMe) interface to access components (e.g., memory devices) when the memory sub-system is coupled with the host system by the PCIe interface. The physical host interface can provide an interface for passing control, address, data, and other signals between the memory sub-system and the host system. In general, the host system can access multiple memory sub-systems via a same communication connection, multiple separate communication connections, or a combination of communication connections.

The processing device of the host system can be, for example, a microprocessor, a central processing unit (CPU), a processing core of a processor, an execution unit, etc. In some instances, the controller can be referred to as a memory controller, a memory management unit, or an initiator. In one example, the controller controls the communications over a bus coupled between the host system and the memory sub-system. In general, the controller can send commands or requests to the memory sub-system for desired access to memory devices. The controller can further include interface circuitry to communicate with the memory sub-system. The interface circuitry can convert responses received from the memory sub-system into information for the host system.

The controller of the host system can communicate with a controller of the memory sub-system to perform operations such as reading data, writing data, or erasing data at the memory devices, and other such operations. In some instances, the controller is integrated within the same package of the processing device. In other instances, the controller is separate from the package of the processing device. The controller or the processing device can include hardware such as one or more integrated circuits (ICs), discrete components, a buffer memory, or a cache memory, or a combination thereof. The controller or the processing device can be a microcontroller, special-purpose logic circuitry (e.g., a field programmable gate array (FPGA), an application specific integrated circuit (ASIC), etc.), or another suitable processor.

The memory devices can include any combination of the different types of non-volatile memory components and volatile memory components. The volatile memory devices can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, or a PLC portion of memory cells, or any combination thereof. The memory cells of the memory devices can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), spin transfer torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller (or controller for simplicity) can communicate with the memory devices to perform operations such as reading data, writing data, or erasing data at the memory devices and other such operations (e.g., in response to commands scheduled on a command bus by controller). The controller can include hardware such as one or more integrated circuits (ICs), discrete components, or a buffer memory, or a combination thereof. The hardware can include digital circuitry with dedicated (i.e., hard-coded) logic to perform the operations described herein. The controller can be a microcontroller, special-purpose logic circuitry (e.g., a field programmable gate array (FPGA), an application specific integrated circuit (ASIC), etc.), or another suitable processor.

The controller can include a processing device (processor) configured to execute instructions stored in a local memory. In the illustrated example, the local memory of the controller includes an embedded memory configured to store instructions for performing various processes, operations, logic flows, and routines that control operation of the memory sub-system, including handling communications between the memory sub-system and the host system.

In some embodiments, the local memory can include memory registers storing memory pointers, fetched data, etc. The local memory can also include read-only memory (ROM) for storing micro-code. While the example memory sub-system includes a controller, in another embodiment of the present disclosure, a memory sub-system does not include a controller, and can instead rely upon external control (e.g., provided by an external host, or by a processor or controller separate from the memory sub-system).

In general, the controller can receive commands or operations from the host system and can convert the commands or operations into instructions or appropriate commands to achieve the desired access to the memory devices. The controller can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices. The controller can further include host interface circuitry to communicate with the host system via the physical host interface. The host interface circuitry can convert the commands received from the host system into command instructions to access the memory devices as well as convert responses associated with the memory devices into information for the host system.

The memory sub-system can also include additional circuitry or components that are not illustrated. In some embodiments, the memory sub-system can include a cache or buffer (e.g., DRAM) and address circuitry (e.g., a row decoder and a column decoder) that can receive an address from the controller and decode the address to access the memory devices.

In some embodiments, the memory devices include local media controllers that operate in conjunction with memory sub-system controller to execute operations on one or more memory cells of the memory devices. An external controller (e.g., memory sub-system controller) can externally manage the memory device (e.g., perform media management operations on the memory device). In some embodiments, a memory device is a managed memory device, which is a raw memory device combined with a local media controller for media management within the same memory device package. An example of a managed memory device is a managed NAND (MNAND) device.

The controller or a memory device can include a storage manager configured to implement storage functions discussed above. In some embodiments, the controller in the memory sub-system includes at least a portion of the storage manager. In other embodiments, or in combination, the controller or the processing device in the host system includes at least a portion of the storage manager. For example, the controller, the controller, or the processing device can include logic circuitry implementing the storage manager. For example, the controller, or the processing device (processor) of the host system, can be configured to execute instructions stored in memory for performing the operations of the storage manager described herein. In some embodiments, the storage manager is implemented in an integrated circuit chip disposed in the memory sub-system. In other embodiments, the storage manager can be part of the firmware of the memory sub-system, an operating system of the host system, a device driver, or an application, or any combination therein.

In one embodiment, an example machine of a computer system within which a set of instructions, for causing the machine to perform any one or more of the methods discussed herein, can be executed. In some embodiments, the computer system can correspond to a host system that includes, is coupled to, or utilizes a memory sub-system or can be used to perform the operations described above. In alternative embodiments, the machine can be connected (e.g., networked) to other machines in a LAN, an intranet, an extranet, or the internet, or any combination thereof. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a personal digital assistant (PDA), a cellular telephone, a web appliance, a server, a network router, a switch or bridge, a network-attached storage facility, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system includes a processing device, a main memory (e.g., read-only memory (ROM), flash memory, dynamic random access memory (DRAM) such as synchronous DRAM (SDRAM) or Rambus DRAM (RDRAM), static random access memory (SRAM), etc.), and a data storage system, which communicate with each other via a bus (which can include multiple buses).

A processing device can be one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. A processing device can also be one or more special-purpose processing devices such as an application specific integrated circuit (ASIC), a field programmable gate array (FPGA), a digital signal processor (DSP), network processor, or the like. The processing device is configured to execute instructions for performing the operations and steps discussed herein. The computer system can further include a network interface device to communicate over the network.

The data storage system can include a machine-readable medium (also known as a computer-readable medium) on which is stored one or more sets of instructions or software embodying any one or more of the methodologies or functions described herein. The instructions can also reside, completely or at least partially, within the main memory and within the processing device during execution thereof by the computer system, the main memory and the processing device also constituting machine-readable storage media. The machine-readable medium, data storage system, or main memory can correspond to the memory sub-system.

In one embodiment, the instructions include instructions to implement functionality corresponding to the operations described above. While the machine-readable medium is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

In one embodiment, a memory device includes a controller that controls voltage drivers (e.g., 205, 215, 225 of FIG. 3) and/or other components of the memory device. The controller is instructed by firmware or other software. The software can be stored on a machine-readable medium as instructions, which can be used to program the controller. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations may be described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special-purpose circuitry, with or without software instructions, such as using application-specific integrated circuit (ASIC) or field-programmable gate array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. A device comprising:
a memory cell array having sets of memory cells, wherein each set is programmable to store a multi-bit signed weight;
voltage drivers configured to apply voltages to each set, wherein the voltages correspond to a multi-bit signed input to be multiplied by the multi-bit signed weight for each set; and
at least one common line coupled to each set, wherein the common line is configured to sum output currents from the sets.

2. The device of claim 1, further comprising respective first and second input lines configured to apply the voltages to each set, wherein:
the multi-bit signed input comprises a plurality of bits;
for each set, a constant voltage is applied to one of the first or second input lines to represent a sign of the bits of the respective signed input; and
for each set, a varying voltage magnitude is applied to the other one of the first or second input lines to represent a respective magnitude of the bits of the signed input.

3. The device of claim 2, wherein voltages corresponding to each bit of the signed input are applied serially to the respective set.

4. The device of claim 2, wherein voltages corresponding to each bit of the signed input are applied to the respective set in a series of time slices, with each time slice corresponding to one bit of the signed input.

5. The device of claim 1, wherein summing the output currents from the sets provides a first current sum and a second current sum.

6. The device of claim 5, further comprising a digitizer, wherein:
the digitizer is further configured to generate a first digital value based on the first current sum, and a second digital value based on the second current sum; and
a sign and magnitude of a signed result are determined based on the first and second digital values.

7. The device of claim 1, wherein:
first memory cells in each set are configured to store a zero for each bit of the signed weight;
second memory cells in the set are configured to store values representing a respective magnitude for each bit of the signed weight; and
a position in the set of the first memory cells corresponds to a sign of the signed weight.

8. The device of claim 7, wherein:
the at least one common line comprises a first digit line and a second digit line; and
at least one of the first memory cells is coupled to the first digit line, and at least another one of the first memory cells is coupled to the second digit line.

9. An apparatus comprising:
at least one sensor;
and
a controller configured to:
program memory cells of each of a plurality of sets to store a respective multi-bit signed weight;
receive data from the sensor;
apply voltages to the sets, wherein the voltages are based on the data received from the sensor; and
determine signed results based on summing output currents from the sets on at least one common line, wherein each of the signed results corresponds to a respective bit significance in the signed weights.

10. The apparatus of claim 9, wherein:
each signed weight comprises a first bit of a first significance, and a second bit of a second significance;
the plurality of signed results comprises a first signed result and a second signed result;
the first signed result is determined using the first bit of each signed weight;
the second signed result is determined using the second bit of each signed weight; and
determining an accumulation result by adding the first and second signed results.

11. The apparatus of claim 9, further comprising respective first and second input lines configured to apply the voltages to each set, wherein:
each multi-bit signed input comprises a plurality of bits;
for each set, a constant voltage is applied to one of the first or second input lines to represent a sign of the bits of the respective signed input; and
for each set, a varying voltage magnitude is applied to the other one of the first or second input lines to represent a respective magnitude of the bits of the signed input.

12. The apparatus of claim 11, wherein voltages corresponding to each bit of the signed input are applied to the set in a series of time slices, with each time slice corresponding to one bit of the signed input.

13. The apparatus of claim 12, wherein at least one accumulation result comprises a first accumulation result determined at a first of the time slices, and a second accumulation result determined at a second of the time slices.

14. The apparatus of claim 9, wherein a magnitude of each output current from those memory cells programmed at a state representing 1 corresponds to the respective bit significance in the signed weights.

15. The apparatus of claim 14, wherein the magnitudes of the output currents vary by a power of two based on the bit significance corresponding to the respective output current.

16. The apparatus of claim 9, further comprising a plurality of wordlines coupled to memory cells in each set, wherein each of the wordlines corresponds to a bit significance in the signed weights.

17. The apparatus of claim 16, wherein the at least one common line is at least one digit line, the apparatus further comprising:
bitlines coupled to memory cells in each set;
select transistors coupling the bitlines to the digit line; and
select lines configured to control the select transistors, wherein applying the voltages comprises applying voltages on the select lines to bias gates of the select transistors.

18. The apparatus of claim 9, wherein:
the memory cells are NAND flash memory cells;
each set has four memory cells; and
each memory cell of the set stores a plurality of bits representing the signed weight stored by the set.

19. A method comprising:
programming sets of memory cells;
applying voltages to the sets; and
determining a plurality of signed results based on summing output currents from the sets.

20. The method of claim 19, wherein the output currents are summed on a first and second line, the method further comprising:
determining a magnitude of an accumulation result based on a difference in first and second magnitudes of sums of the output currents on the first and second lines, respectively; and
determining a sign of the accumulation result based on the one of the first or second magnitudes having a smaller magnitude.
